(19) United States
(12) Patent Application Publication
(10) Pub. No.: US 2022/0171286 A1
(43) Pub. Date: Jun. 2, 2022

(54) RESIST COMPOSITION AND METHOD OF FORMING RESIST PATTERN

(71) Applicants: Tokyo Ohka Kogyo Co., Ltd., Kawasaki-shi (JP); National Institute of Advanced Industrial Science and Technology, Tokyo (JP)

(72) Inventors: Takatoshi INARI, Kawasaki-shi (JP); Masatoshi ARAI, Kawasaki-shi (JP); Takaya MAEHASHI, Kawasaki-shi (JP); Yoshitaka KOMURO, Kawasaki-shi (JP); Daisuke KAWANA, Kawasaki-shi (JP); Kiwamu SUE, Tsukuba-shi (JP); Sho KATAOKA, Tsukuba-shi (JP)

(21) Appl. No.: 17/454,891

(22) Filed: Nov. 15, 2021

(30) Foreign Application Priority Data
Nov. 30, 2020 (JP) 2020-198591

(51) Int. Cl. G03F 7/039; G03F 7/038; C08F 220/28

(52) U.S. Cl. CPC G03F 7/039; C08F 220/283; G03F 7/038

(57) ABSTRACT

A resist composition containing a metal compound and a polymer. A structure of the metal compound is changed upon exposure, and the metal compound exhibits changed solubility in a developing solution. The polymer segregates on a surface of a resist film in a case where the resist film is formed using the resist composition. The metal compound contains a metal ion of a metal atom of Group 3 to Group 16 in the long periodic table or a metal oxide of the metal atom, and a bonder that is bonded to the metal ion or the metal oxide. The content of the metal atom contained in the metal ion or the metal oxide is in a range of 0.2% to 3% by mass with respect to a total mass of the resist composition.

### BACKGROUND OF THE INVENTION

### Field of the Invention

The present invention relates to a resist composition and a method of forming a resist pattern.

Priority is claimed on Japanese Patent Application No. 2020-198591, filed Nov. 30, 2020, the content of which is incorporated herein by reference.

### Description of Related Art

In recent years, in the production of semiconductor elements and liquid crystal display elements, advances in lithography techniques have led to a rapid progress in pattern fining. Typically, the fining technique is carried out by shortening the wavelength (increasing the energy) of the light source for exposure.

Resist materials for use with these types of light sources for exposure require lithography characteristics such as a high resolution capable of reproducing a fine-sized pattern, and a high level of sensitivity to these types of light sources for exposure. As a resist material that satisfies these requirements, a chemically amplified resist composition that contains a base material component that exhibits changed solubility in a developing solution under action of acid, and an acid generator component that generates acid upon exposure has been conventionally used in the related art.

Recently, as a resist material suitable for reproducing a finer pattern, a resist composition containing a compound containing a metal atom as a base material component has been proposed. In a resist composition containing a metal compound as a base material component, the metal compound exhibits reduced solubility in a developing solution upon exposure, and a negative-tone pattern is formed. Unlike the chemically amplified resist composition, this resist composition is more suitable for forming a fine pattern since acid diffusion is not involved.

For example, PCT International Publication No. WO2014/156374 describes a resist composition containing a complex in which an organic ligand is coordinated to a core of a metal oxide.

Further, Published Japanese Translation No. 2016-530565 of the PCT International Publication describes a resist composition containing a compound in which an organic group is covalently bonded to a core of a metal oxide.

### SUMMARY OF THE INVENTION

A resist composition containing a metal compound as a base material component has low stability, and after a resist film is formed, the resist film tends to be denatured and insoluble. As a result, the solubility of the resist film in a developing solution may decrease even at unexposed portions, and thus the resist film may be difficult to be dissolved during development. Further, there is a problem that the shape of the resist pattern is deteriorated since unexposed portions become difficult to dissolve in a developing solution.

The present invention has been made in consideration of the above circumstances, and an object of the present invention is to provide a resist composition having high stability, excellent lithography characteristics such as a resist pattern shape, and good etching resistance, and a method of forming a resist pattern using the resist composition.

In order to achieve the above-described object, the present invention employs the following configurations.

That is, a first aspect of the present invention is a resist composition containing a metal compound, and a polymer that segregates on a surface of a resist film in a case where the resist film is formed using the resist composition, in which a structure of the metal compound is changed upon exposure, the metal compound exhibits changed solubility in a developing solution, the metal compound contains a metal ion of a metal atom of Group 3 to Group 16 in the long periodic table or a metal oxide of the metal atom, and a bonder that is bonded to the metal ion or the metal oxide, a content of the metal atom contained in the metal ion or the metal oxide is in a range of 0.2% to 3% by mass with respect to a total mass of the resist composition, and the polymer has at least one constitutional unit selected from the group consisting of a constitutional unit (a01) derived from a compound represented by General Formula (a01-1) and a constitutional unit (a02) represented by General Formula (a02-1).

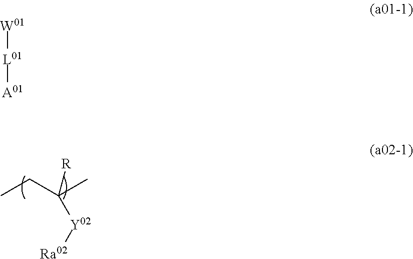

[In General Formula (a01-1), W⁰¹ represents a polymerizable group-containing group; L⁰¹ represents a single bond or a divalent linking group; and A⁰¹ represents a hydrocarbon group which may have a substituent. However, at least one of W⁰¹, L⁰¹, and A⁰¹ contains at least one fluorine atom.

In General Formula (a02-1), R represents a hydrogen atom, an alkyl group having 1 to 5 carbon atoms, a halogenated alkyl group having 1 to 5 carbon atoms (provided that a fluorinated alkyl group is excluded), or a halogen atom (provided that a fluorine atom is excluded); Y⁰² represents a single bond or divalent linking group; and Ra⁰² represents a hydrocarbon group (provided that a group containing an acid dissociable group is excluded.]

A second aspect of the present invention is a method of forming a resist pattern, including a step of forming a resist film on a support using the resist composition according to the first aspect, a step of exposing the resist film, and a step of developing the exposed resist film to form a resist pattern.

According to the present invention, it is possible to provide a resist composition having high stability, excellent lithography characteristics such as a resist pattern shape, and good etching resistance, and a method of forming a resist pattern using the resist composition.

### DETAILED DESCRIPTION OF THE INVENTION

In the present specification and the scope of the present claims, the term “aliphatic” is a relative concept used with respect to the term “aromatic” and defines a group or compound that has no aromaticity.

The “alkyl group” includes linear, branched, and cyclic monovalent saturated hydrocarbon groups, unless otherwise specified. The same applies to an alkyl group in an alkoxy group.

The “alkylene group” includes linear, branched, or cyclic, divalent saturated hydrocarbon groups, unless otherwise specified.

Examples of the “halogen atom” include a fluorine atom, a chlorine atom, a bromine atom, and an iodine atom.

The “constitutional unit” indicates a monomer unit that constitutes the formation of a polymeric compound (a resin, a polymer, or a copolymer).

In a case where “may have a substituent” is described, both of a case where a hydrogen atom (—H) is substituted with a monovalent group and a case where a methylene group (—CH₂—) is substituted with a divalent group are included.

The “exposure” is used as a general concept that includes irradiation with any form of radiation.

The “acid decomposable group” indicates a group in which at least part of bonds in the structure of the acid decomposable group can be cleaved under action of acid.

Examples of the acid decomposable group having polarity that is increased under action of acid include groups that are decomposed under action of acid to generate a polar group.

Examples of the polar group include a carboxy group, a hydroxyl group, an amino group, and a sulfo group (—SO₃H).

More specific examples of the acid decomposable group include a group (for example, a group obtained by protecting a hydrogen atom of the OH-containing polar group with an acid dissociable group) obtained by protecting the above-described polar group with an acid dissociable group.

The “acid dissociable group” indicates any one of (i) a group in which a bond between the acid dissociable group and an atom adjacent to the acid dissociable group can be cleaved under action of acid; and (ii) a group in which part of bonds are cleaved under action of acid, and then a decarboxylation reaction occurs, thereby cleaving the bond between the acid dissociable group and the atom adjacent to the acid dissociable group.”

It is necessary that the acid dissociable group that constitutes the acid decomposable group be a group that exhibits a lower polarity than the polar group generated by the dissociation of the acid dissociable group. Therefore, in a case where the acid dissociable group dissociates under action of acid, a polar group exhibiting a higher polarity than the acid dissociable group is generated, whereby the polarity increases. As a result, the polarity of the entire component (A1) is increased. By the increase in the polarity, the solubility in a developing solution relatively changes. The solubility in a developing solution is increased in a case where the developing solution is an alkali developing solution, whereas the solubility in a developing solution is decreased in a case where the developing solution is an organic developing solution.

The “base material component” is a compound having a film-forming ability. In the present specification, the compound that is used as a base material component is a metal compound (M). As will be described later, the metal compound (M) has a structure in which a metal or a metal oxide is bonded to a bonder, and the metal compounds are crosslinked with each other upon exposure to form a network. The bonder may be an inorganic compound or may be an organic compound.

A “constitutional unit derived from” means a constitutional unit that is formed by the cleavage of a multiple bond between carbon atoms, for example, an ethylenic double bond.

In the “acrylic acid ester”, the hydrogen atom bonded to the carbon atom at the α-position may be substituted with a substituent. The substituent (R^{αx}) that is substituted for the hydrogen atom bonded to the carbon atom at the α-position is an atom other than a hydrogen atom, or a group. Further, an itaconic acid diester in which the substituent (R^{αx}) is substituted with a substituent having an ester bond or an α-hydroxyacryl ester in which the substituent (R^{αx}) is substituted with a hydroxyalkyl group or a group obtained by modifying a hydroxyl group of the hydroxyalkyl group can be mentioned as the acrylic acid ester. A carbon atom at the α-position of acrylic acid ester indicates the carbon atom bonded to the carbonyl group of acrylic acid unless otherwise specified.

Hereinafter, an acrylic acid ester obtained by substituting a hydrogen atom bonded to the carbon atom at the α-position with a substituent is also referred to as an α-substituted acrylic acid ester”.

The “derivative” includes a compound obtained by substituting a hydrogen atom at the α-position of an object compound with another substituent such as an alkyl group or a halogenated alkyl group; and a derivative thereof. Examples of the derivative thereof include a derivative obtained by substituting the hydrogen atom of a hydroxyl group of an object compound in which a hydrogen atom at the α-position may be substituted with a substituent, with an organic group; and a derivative obtained by bonding a substituent other than a hydroxyl group to an object compound in which a hydrogen atom at the α-position may be substituted with a substituent. The α-position refers to the first carbon atom adjacent to the functional group unless otherwise specified.

Examples of the substituent that is substituted for the hydrogen atom at the α-position of hydroxystyrene include the same one as R^{αx}.

In the present specification and the scope of the present claims, asymmetric carbon atoms may be present, and thus enantiomers or diastereomers may be present depending on the structure represented by the chemical formula. In that case, these isomers are represented by one chemical formula. These isomers may be used alone or a mixture thereof may be used.

(Resist Composition)

The resist composition according to the first aspect of the present invention is a resist composition containing a metal compound (M), in which a structure of the metal compound is changed upon exposure, and the metal compound exhibits changed solubility in a developing solution.

Such a resist composition contains a metal compound (M) (hereinafter, also referred to as a “component (M)”) and a polymer (P) (hereinafter, also referred to as a component (P) that segregates on a surface of a resist film in a case where the resist film is formed using the resist composition.

In a case where a resist film is formed using the resist composition according to the present embodiment and the formed resist film is subjected to selective exposure, the component (M) exhibits changed solubility in a developing solution at exposed portions, whereas the component (M) exhibits unchanged solubility in a developing solution at unexposed portions of the resist film, which generates the difference in solubility in the developing solution between the exposed portion and unexposed portions. As a result, in a case where the resist film is subjected to development, exposed portions of the resist film are dissolved and removed to form a positive-tone resist pattern in a case where the resist composition is a positive-tone type, whereas unexposed portions of the resist film are dissolved and removed to form a negative-tone resist pattern in a case where the resist composition is a negative-tone type.

In the present specification, a resist composition which forms a positive-tone resist pattern by dissolving and removing the exposed portions of the resist film is called a positive-tone resist composition, and a resist composition which forms a negative-tone resist pattern by dissolving and removing the unexposed portions of the resist film is called a negative-tone resist composition. The resist composition according to the present embodiment is typically a negative-tone resist composition. Further, in the formation of a resist pattern, the resist composition according to the present embodiment may be applied to an alkali developing process using an alkali developing solution in the developing treatment, or a solvent developing process using a developing solution (an organic developing solution) containing an organic solvent.

<Metal Compound (M)>

The resist composition according to the present embodiment contains a metal compound (M) (a component (M)). The component (M) is a metal compound that contains a metal ion of a metal atom of Group 3 to Group 16 in the long periodic table or a metal oxide of the metal atom, and a bonder that is bonded to the metal ion or the metal oxide. The resist composition of the present embodiment contains the component (M) as a base material component. In a case where the component (M) is used, the base material component exhibits changed solubility in an organic solvent before and after exposure, and thus a good development contrast can be obtained in the solvent developing process.

In a case where the solvent developing process is applied, the base material component including the component (M) has a high solubility in an organic developing solution before exposure, and the solubility in an organic developing solution decreases upon exposure. As a result, in the formation of a resist pattern, in a case where a resist film obtained by applying the resist composition onto a support is subjected to the selective exposure, exposed portions of the resist film changes from a soluble state to a poorly soluble state with respect to an organic developing solution, whereas unexposed portions of the resist film remain soluble and unchanged, whereby a contrast between the exposed portions and the unexposed portions can be obtained, and thus a negative-tone resist pattern is formed by developing in the organic developing solution.

<<Metal Ion or Metal Oxide ((M1) Component)>>

The component (M) contains a metal ion of a metal atom of Group 3 to Group 16 in the long periodic table or a metal oxide of the metal atom (hereinafter, also collectively referred to as “component (M1)”).

Examples of the Group 3 metal atom include scandium (Sc) and yttrium (Y).

Examples of the Group 4 metal atom include titanium (Ti), zirconium (Zr), and hafnium (Hf).

Examples of the Group 5 metal atom include vanadium (V), niobium (Nb), and tantalum (Ta).

Examples of the Group 6 metal atom include chromium (Cr), molybdenum (Mo), and tungsten (W).

Examples of the Group 7 metal atom include manganese (Mn), technetium (Tc), and rhenium (Re).

Examples of the Group 8 metal atom include iron (Fe), ruthenium (Ru), and osmium (Os).

Examples of the Group 9 metal atom include cobalt (Co), rhodium (Rh), and iridium (Ir).

Examples of the Group 10 metal atom include nickel (Ni), palladium (Pd), and platinum (Pt).

Examples of the Group 11 metal atom include copper (Cu), silver (Ag), and gold (Au).

Examples of the Group 12 metal atom include zinc (Zn), cadmium (Cd), and mercury (g).

Examples of the Group 13 metal atom include aluminum (Al), gallium (Ga), indium (In), and thallium (Tl).

Examples of the Group 14 metal atom include germanium (Ga), tin (Sn), and lead (Pb).

Examples of the Group 15 metal atom include antimony (Sb) and bismuth (Bi).

Examples of the Group 16 metal atom include tellurium (Te) and polonium (Po).

The metal atom is preferably a metal atom of Group 3, Group 4, Group 5, Group 6, Group 13, Group 14, or Group 15, and a metal atom of Group 4 or Group 14 is preferable. This metal atom is preferably yttrium, titanium, zirconium, hafnium, tantalum, tungsten, aluminum, tin, or antimony, and more preferably zirconium, hafnium, or tin.

The component (M1) may be a metal ion. The metal ion is not particularly limited as long as it is a metal ion of a metal atom of Group 3 to Group 16 in the long periodic table.

Specific examples of the metal ion include zirconium ion (Zr⁴⁺), hafnium ion (Hf⁴⁺), cobalt (Co²⁺, Co³⁺), nickel (Ni²⁺, Ni³⁺), zinc (Zn²⁺), tin (Sn²⁺, Sn⁴⁺), antimony (Sb³⁺), and tellurium (Te⁴⁺), but are not limited thereto.

The component (M1) may be a metal oxide of a metal atom of Group 3 to Group 16 in the long periodic table. The metal oxide is a compound formed by covalently bonding a metal atom and oxygen. Examples of the metal oxide include metal oxides of the metal atoms described above.

Specific examples of the metal atom constituting the metal oxide include the same metal atoms as the metal atoms described above but are not limited to. Specific examples of the metal oxide include, which are not limited to, metal oxides of Group 3 elements, such as scandium (III) oxide (Sc₂O₃) and yttrium (III) oxide (Y₂O₃); metal oxides of Group 4 elements, such as titanium (IV) oxide (TiO₂), zirconia (ZrO₂), and hafnium (IV) oxide (HfO₂); Group 5 element metal oxides, such as vanadium (V) oxide (V₂O₅), niobium (V) oxide (Nb₂O₅), and tantalum (V) oxide (Ta₂O₅); Group 6 element metal oxides, such as chromium (VI) oxide (CrO₃), molybdenum (VI) oxide (MoO₃), and tungsten (VI) oxide (WO₃); metal oxides of Group 13 elements, such as aluminum (III) oxide (Al₂O₃), gallium (III) oxide (Ga₂O₃), and indium (III) oxide (In₂O₃); metal oxides of Group 14 elements, such as germanium dioxide (GaO₂), tin (II) oxide (SnO), and tin (IV) oxide (SnO₂); and metal oxides of Group 15 elements, such as antimony trioxide (Sb₂O₃).

In addition, the metal oxide may be a hydroxide of the metal oxide. Examples of the hydroxide of the metal oxide include Zr₆O₄(OH)₄, Hf₆O₄(OH)₄, and Sn₁₂O₁₄(OH)₆, but are not limited to.

One kind of the component (M1) may be used alone, or a combination of two or more kinds thereof may be used.

<<Bonder ((M2) Component)>>

The component (M) contains a bonder (M2) that is bonded to a metal ion or a metal oxide (hereinafter, also referred to as a “component (M2)”). The bond type between the metal ion or metal oxide and the bonder is not particularly limited and may be any one of a covalent bond, a coordination bond, and an ionic bond.

The component (M2) is not particularly limited as long as it can be bonded to a metal ion or a metal oxide. Examples of the bonder include an organic group having 1 to 20 carbon atoms an inorganic anion.

The organic group having 1 to 20 carbon atoms preferably has 1 to 15 carbon atoms, more preferably 1 to 12 carbon atoms, and still more preferably 1 to 10 carbon atoms. Examples of the inorganic anion include a hydroxide ion (OH⁻), a hydrogen sulfide ion (SH⁻), a metaphosphate ion (PO₃⁻), and a nitrate ion (NO₃⁻).

Bonder (M2-1) to be Covalently Bonded

Examples of the bonder (hereinafter, also referred to as a “bonder (M2-1)”) that is covalently bonded to a metal ion or a metal oxide include an organic group represented by General Formula (m2-1).

*-Rm¹ (m2-1)

[In the formula, Rm¹ represents a monovalent organic group having 1 to 20 carbon atoms. * Represents a bond to a metal ion or a metal oxide. In a case where two or more Rm¹'s that are bonded to a metal ion or a metal oxide are present, the two or more Rm¹ 's may be bonded to each other to form a divalent or higher valent linking group.]

In General Formula (m2-1), Rm¹ represents a monovalent organic group having 1 to 20 carbon atoms. Examples of the organic group as Rm¹ include a hydrocarbon group having 1 to 20 carbon atoms, which may have a substituent. The hydrocarbon group preferably has 1 to 15 carbon atoms, more preferably 1 to 10 carbon atoms, still more preferably 1 to 6 carbon atoms, and particularly preferably 1 to 3 carbon atoms. The hydrocarbon group may be an aliphatic hydrocarbon group or an aromatic hydrocarbon group.

The aliphatic hydrocarbon group may be saturated or may be unsaturated. The aliphatic hydrocarbon group may be linear or may be branched.

The linear saturated aliphatic hydrocarbon group is preferably an alkyl group having 1 to 15 carbon atoms, more preferably an alkyl group having 1 to 10 carbon atoms, still more preferably an alkyl group having 1 to 6 carbon atoms, and particularly preferably an alkyl group having 1 to 3 carbon atoms.

The linear unsaturated aliphatic hydrocarbon group is preferably an alkenyl group or alkynyl group having 2 to 15 carbon atoms, more preferably an alkenyl group or alkynyl group having 2 to 10 carbon atoms, still more preferably an alkenyl group or alkynyl group having 2 to 6 carbon atoms, and particularly preferably an alkenyl group or alkynyl group having 2 or 3 carbon atoms.

The branched saturated aliphatic hydrocarbon group is preferably a branched alkyl group having 3 to 15 carbon atoms, more preferably a branched alkyl group having 3 to 10 carbon atoms, still more preferably a branched alkyl group having 3 to 6 carbon atoms, and particularly preferably a branched alkyl group having 3 or 4 carbon atoms.

The branched unsaturated aliphatic hydrocarbon group is preferably a branched alkenyl group or alkynyl group having 3 to 15 carbon atoms, more preferably a branched alkenyl group or alkynyl group having 3 to 10 carbon atoms, still more preferably a branched alkenyl group or alkynyl group having 3 to 6 carbon atoms, and particularly preferably a branched alkenyl group or alkynyl group having 3 or 4 carbon atoms.

The aliphatic hydrocarbon group may contain a ring in the structure thereof. Examples of the aliphatic hydrocarbon group containing a ring in the structure thereof include a cyclic aliphatic hydrocarbon group which may have a substituent containing a hetero atom in the ring structure thereof (a group obtained by removing two hydrogen atoms from an aliphatic hydrocarbon ring), a group obtained by bonding the cyclic aliphatic hydrocarbon group to the terminal of a linear or branched aliphatic hydrocarbon group, and a group obtained by interposing the cyclic aliphatic hydrocarbon group in a linear or branched aliphatic hydrocarbon group. The cyclic aliphatic hydrocarbon group preferably has 3 to 15 carbon atoms, more preferably 3 to 10 carbon atoms, and still more preferably 3 to 6 carbon atoms. The cyclic aliphatic hydrocarbon group may be polycyclic or monocyclic.

The aliphatic hydrocarbon group which is a monocyclic group is preferably a group obtained by removing one hydrogen atom from a monocycloalkane. The monocycloalkane preferably has 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane. The polycycloalkane preferably has 7 to 12 carbon atoms, and specific examples thereof include adamantane, norbornane, isobornane, tricyclodecane, and tetracyclododecane.

The organic group as Rm¹ may be an aromatic hydrocarbon group. The aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring preferably has 5 to 20 carbon atoms, more preferably 6 to 15 carbon atoms, and still more preferably 6 to 12 carbon atoms.

Specific examples of the aromatic ring include aromatic hydrocarbon rings such as benzene, naphthalene, anthracene, and phenanthrene; and an aromatic heterocyclic ring obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group include a group obtained by removing one hydrogen atom from the above-described aromatic hydrocarbon ring or aromatic heterocyclic ring (an aryl group or a heteroaryl group); a group obtained by removing one hydrogen atom from an aromatic compound having two or more aromatic rings (biphenyl, fluorene or the like); and a group obtained by substituting one hydrogen atom of the above-described aromatic hydrocarbon ring or aromatic heterocyclic ring with an alkylene group (an arylalkyl group such as a benzyl group, a phenethyl group, a 1-naphthylmethyl group, a 2-naphthylmethyl group, a 1-naphthylethyl group, or a 2-naphthylethyl group). The alkylene group that is bonded to the aromatic hydrocarbon ring or the aromatic heterocyclic ring preferably has 1 to 4 carbon atoms, more preferably 1 to 3 carbon atoms, and particularly preferably 1 or 2 carbon atoms.

The hydrocarbon group as Rm¹ may have a substituent. The substituent may be a substituent that is substituted for a hydrogen atom (—H) of a hydrocarbon chain or may be a substituent that is substituted for a methylene group (—CH₂—) of a hydrocarbon chain.

Examples of the group that is substituted for a hydrogen atom include a carboxy group, a hydroxy group, an amino group, a sulfo group, a nitro group, a thiol group, a cyano group, a phosphoric acid group, a halogen atom, an alkoxy group, and an acyl group, but are not limited thereto. The alkoxy group and the acyl group as the substituent preferably have 1 to 6 carbon atoms, more preferably 1 to 3 carbon atoms, and still more preferably 1 or 2 carbon atoms.

Examples of the group that is substituted for a methylene group include —O—, —C(═O)—O—, —O—C(═O)—, —C(═O)—, —O—C(═O)—O—, —C(═O)—NH—, —NH—C(═O)—, —NH—, —S—, —S(═O)₂—, and —S(═O)₂—O—, but are not limited thereto.

Rm¹ is preferably a hydrocarbon group, more preferably an aliphatic hydrocarbon group, still more preferably a linear or branched aliphatic hydrocarbon group, and even still more preferably a branched saturated aliphatic hydrocarbon group. The saturated aliphatic hydrocarbon group is preferably an alkyl group having 1 to 15 carbon atoms, more preferably an alkyl group having 1 to 10 carbon atoms, still more preferably an alkyl group having 1 to 6 carbon atoms, and particularly preferably an alkyl group having 1 to 3 carbon atoms. Specific examples of Rm¹ include a branched alkyl group having 1 to 15 carbon atoms (for example, a t-butyl group), a linear unsaturated hydrocarbon group having 2 to 15 carbon atoms (for example, a vinyl group), a linear alkyl group having 1 to 15 carbon atoms (for example, a methyl group, an ethyl group, or an n-butyl group), and an aromatic hydrocarbon group having 6 to 15 carbon atoms (for example, a phenyl group). Rm¹ is preferably a branched alkyl group having 1 to 15 carbon atoms (for example, a t-butyl group), a linear unsaturated hydrocarbon group having 2 to 15 carbon atoms (for example, a vinyl group), or a linear alkyl group having 1 to 15 carbon atoms (for example, a methyl group, an ethyl group, or n-butyl group), more preferably a branched alkyl group having 1 to 15 carbon atoms (for example, a t-butyl group) or a linear unsaturated hydrocarbon group having 2 to 15 carbon atoms (for example, a vinyl group), and still more preferably a branched alkyl group having 1 to 15 carbon atoms (for example, a t-butyl group).

In a case where two or more bonders (M2-1) that are bonded to a metal ion or a metal oxide are present, two or more Rm¹'s contained in the two or more bonders (M2-1) may be bonded to each other to form a divalent or higher valent linking group.

One kind of the bonder (M2-1) may be used alone, or a combination of two or more kinds thereof may be used.

Bonder (M2-2) to be Coordinately Bonded

Examples of the bonder (hereinafter, also referred to as “bonder (M2-2)”) that is coordinately bonded to a metal ion or metal oxide include an organic anion or an inorganic anion.

Examples of the inorganic anion include a hydroxide ion (OH⁻), a hydrogen sulfide ion (SH⁻), a metaphosphate ion (PO₃⁻), and a nitrate ion (NO₃⁻).

Examples of the organic anion include an organic anion represented by General Formula (m2-2).

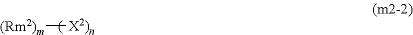

[In the formula, Rm² represents an organic group. X² represents an anionic group. m represents an integer in a range of 0 to 3. n represents an integer in a range of 1 to 4. In a case where n/m is 2 or more, a plurality of Rm²'s may be the same or may be different from each other. In a case where n/m is 2 or more, a plurality of X²'s may be the same or may be different from each other.]

In General Formula (m2-2), Rm² represents an organic group. Examples of the organic group include a hydrocarbon group which may have a substituent. Examples of the hydrocarbon group include a group mentioned as a monovalent hydrocarbon group as Rm¹ in General Formula (m2-1), a group obtained by removing one hydrogen atom from the group mentioned as a monovalent hydrocarbon group as Rm¹ in General Formula (m2-1), a group obtained by removing two hydrogen atoms from the group mentioned as a monovalent hydrocarbon group as Rm¹ in General Formula (m2-1), and a group obtained by removing three hydrogen atoms from the group mentioned as a monovalent hydrocarbon group as Rm¹ in General Formula (m2-1). Preferred examples thereof include a group obtained by removing 1 to 3 hydrogen atoms from the group of the preferred example, mentioned as a monovalent hydrocarbon group as Rm¹ in General Formula (m2-1).

The hydrocarbon group as Rm² may have a substituent. Examples of the substituent include the same ones as those mentioned as the substituent as Rm¹ in General Formula (m2-1).

The group that is substituted for a hydrogen atom is preferably a cyano group, a nitro group, a halogen atom, an alkoxy group, or an acyl group. The alkoxy group and the acyl group as the substituent preferably have 1 to 6 carbon atoms, more preferably 1 to 3 carbon atoms, and still more preferably 1 or 2 carbon atoms.

Examples of the group that is substituted for a methylene group include —O—, —C(═O)—O—, —O—C(═O)—, —C(═O)—, —O—C(═O)—O—, —C(═O)—NH—, —NH—C(═O)—, —NH—, —S—, —S(═O)₂—, and —S(═O)₂—O—, but are not limited thereto.

m represents an integer in a range of 0 to 3.

n represents an integer in a range of 1 to 4. In a case where m is 1, n is preferably in a range of 1 to 3 and more preferably 1 or 2. In a case where m is 2 or 3, n is preferably 1.

Specific examples of Rm² are shown below but are not limited thereto. In the formula, * represents a bond to X² in General Formula (m2-2).

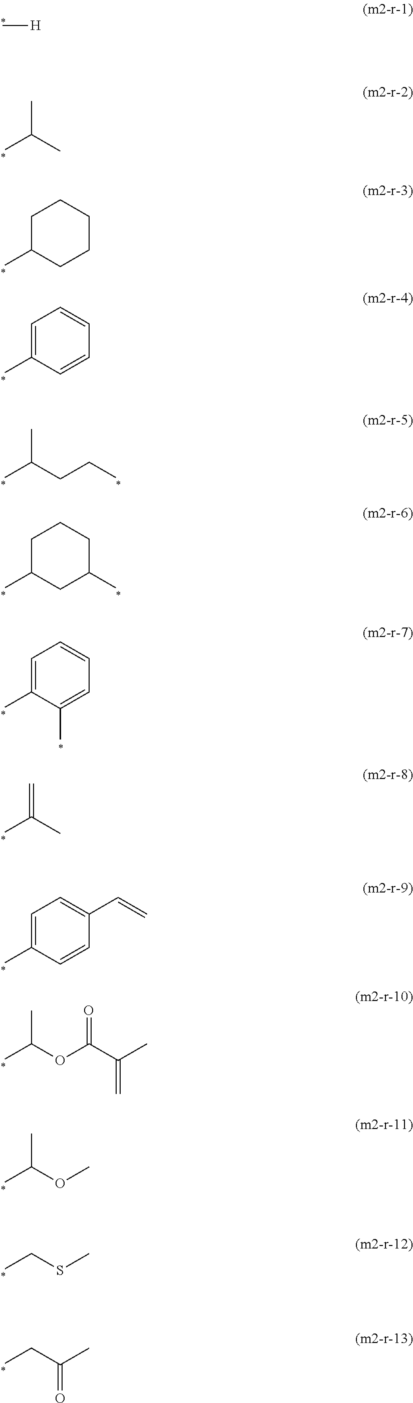

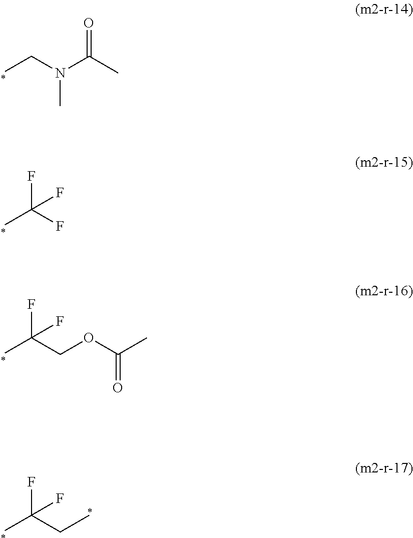

In General Formula (m2-2), X² represents an m/n-valent anionic group. The anionic group is a functional group containing a negatively charged atom. X² is preferably an anionic group containing —O⁻, —S⁻, —SO⁻, —SS⁻, SO₃⁻, P(OH)O₃⁻, —NH⁻, or —N⁻—CO—.

Specific examples of X² are shown below but are not limited thereto. In the formula, * represents a bond to Rm² in General Formula (m2-2).

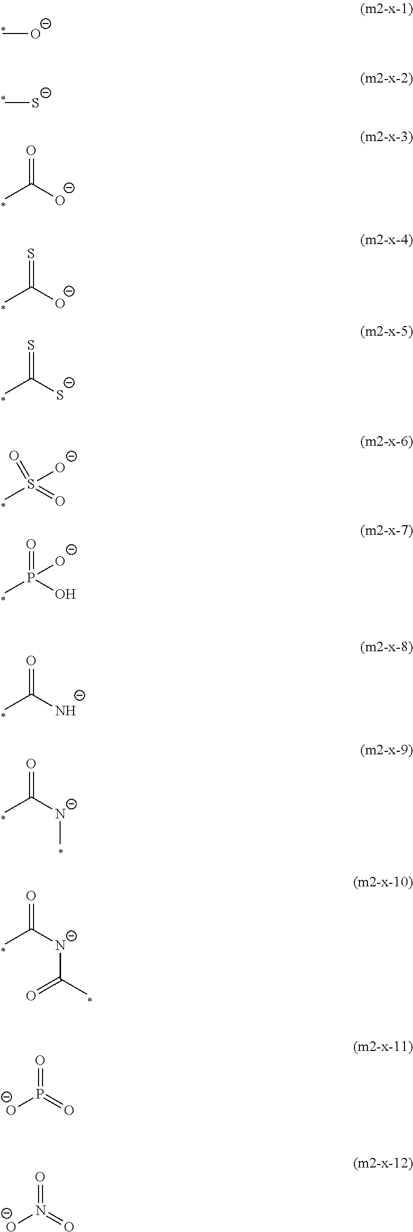

Specific examples of the bonder (M2-2) are shown below but are not limited thereto.

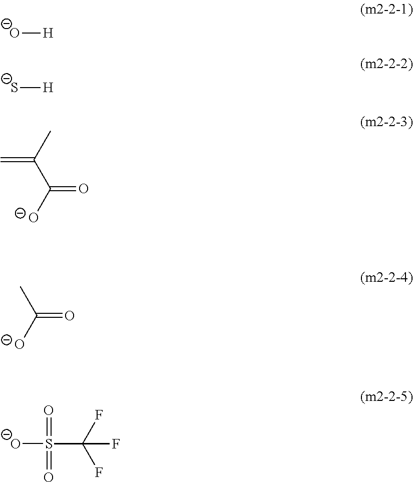

One kind of the bonder (M2-2) may be used alone, or a combination of two or more kinds thereof may be used.

Bonder (M2-3) to be Ionically Bonded

Examples of the bonder (hereinafter, also referred to as “bonder (M2-3)”) that is ionically bonded to a metal ion or metal oxide include an organic anion or an inorganic anion. Examples of the organic anion and the inorganic anion include the same ones as the organic anions and the inorganic anions mentioned in the bonder (M2-2).

One kind of the bonder (M2-3) may be used alone, or a combination of two or more kinds thereof may be used.

In a case where the component (M2) is the bonder (M2-3), the component (M1) is a metal ion of a metal atom of Group 3 to Group 16 in the long periodic table. An example of the component (M) in a case where the component (M2) is the bonder (M2-3) is shown below.

[M₀₂ ^{p⊖}]_{q/p}M₀₁^{q⊕}

q/p

[In the formula, M₀₁ represents a p-valent cation of Group 3 to Group 16 metal atoms in the long periodic table; and M₀₂ represents the bonder (M2) which is a p-valent anion.]

The proportion of the component (M2) with respect to the component (M1) is preferably in a range of 10 to 900 parts by mass, more preferably in a range of 30 to 400 parts by mass, and still more preferably in a range of 30 to 200 parts by mass, with respect to 100 parts by mass of the (M1) component. The molar ratio of the component (M1) to the component (M2) ((M1) component:(M2) component (molar ratio)) is preferably in a range of 1:1 to 1:20, more preferably in a range of 1:4 to 1:14, and still more preferably in a range of 1:12 to 1:14. In a case where the proportion of the component (M2) with respect to the component (M1) is set within the above preferred range, the stability of the resist composition is improved.

The content of the metal atom in the component (M) is preferably in a range of 10% to 80% by mass, more preferably in a range of 20% to 70% by mass, and still more preferably in a range of 30% to 60% by mass. In a case where the content of the metal atom in the component (M) is set within the above preferred range, the stability of the resist composition is improved.

In the resist composition according to the present embodiment, the content of the metal atom (hereinafter, also referred to as a “content of the metal atom”) contained in the metal ion or the metal oxide is in a range of 0.2% to 3% by mass with respect to the total mass (100% by mass) of the resist composition. In a case where the content of the metal atom is within the above range, the function as a negative-tone resist composition is exhibited.

The content of the metal atom with respect to the total mass (100% by mass) of the resist composition can be calculated by the following expression.

Content of metal atom (% by mass)=[(content of metal atom with respect to total mass of component (M)(% by mass))×(total mass of component(M))]/(total mass of resist composition)

In the above expression, the “content of metal atom (% by mass) with respect to total mass of component (M)” can be calculated based on the mass of the metal oxide remaining after heating the component (M) at 600° C. and the mass of the component (M) after being subject to the heating.

The metal compound of the component (M) can be produced by using a known method.

For example, the metal compound of the component (M) can be obtained by reacting a metal alkoxide of the metal constituting the component (M1) with the component (M2) in an appropriate solvent. As the solvent, for example, an alcohol-based solvent, a ketone-based solvent, an amide-based solvent, an ether-based solvent, an ester-based solvent, or a hydrocarbon-based solvent can be used. Specific examples of these solvents include solvents mentioned in the component (S) described later.

Examples of the reaction temperature include 0° C. to 150° C., and 10° C. to 120° C. is preferable. Examples of the reaction time include 30 minutes to 24 hours, and 1 to 20 hours are preferable.

<Polymer (P)>

The resist composition according to the present embodiment contains a polymer (P) (a component (P)) in addition to the above component (M). The component (P) is a polymer that segregates on the surface of the resist film in a case where a resist film is formed using the resist composition. The component (P) has at least one constitutional unit selected from the group consisting of a constitutional unit (a01) derived from a compound represented by General Formula (a0-1) and a constitutional unit (a02) represented by General Formula (a02-1).

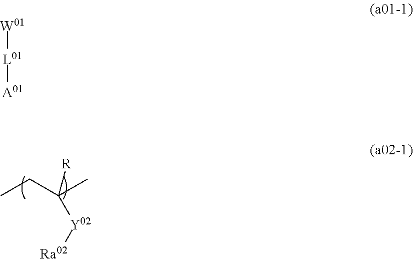

[In General Formula (a01-1), W⁰¹ represents a polymerizable group-containing group; L⁰¹ represents a single bond or a divalent linking group; and A⁰¹ represents a hydrocarbon group which may have a substituent. However, at least one of W⁰¹, L⁰¹, and A⁰¹ contains at least one fluorine atom.

In General Formula (a02-1), R represents a hydrogen atom, an alkyl group having 1 to 5 carbon atoms, a halogenated alkyl group having 1 to 5 carbon atoms (provided that a fluorinated alkyl group is excluded), or a halogen atom (provided that a fluorine atom is excluded); Y⁰² represents a single bond or divalent linking group; and Ra⁰² represents a hydrocarbon group (provided that a group containing an acid dissociable group is excluded.]

The component (P) segregates on the surface of the resist film in a case where the resist film is formed. As a result, the contact between the resist film and the air is suppressed, and the insolubility of the resist film is suppressed.

<<Constitutional Unit (a01)>>

The constitutional unit (a01) is a constitutional unit derived from a compound represented by General Formula (a01-1).

In General Formula (a01-1), W⁰¹ represents a polymerizable group-containing group.

The “polymerizable group” is a group that enables a compound having the polymerizable group to be polymerized by radical polymerization or the like, and includes a group containing a multiple bond between carbon atoms, such as an ethylenic double bond. In the constitutional unit (a01), the multiple bonds in the polymerizable group are cleaved to form a main chain.

Examples of the polymerizable group as W⁰¹ include a vinyl group, an allyl group, acryloyl group, a methacryloyl group, a fluorovinyl group, a difluorovinyl group, a trifluorovinyl group, a difluorotrifluoromethylvinyl group, a trifluoroallyl group, a perfluoroallyl group, a trifluoromethylacryloyl group, a nonylfluorobutylacryloyl group, a vinyl ether group, a fluorine-containing vinyl ether group, an allyl ether group, a fluorine-containing allyl ether group, a styryl group, and a vinylnaphthyl group, a fluorine-containing styryl group, a fluorine-containing vinylnaphthyl group, a norbornyl group, a fluorine-containing norbornyl group, and a silyl group.

The “polymerizable group-containing group” as W⁰¹ may be a group composed of only a polymerizable group, or a group composed of a polymerizable group and a group other than the polymerizable group. Examples of the group other than the polymerizable group include a divalent hydrocarbon group which may have a substituent and a divalent linking group containing a hetero atom.

Divalent Hydrocarbon Group which May have Substituent:

In a case where the group other than the polymerizable group represents a divalent hydrocarbon group which may have a substituent, the hydrocarbon group may be an aliphatic hydrocarbon group or an aromatic hydrocarbon group.

Aliphatic Hydrocarbon Group as a Group Other than the Polymerizable Group

The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

Examples of the aliphatic hydrocarbon group include a linear or branched aliphatic hydrocarbon group, and an aliphatic hydrocarbon group containing a ring in the structure thereof.

Linear or Branched Aliphatic Hydrocarbon Group

The linear aliphatic hydrocarbon group preferably has 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group has preferably 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The linear or branched aliphatic hydrocarbon group may have or may not have a substituent. Examples of the substituent include a fluorine atom, a fluorinated alkyl group having 1 to 5 carbon atoms, which has been substituted with a fluorine atom, and a carbonyl group.

Aliphatic Hydrocarbon Group Containing Ring in Structure Thereof

Examples of the aliphatic hydrocarbon group containing a ring in the structure thereof include a cyclic aliphatic hydrocarbon group which may have a substituent containing a hetero atom in the ring structure thereof (a group obtained by removing two hydrogen atoms from an aliphatic hydrocarbon ring), a group obtained by bonding the cyclic aliphatic hydrocarbon group to the terminal of a linear or branched aliphatic hydrocarbon group, and a group obtained by interposing the cyclic aliphatic hydrocarbon group in a linear or branched aliphatic hydrocarbon group. Examples of the linear or branched aliphatic hydrocarbon group include the same ones as those described above.

The cyclic aliphatic hydrocarbon group preferably has 3 to 20 carbon atoms and more preferably 3 to 12 carbon atoms.

The cyclic aliphatic hydrocarbon group may be a polycyclic group or a monocyclic group. The monocyclic alicyclic hydrocarbon group is preferably a group obtained by removing two hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing two hydrogen atoms from a polycycloalkane, and the polycycloalkane is preferably a group having 7 to 12 carbon atoms. Specific examples of the polycyclic alicyclic hydrocarbon group include adamantane, norbornane, isobornane, tricyclodecane, and tetracyclododecane.

The cyclic aliphatic hydrocarbon group may have or may not have a substituent. Examples of the substituent include an alkyl group, an alkoxy group, a halogen atom, a halogenated alkyl group, a hydroxyl group, and a carbonyl group.

The alkyl group as the substituent is preferably an alkyl group having 1 to 5 carbon atoms, and most preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom for the substituent include a fluorine atom, a chlorine atom, a bromine atom, and an iodine atom, and a fluorine atom is preferable.

Examples of the halogenated alkyl group as the substituent include a group obtained by substituting part or all hydrogen atoms in the above-described alkyl groups with the above-described halogen atoms.

In the cyclic aliphatic hydrocarbon group, part of carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.

Aromatic Hydrocarbon Group as a Group Other than the Polymerizable Group

The aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. Here, the number of carbon atoms in a substituent is not included in the number of carbon atoms. Specific examples of the aromatic ring include aromatic hydrocarbon rings such as benzene, naphthalene, anthracene, and phenanthrene; and an aromatic heterocyclic ring obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group include a group (an arylene group or a heteroarylene group) obtained by removing two hydrogen atoms from the above-described aromatic hydrocarbon ring or the above-described aromatic heterocyclic ring; a group obtained by removing two hydrogen atoms from an aromatic compound (for example, biphenyl or fluorene) having two or more aromatic rings; and a group (for example, a group obtained by further removing one hydrogen atom from an aryl group in the arylalkyl group such as a benzyl group, a phenethyl group, a 1-naphthylmethyl group, a 2-naphthylmethyl group, a 1-naphthylethyl group, or a 2-naphthylethyl group) obtained by substituting one hydrogen atom of a group (an aryl group or a heteroaryl group) obtained by removing one hydrogen atom from the above aromatic hydrocarbon ring or the above aromatic heterocyclic ring, with an alkylene group. The alkylene group bonded to the aryl group or the heteroaryl group preferably has 1 to 4 carbon atoms, more preferably 1 or 2 carbon atoms, and particularly preferably 1 carbon atom.

With respect to the aromatic hydrocarbon group, the hydrogen atom contained in the aromatic hydrocarbon group may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group having 1 to 5 carbon atoms, and most preferably a methyl group, an ethyl group, a propyl group, an n-butyl group, or a tert-butyl group.

Examples of the alkoxy group, the halogen atom, and the halogenated alkyl group, as the substituent, include the same groups as those exemplified as the substituent that is substituted for a hydrogen atom contained in the cyclic aliphatic hydrocarbon group.

Divalent Linking Group Containing Hetero Atom:

In a case where the group other than the polymerizable group represents a divalent linking group containing a hetero atom, preferred examples of the linking group include —O—, —C(═O)—O—, —C(═O)—, —O—C(═O)—O——C(═O)—NH—, —NH—, —NH—C(═NH)— (H may be substituted with a substituent such as an alkyl group, an acyl group, or the like), —S—, —S(═O)₂—, —S(═O)₂—O—, and a group represented by General Formula: —Y²¹—O—Y²², —Y²¹—O—, —Y²¹—C(═O)—O—, —C(═O)—O—Y²¹—, —[Y²¹—C(═O)—O]ₘ″-Y²²—, —Y²¹—O—C(═O)—Y²²— or —Y²¹—S(═O)₂—O—Y²²— [in the formulae, Y²¹ and Y²² each independently represent a divalent hydrocarbon group which may have a substituent, O represents an oxygen atom, and m″ represents an integer in a range of 0 to 3].

In a case where the divalent linking group containing a hetero atom is —C(═O)—NH—, —C(═O)—NH—C(═O)—, —NH—, or —NH—C(═NH)—, H may be substituted with a substituent such as an alkyl group, an acyl group, or the like. The substituent (an alkyl group, an acyl group, or the like) preferably has 1 to 10 carbon atoms, more preferably 1 to 8 carbon atoms, and particularly preferably 1 to 5 carbon atoms.

In General Formulae —Y²¹—O—Y²²—, —Y²¹—O—, —Y²¹—C(═O)—O—, —C(═O)—O—Y²¹—, —[Y²¹—C(═O)—O]ₘ″-Y²²—, —Y²¹—O—C(═O)—Y²²—, and —Y²¹—S(═O)₂—O—Y²²—, Y²¹, and Y²² each independently represent a divalent hydrocarbon group which may have a substituent. Examples of the divalent hydrocarbon group include the same one as the divalent hydrocarbon group which may have a substituent, mentioned in the explanation of the above-described divalent linking group.

Y²¹ is preferably a linear aliphatic hydrocarbon group, more preferably a linear alkylene group, still more preferably a linear alkylene group having 1 to 5 carbon atoms, and particularly preferably a methylene group or an ethylene group.

Y²² is preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by Formula —[Y²¹—C(═O)—O]ₘ″-Y²²—, m″ represents an integer in a range of 0 to 3, preferably an integer in a range of 0 to 2, more preferably 0 or 1, and particularly preferably 1. In other words, it is particularly preferable that the group represented by Formula —[Y²¹—C(═O)—O]ₘ″-Y²²— represents a group represented by Formula —Y²¹—C(═O)—O—Y²²—. Among them, a group represented by Formula —(CH₂)_{a′}—C(═O)—O—(CH₂)_{b′}— is preferable. In the formula, a′ represents an integer in a range of 1 to 10, preferably an integer in a range of 1 to 8, more preferably an integer in a range of 1 to 5, still more preferably 1 or 2, and most preferably 1. b′ represents an integer in a range of 1 to 10, preferably an integer in a range of 1 to 8, more preferably an integer in a range of 1 to 5, still more preferably 1 or 2, and most preferably 1.

Suitable examples of the polymerizable group-containing group as W⁰¹ include a group represented by a chemical formula: C(R^{X11})(R^{X12})═C(R^{X13})-Ya^{x0}. In the chemical formula, R^{X11}, R^{X12}, and R^{X13} each independently represent a hydrogen atom, an alkyl group having 1 to 5 carbon atoms, or a halogenated alkyl group having 1 to 5 carbon atoms, and Ya^{x0} represents a single bond or a divalent linking group.

The alkyl group having 1 to 5 carbon atoms as R^{X11}, R^{X12}, and R^{X13} is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group obtained by substituting part or all hydrogen atoms in the alkyl group having 1 to 5 carbon atoms with a halogen atom. The halogen atom is particularly preferably a fluorine atom.

Among these, R^{X11} and R^{X12} are each preferably a hydrogen atom, an alkyl group having 1 to 5 carbon atoms, or a fluorinated alkyl group having 1 to 5 carbon atoms, and in terms of industrial availability, a hydrogen atom or a methyl group is more preferable.

In addition, R^{X13} is preferably a hydrogen atom, an alkyl group having 1 to 5 carbon atoms, or a fluorinated alkyl group having 1 to 5 carbon atoms, and in terms of industrial availability, a hydrogen atom or a methyl group is more preferable.

The divalent linking group as Ya^{x0} is not particularly limited, and suitable examples thereof include a divalent hydrocarbon group which may have a substituent and a divalent linking group having a hetero atom, each of which is the same as that described above.

Among the above, Ya^{x0} is preferably an ester bond [—C(═O)—O— or —O—C(═O)—], an ether bond (—O—), a linear or branched alkylene group, an aromatic hydrocarbon group, or a combination thereof, or a single bond. Among these, Ya^{x0} is more preferably a group composed of a combination of an ester bond [—C(═O)—O— or —O—C(═O)—] and a linear alkylene group or a single bond. Ya^{x0} is preferably a single bond.

In General Formula (a01-1), L⁰¹ represents a single bond or a divalent linking group.

Examples of the divalent linking group as L⁰¹ include the same one as the divalent hydrocarbon group which may have a substituent, other than the polymerizable group as W⁰¹, and a divalent linking group containing a hetero atom.

In General Formula (a01-1), A⁰¹ represents a hydrocarbon group which may have a substituent.

Examples of the hydrocarbon group which may have a substituent, as A⁰¹, include the same one as the hydrocarbon group which may have a substituent, mentioned as the monovalent organic group as R^{m1} in General Formula (m2-1). The hydrocarbon group as A⁰¹ preferably has 1 to 20 carbon atoms, more preferably 1 to 15 carbon atoms, and still more preferably 1 to 12 carbon atoms.

In General Formula (a0-1), at least one of W⁰¹, L⁰¹, and A⁰¹ contains at least one fluorine atom. The number of fluorine atoms contained in W⁰¹, L⁰¹, and A⁰¹ is not particularly limited. The total number of fluorine atoms contained in the constitutional unit (a01) is preferably 2 or more and more preferably 3 or more. The upper limit value of the total number of fluorine atoms is not particularly limited; however, it is, for example, 15 or less and preferably 10 or less. 1% or more of hydrogen atoms contained in the hydrocarbon group as W⁰¹, L⁰¹, and A⁰¹ may be substituted with a fluorine atom, 10% or more thereof is preferably substituted with a fluorine atom, or 20% or more thereof is more preferably substituted with a fluorine atom, and 100% thereof may be substituted with a fluorine atom.

The constitutional unit (a01) is preferably a constitutional unit derived from a compound represented by General Formula (a01-2).

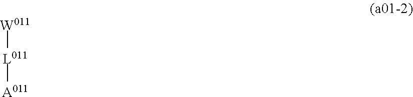

[In the formulae, W⁰¹¹ represents a polymerizable group-containing group; L⁰¹¹ represents a single bond or —CO—O—; and A⁰¹¹ represents a hydrocarbon group which may have a substituent containing a fluorine atom.]

In General Formula (a01-2), W⁰¹¹ represents a polymerizable group-containing group.

Examples of the polymerizable group-containing group as W⁰¹¹ include the same ones as those mentioned in W⁰¹ in General Formula (a01-1).

In General Formula (a01-2), L⁰¹¹ represents a single bond or —CO—O—.

In General Formula (a01-2), A⁰¹¹ represents a hydrocarbon group which may have a substituent containing a fluorine atom.

Examples of the hydrocarbon group which may have a substituent containing a fluorine atom, as A⁰¹¹, include those containing one or more fluorine atoms, mentioned as A⁰¹ in General Formula (a01-1). The number of fluorine atoms contained in A⁰¹¹ is preferably 2 or more and more preferably 3 or more. The upper limit value of the total number of fluorine atoms is not particularly limited; however, it is, for example, 15 or less and preferably 10 or less. 1% or more of hydrogen atoms contained in the hydrocarbon group as A⁰¹¹ may be substituted with a fluorine atom, 10% or more thereof is preferably substituted with a fluorine atom, or 20% or more thereof is more preferably substituted with a fluorine atom, and 100% thereof may be substituted with a fluorine atom.

A⁰¹¹ is preferably a linear or branched fluorinated alkyl group or a group containing a linear or branched fluorinated alkylene group. A⁰¹¹ is more preferably a group containing a trifluoromethyl group.

The constitutional unit (a01) is preferably a constitutional unit derived from a compound represented by General Formula (a01-2-1), General Formula (a01-2-2), or General Formula (a01-2-3).

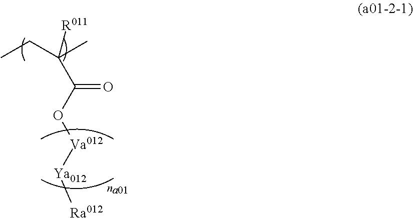

[In General Formula (a01-2-1), R⁰¹¹ represents a hydrogen atom, an alkyl group having 1 to 5 carbon atoms, a halogenated alkyl group having 1 to 5 carbon atoms, or a halogen atom; Va⁰¹² represents a divalent hydrocarbon group which may have a substituent; Ya⁰¹² represents —CO—O— or —O—CO—; Ra⁰¹² represents a hydrocarbon group which may have a substituent; and nₐ₀₁ represents an integer in a range of 0 to 2. However, at least one of Va⁰¹² and Ra⁰¹² contains at least one fluorine atom. In a case where nₐ₀₁ is 2, a plurality of Va⁰¹²'s and Ya⁰¹²'s may be the same or different from each other.]

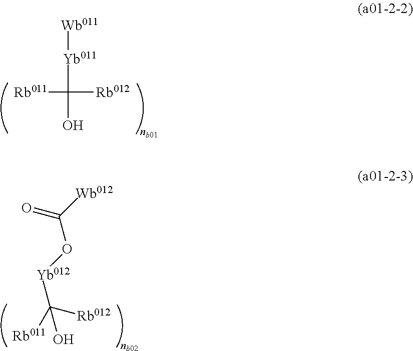

[In the formula, Rb⁰¹¹ represents a fluorinated alkyl group having 1 to 12 carbon atoms. Rb⁰¹² represents an organic group having 1 to 12 carbon atoms, which may have a fluorine atom, or a hydrogen atom. Wb⁰¹¹ and Wb⁰¹² represent a polymerizable group-containing group. Yb⁰¹¹ represents a single bond or an (n_{b01}+1)-valent linking group. Yb⁰¹¹ and Wb⁰¹¹ may form a condensed ring. Yb⁰¹² represents a single bond or an (n_{b02}+1)-valent linking group. n_{b01} and n_{b02} represent an integer in a range of 1 to 3.]

In General Formula (a01-2-1), R⁰¹¹ represents a hydrogen atom, an alkyl group having 1 to 5 carbon atoms, a halogenated alkyl group having 1 to 5 carbon atoms, or a halogen atom.

The alkyl group having 1 to 5 carbon atoms as R is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group obtained by substituting part or all hydrogen atoms in the alkyl group having 1 to 5 carbon atoms with a halogen atom. The halogen atom is particularly preferably a fluorine atom.

R is preferably a hydrogen atom, an alkyl group having 1 to 5 carbon atoms, or a fluorinated alkyl group having 1 to 5 carbon atoms, and in terms of industrial availability, a hydrogen atom or a methyl group is most preferable.

In General Formula (a01-2-1), Va⁰¹² represents a divalent hydrocarbon group which may have a substituent. Examples of the divalent hydrocarbon group as Va⁰¹² include the same one as the divalent hydrocarbon group which may have a substituent, other than the polymerizable group as W⁰¹ in General Formula (a01-1). The divalent hydrocarbon group as Va⁰¹² preferably has 1 to 10 carbon atoms, more preferably 1 to 6 carbon atoms, and still more preferably 1 to 4 carbon atoms.

Va⁰¹² is preferably a saturated aliphatic hydrocarbon group and more preferably a linear, branched, or cyclic alkylene group.

In General Formula (a01-2-1), Ya⁰¹² represents —CO—O— or —O—CO—.

In General Formula (a01-2-1), Ra⁰¹² represents a hydrocarbon group which may have a substituent.

Examples of the hydrocarbon group as Ra⁰¹² include the same one as the hydrocarbon group which may have a substituent, mentioned as the monovalent organic group as Rm¹ in General Formula (m2-1). The hydrocarbon group as Ra⁰¹² preferably has 1 to 15 carbon atoms, more preferably 1 to 10 carbon atoms, and still more preferably 1 to 6 carbon atoms.

Ra⁰¹² is preferably a saturated aliphatic hydrocarbon group and more preferably a linear, branched, or cyclic alkyl group.

In General Formula (a01-2-1), nₐ₀₁ represents an integer in a range of 0 to 2. In a case where nₐ₀₁ is 2, a plurality of Va⁰¹²'s may be the same or different from each other. In a case where nₐ₀₁ is 2, a plurality of Ya⁰¹²'s may be the same or different from each other.

In General Formula (a01-2-1), at least one of Va⁰¹² and Ra⁰¹² contains at least one fluorine atom. The total number of fluorine atoms contained in Va⁰¹² and Ra⁰¹² is not particularly limited; however, it is preferably 2 or more and more preferably 3 or more. Examples of the upper limit value of the total number of fluorine atoms contained in Va⁰¹² and Ra⁰¹² include 15 or less, and 10 or less. 1% or more of hydrogen atoms contained in the hydrocarbon group as Va⁰¹² and Ra⁰¹² may be substituted with a fluorine atom, 10% or more thereof is preferably substituted with a fluorine atom, or 20% or more thereof is more preferably substituted with a fluorine atom, and 100% thereof may be substituted with a fluorine atom.

In a case where Va⁰¹² contains a fluorine atom, Va⁰¹² is a divalent group obtained by substituting part or all hydrogen atoms of a hydrocarbon group with a fluorine atom. Va⁰¹² is preferably a linear or branched fluorinated alkylene group having 1 to 10 carbon atoms and more preferably a linear or branched fluorinated alkylene group having 1 to 6 carbon atoms.

In a case where Ra⁰¹² contains a fluorine atom, Ra⁰¹² is a monovalent group obtained by substituting part or all hydrogen atoms of a hydrocarbon group with a fluorine atom. Ra⁰¹² is preferably a linear or branched fluorinated alkyl group having 1 to 10 carbon atoms and more preferably a linear or branched fluorinated alkyl group having 1 to 6 carbon atoms. Ra⁰¹² more preferably contains a trifluoromethyl group.

In General Formulae (a01-2-2) and (a01-2-3), Wb⁰¹¹ and Wb⁰¹² represent a polymerizable group-containing group.

Examples of the polymerizable group-containing group as Wb⁰¹¹ and Wb⁰¹² include the same ones as those mentioned in W⁰¹ in General Formula (a01-1).

In General Formulae (a01-2-2) and (a01-2-3), Rb⁰¹¹ represents a fluorinated alkyl group having 1 to 12 carbon atoms.

The fluorinated alkyl group having 1 to 12 carbon atoms is a group in which part or all hydrogen atoms in the alkyl group having 1 to 12 carbon atoms have been substituted with a fluorine atom. The alkyl group may be linear or branched.

Specific examples of the linear fluorinated alkyl group having 1 to 12 carbon atoms include a methyl group, an ethyl group, a propyl group, a butyl group, a pentyl group, a hexyl group, a heptyl group, an octyl group, a nonyl group, a decyl group, and an undecyl group, a group in which part or all hydrogen atoms of a dodecyl group are substituted with a fluorine atom. Specific examples of the branched fluorinated alkyl group having 1 to 12 carbon atoms include a 1-methylethyl group, a 1,1-dimethylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a group in which part or all hydrogen atoms of a 4-methylpentyl group are substituted with a fluorine atom.

Among the above, the fluorinated alkyl group having 1 to 12 carbon atoms as Rb⁰¹¹ is preferably a fluorinated alkyl group having 1 to 5 carbon atoms and specifically, particularly preferably a trifluoromethyl group.

In General Formulae (a01-2-2) and (a01-2-3), Rb⁰¹² represents an organic group having 1 to 12 carbon atoms, which may have a fluorine atom, or a hydrogen atom.

Examples of the organic group having 1 to 12 carbon atoms as Rb⁰¹², which may have a fluorine atom, include a monovalent hydrocarbon group which may have a substituent.

Examples of the hydrocarbon group include a linear or branched alkyl group and a cyclic hydrocarbon group. Examples of the linear or branched alkyl group include the same one as the fluorinated alkyl group having 1 to 12 carbon atoms as Rb⁰¹¹.

In a case where Rb⁰¹² represents a cyclic hydrocarbon group, the hydrocarbon group may be an aliphatic hydrocarbon group or an aromatic hydrocarbon group and may be a polycyclic group or a monocyclic group.

The aliphatic hydrocarbon group which is a monocyclic group is preferably a group obtained by removing one hydrogen atom from a monocycloalkane. The monocycloalkane preferably has 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane. The polycycloalkane preferably has 7 to 12 carbon atoms, and specific examples thereof include adamantane, norbornane, isobornane, tricyclodecane, and tetracyclododecane.

In a case where the cyclic hydrocarbon group as Rb⁰¹² is an aromatic hydrocarbon group, the aromatic hydrocarbon group is a hydrocarbon group having at least one aromatic ring. Specific examples of the aromatic hydrocarbon group include a group obtained by removing one hydrogen atom from an aromatic hydrocarbon ring such as benzene, biphenyl, fluorene, naphthalene, anthracene, or phenanthrene.

The organic group having 1 to 12 carbon atoms as Rb⁰¹² may have a substituent other than a fluorine atom. Examples of the substituent include a hydroxy group, a carboxy group, a halogen atom (a fluorine atom, a chlorine atom, a bromine atom, and the like), an alkoxy group (a methoxy group, an ethoxy group, a propoxy group, a butoxy group, and the like), and an alkyloxycarbonyl group.

Rb⁰¹² is preferably a fluorinated alkyl group having 1 to 12 carbon atoms, more preferably a fluorinated alkyl group having 1 to 5 carbon atoms, and still more preferably a trifluoromethyl group.

In General Formula (a01-2-2), Yb⁰¹¹ represents a single bond or an (n_{b01}+1)-valent, that is, a divalent, trivalent, or tetravalent linking group.

Examples of the divalent linking group as Yb⁰¹¹ include the same one as the divalent hydrocarbon group which may have a substituent, other than the polymerizable group as W⁰¹ in General Formula (a01-1).

Examples of the trivalent linking group as Yb⁰¹¹ include a group obtained by removing one hydrogen atom from the above-described divalent linking group as Yb⁰¹¹ and a group obtained by bonding the divalent linking group to another divalent linking group.

Examples of the tetravalent linking group as Yb₀₁₁ include a group obtained by removing two hydrogen atoms from the divalent linking group as Yb⁰¹¹.

Yb⁰¹¹ and Wb⁰¹¹ may form a condensed ring.

In a case where Yb⁰¹¹ and Wb⁰¹¹ form a condensed ring, examples of the ring structure of the condensed ring include a condensed ring of an alicyclic hydrocarbon and an aromatic hydrocarbon. The condensed ring formed by Yb⁰¹¹ and Wb⁰¹¹ may have a hetero atom.

The alicyclic hydrocarbon moiety in the condensed ring formed by Yb⁰¹¹ and Wb⁰¹¹ may be a monocyclic ring or a polycyclic ring.

Examples of the condensed ring formed by Yb⁰¹¹ and Wb⁰¹¹ include a condensed ring formed by a polymerizable group of the Wb⁰¹¹ moiety and by Yb⁰¹¹ and a condensed ring formed by a group other than the polymerizable group of the Wb⁰¹¹ moiety and by Yb⁰¹¹. Specific examples thereof include a bicyclic condensed ring of a cycloalkene and an aromatic ring, a tricyclic condensed ring of a cycloalkene and two aromatic rings, and a bicyclic condensed ring of a cycloalkane having a polymerizable group as a substituent and an aromatic ring, and a tricyclic condensed ring of a cycloalkane having a polymerizable group as a substituent and an aromatic ring.

The condensed ring formed by Yb⁰¹¹ and Wb⁰¹¹ may have a substituent. Examples of this substituent include a methyl group, an ethyl group, propyl group, a hydroxy group, a hydroxyalkyl group, a carboxy group, a halogen atom (a fluorine atom, a chlorine atom, a bromine atom, and the like), an alkoxy group (a methoxy group, an ethoxy group, a propoxy group, a butoxy group, and the like), an acyl group, an alkyloxycarbonyl group, and an alkylcarbonyloxy group.

Specific examples of the condensed ring formed by Yb⁰¹¹ and Wb⁰¹¹ are shown below. W^{α} represents a polymerizable group. ** indicates a bond to the carbon atom to which Rb⁰¹¹ and Rb⁰¹² are bonded.

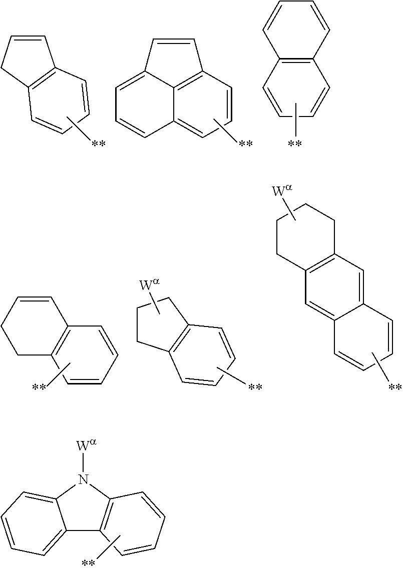

In General Formula (a01-2-3), Yb⁰¹² represents a single bond or an (n_{b02}+1)-valent linking group. Examples of Yb⁰¹² include the same one as Yb⁰¹¹.

In General Formulae (a01-2-2) and (a01-2-3), n_{b01} and n_{b02} are an integer in a range of 1 to 3, and they are preferably 1 or 2 and more preferably 1.

Specific examples of the constitutional unit (a01) are shown below but are not limited thereto.

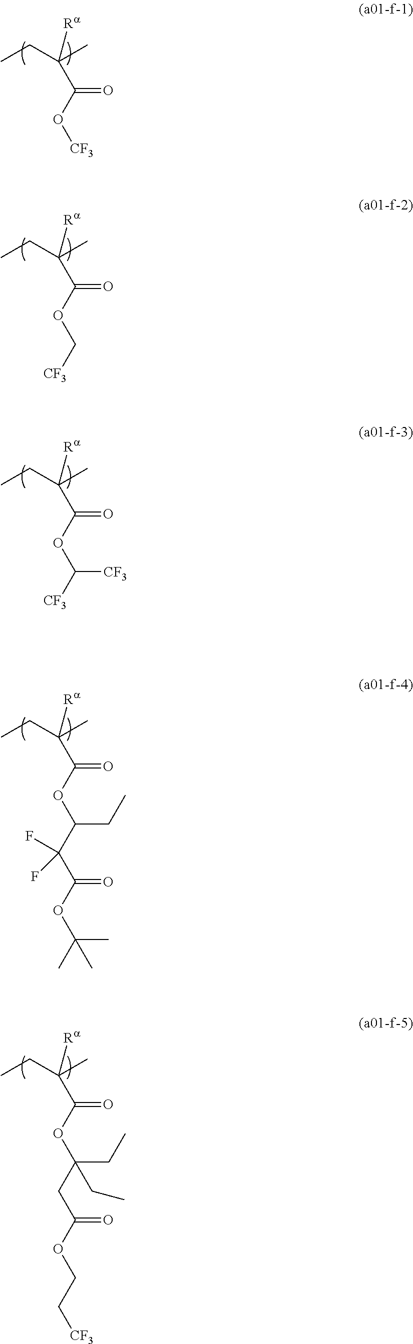

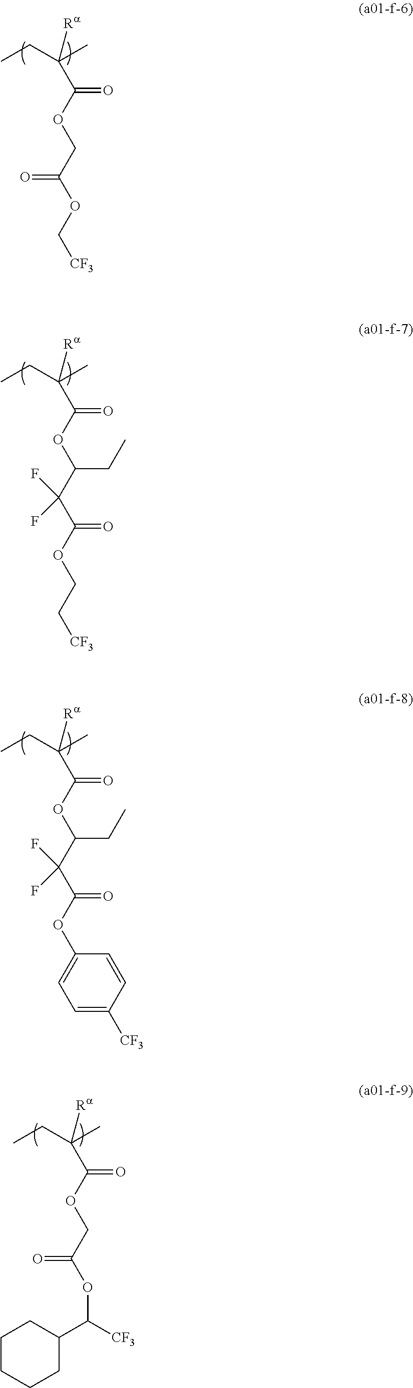

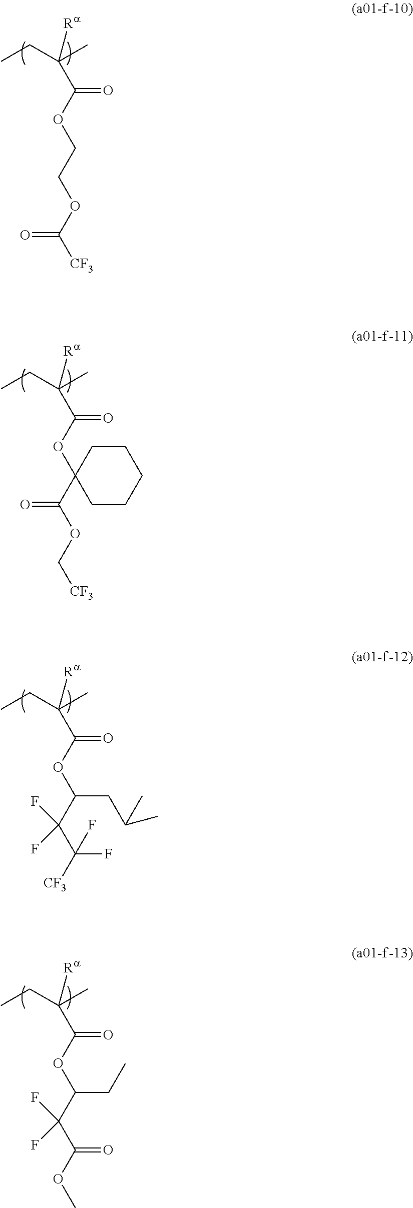

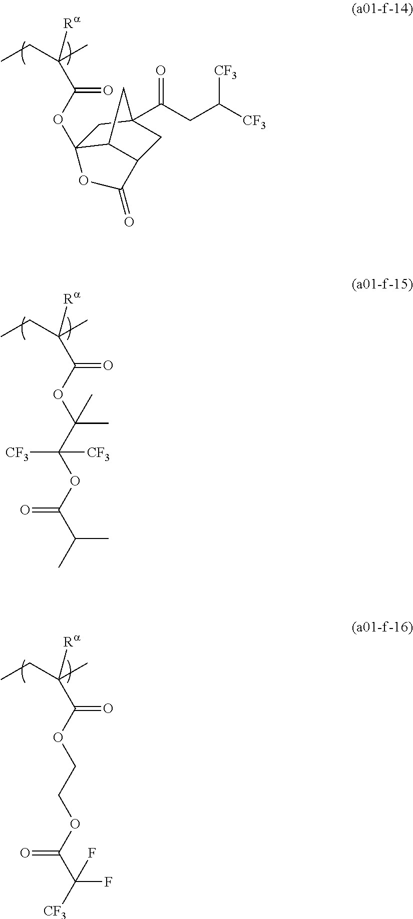

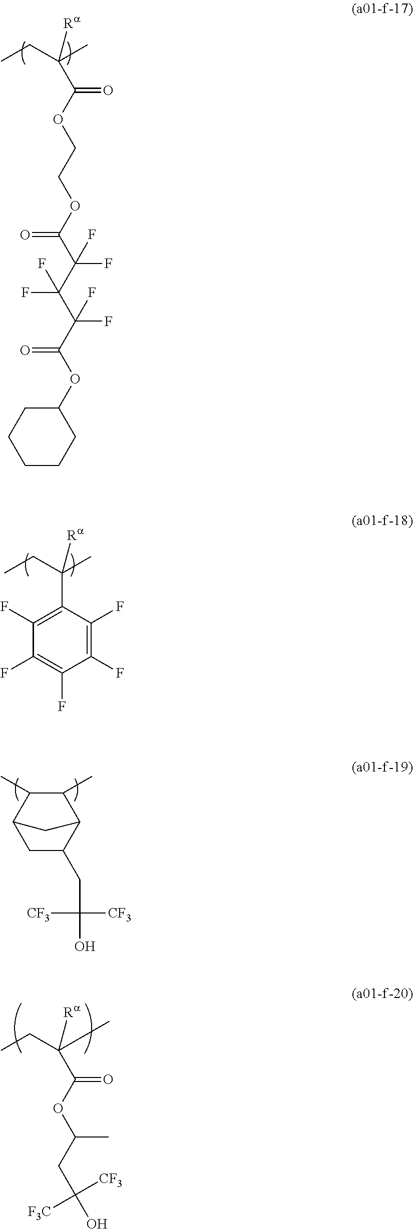

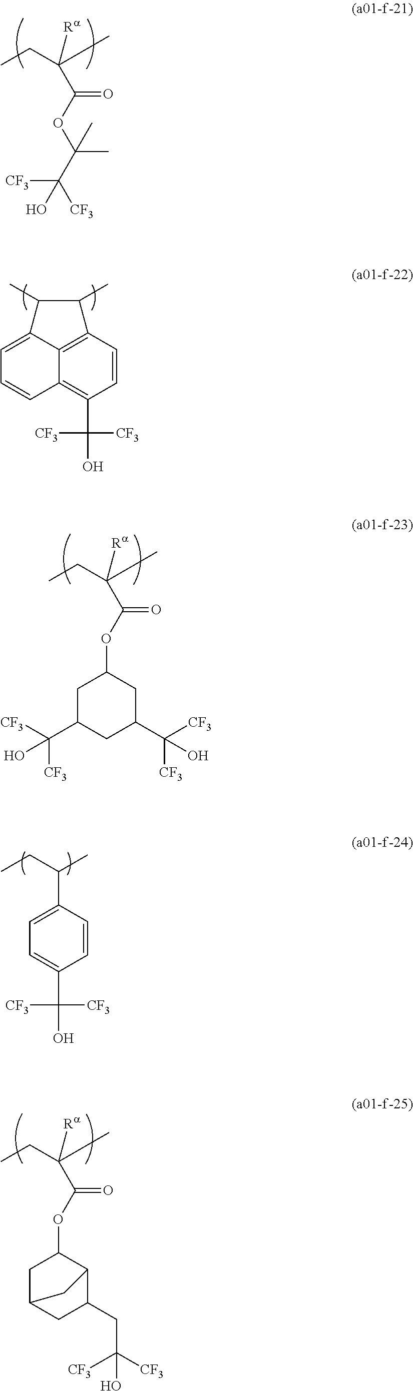

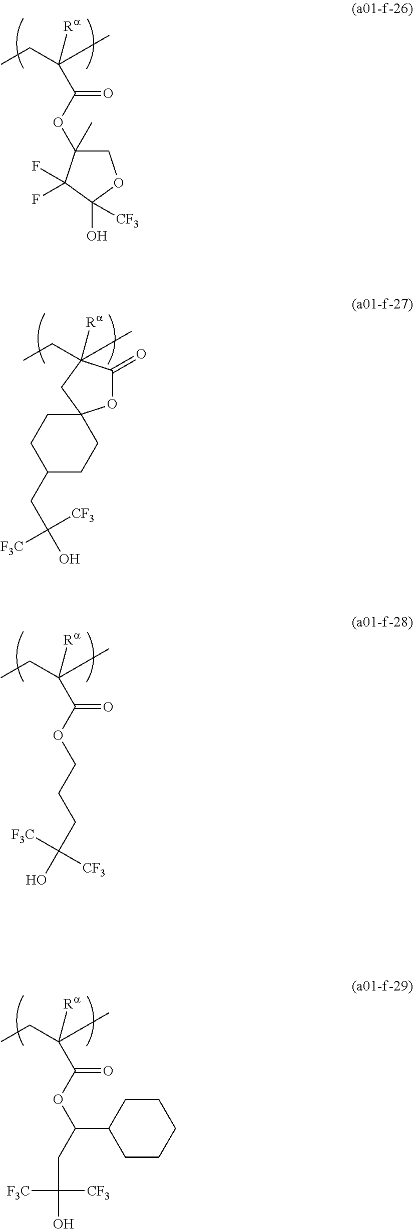

The constitutional unit (a01) contained in the component (P) may be one kind or may be two or more kinds.

The component (P) preferably has a constitutional unit (a01). In a case where the component (P) has a constitutional unit (a01), the proportion of the constitutional unit (a01) in the component (P) is preferably 10% by mole or more, more preferably 30% by mole or more, still more preferably 50% by mole or more, or particularly preferably 60% by mole or more, and it may be 100% by mole, with respect to the total (100% by mole) of all constitutional units constituting the component (P).

In a case where the proportion of the constitutional unit (a01) is set to be equal to or larger than the lower limit value of the above preferred range, the insolubility of the resist film is further suppressed, and thus the lithography characteristics such as the pattern shape are improved.

<<Constitutional Unit (a02)>>

The constitutional unit (a02) is a constitutional unit represented by General Formula (a02-1). The constitutional unit (a02) is a constitutional unit that does not contain a fluorine atom. Among the constitutional units represented by General Formula (a02-1), those corresponding to the constitutional unit (a01) are excluded.

In General Formula (a02-1), R represents a hydrogen atom, an alkyl group having 1 to 5 carbon atoms, or a halogenated alkyl group having 1 to 5 carbon atoms. R is the same as R⁰¹¹ in General Formula (a01-2-1). However, a fluorinated alkyl group is excluded from the halogenated alkyl group as R. The fluorine atom is excluded from the halogen atom as R.

In General Formula (a02-1), Y⁰² represents a single bond or a divalent linking group.

Examples of the divalent linking group as Y⁰² include the same one as the divalent hydrocarbon group which may have a substituent, other than the polymerizable group as W⁰¹ in General Formula (a01-1), and a divalent linking group containing a hetero atom.

In General Formula (a02-1), Ra⁰² represents a hydrocarbon group (however, a group containing an acid dissociable group is excluded).

Examples of the hydrocarbon group as Ra⁰² include a hydrocarbon group having 1 to 20 carbon atoms. However, those containing an acid dissociable group are excluded from the hydrocarbon group as Ra⁰². Examples of the acid dissociable group include an acid dissociable group described in the constitutional unit (a1) described later.

The hydrocarbon group as Ra⁰² preferably has 1 to 20 carbon atoms, more preferably 1 to 15 carbon atoms, and still more preferably 1 to 12 carbon atoms. The hydrocarbon group as Ra⁰² may be an aliphatic hydrocarbon group or an aromatic hydrocarbon group; however, an aliphatic hydrocarbon group is preferable. Examples of the aliphatic hydrocarbon group and the aromatic hydrocarbon group include the same ones as those mentioned in Rm¹ in General Formula (m2-1).

Examples of the constitutional unit (a02) include the following constitutional unit (a5) and constitutional unit (a12).

Constitutional Unit (a5)

The constitutional unit (a02) may be a constitutional unit (a5) containing an acid non-dissociable aliphatic hydrocarbon group. The “acid non-dissociable aliphatic hydrocarbon group” in the constitutional unit (a5) is an aliphatic hydrocarbon group that does not dissociate even in a case where an acid acts.

Examples of the constitutional unit (a5) preferably include a constitutional unit derived from an acrylic acid ester including an acid non-dissociable aliphatic hydrocarbon group. As the aliphatic hydrocarbon group, a large number of cyclic groups known in the related art as cyclic groups that are used in resin components of resist compositions for an ArF excimer laser, a KrF excimer laser (preferably an ArF excimer laser), and the like, can be used.

The aliphatic hydrocarbon group may be saturated or unsaturated; however, it is preferably saturated. The aliphatic hydrocarbon group may be linear or may be branched, and may contain a ring in the structure thereof.

The linear aliphatic hydrocarbon group preferably has 1 to 20 carbon atoms, more preferably 1 to 15 carbon atoms, and still more preferably 1 to 10 carbon atoms.

The branched aliphatic hydrocarbon group preferably has 2 to 20 carbon atoms, more preferably 3 to 15 carbon atoms, and still more preferably 3 to 10 carbon atoms.

The aliphatic hydrocarbon group containing a ring in the structure thereof preferably has 3 to 20 carbon atoms, more preferably 3 to 15 carbon atoms, and still more preferably 3 to 12 carbon atoms. The aliphatic hydrocarbon group containing a ring in the structure is particularly preferably at least one selected from a tricyclodecyl group, an adamantyl group, a tetracyclododecyl group, an isobornyl group, and a norbornyl group, from the viewpoint of industrial availability. These polycyclic groups may have, as a substituent, a linear or branched alkyl group having 1 to 5 carbon atoms.

The aliphatic hydrocarbon group contained in the constitutional unit (a5) is preferably an aliphatic hydrocarbon group containing a ring in the structure, more preferably an alicyclic aliphatic hydrocarbon group, and still preferably a polycyclic aliphatic hydrocarbon group.

The constitutional unit (a5) is preferably a constitutional unit represented by General Formula (a5-1).

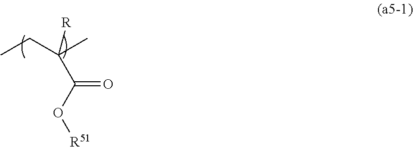

[In the formula, R is the same as R in General Formula (a02-1). R⁵¹ represents an aliphatic hydrocarbon group.]

In General Formula (a5-1), R is the same as R in General Formula (a02-1).

In General Formula (a5-1), R⁵¹ represents an aliphatic hydrocarbon group. The aliphatic hydrocarbon group is the same as described above. The aliphatic hydrocarbon group as R⁵¹ is preferably an aliphatic hydrocarbon group containing a ring in the structure thereof, more preferably an alicyclic hydrocarbon group, and still preferably a polycyclic aliphatic hydrocarbon group.

Specific examples of the constitutional unit (a5) are shown below but are not limited thereto. In each of the following formulae, R^{α} represents a hydrogen atom or a methyl group.

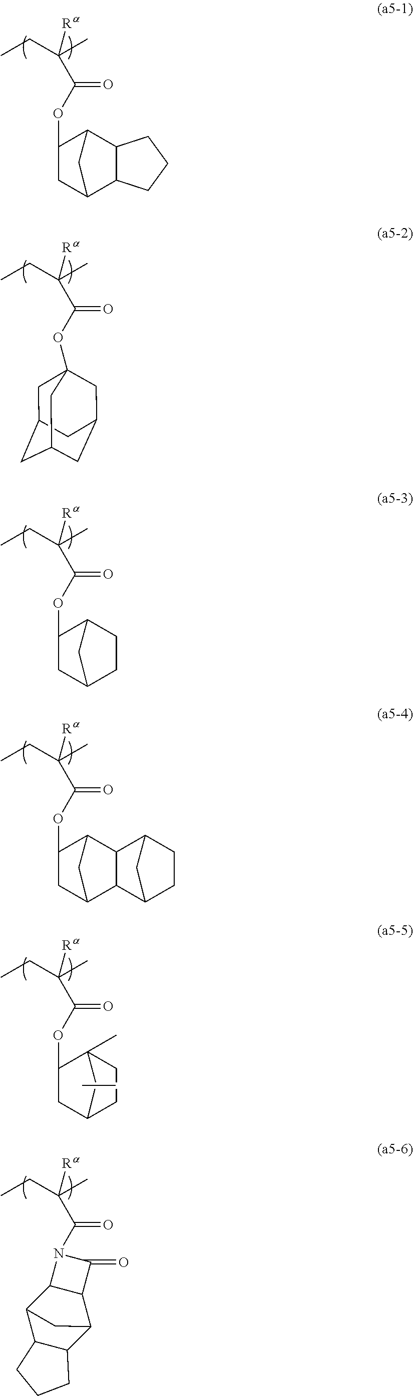

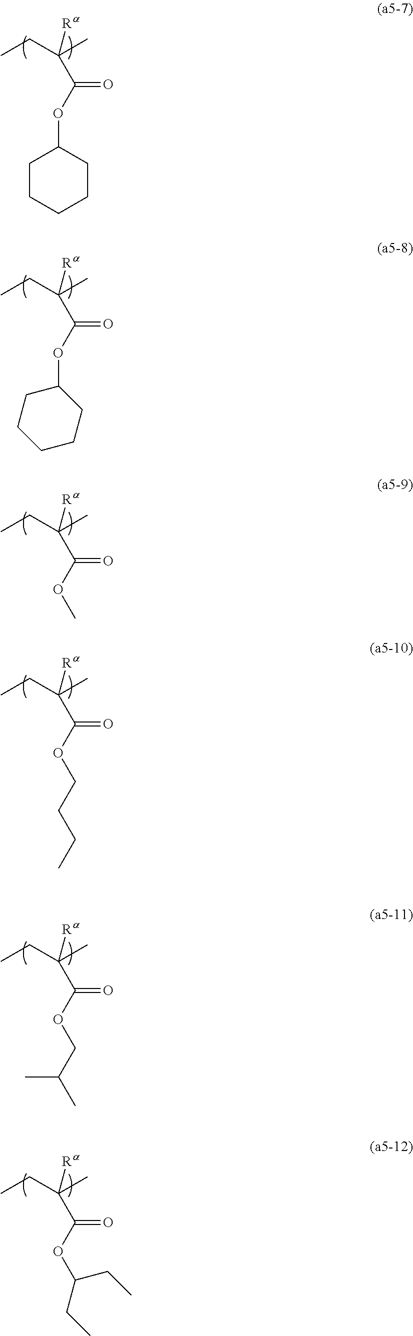

Among the above, the constitutional unit (a5) is preferably a constitutional unit represented by any one of General Formulae (a5-1) to (a5-8), and more preferably a constitutional unit represented by any one of General Formulae (a5-1) to (a5-6).

Constitutional Unit (a12)

The constitutional unit (a02) may be a constitutional unit (a12) containing an aromatic hydrocarbon group. Examples of the constitutional unit (a02) include those in which Ra⁰² in General Formula (a02-1) is an aromatic hydrocarbon group. Examples of the aromatic hydrocarbon group as Ra⁰² include the same ones as those mentioned in Rm¹ in General Formula (m2-1).

Specific examples of the constitutional unit (a12) are shown below but are not limited thereto.

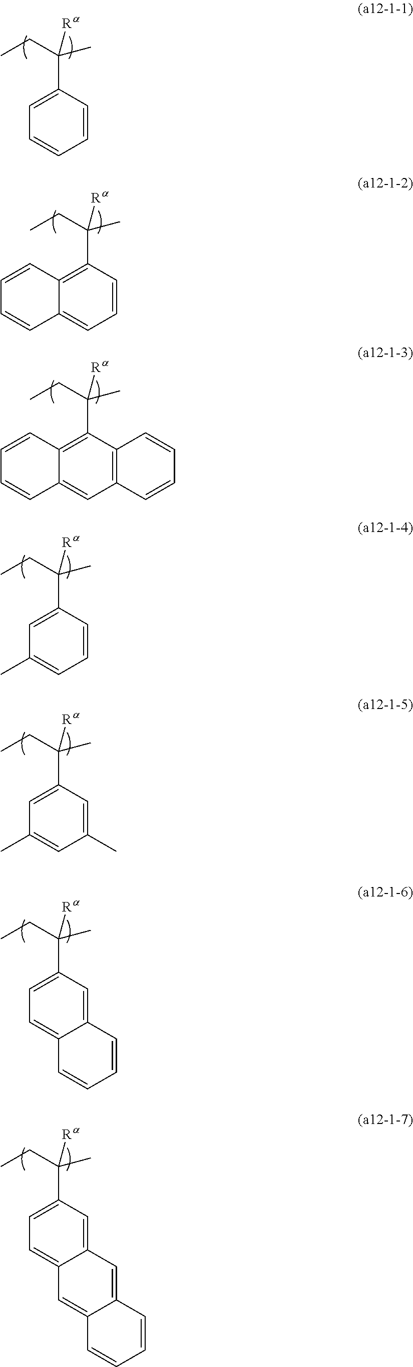

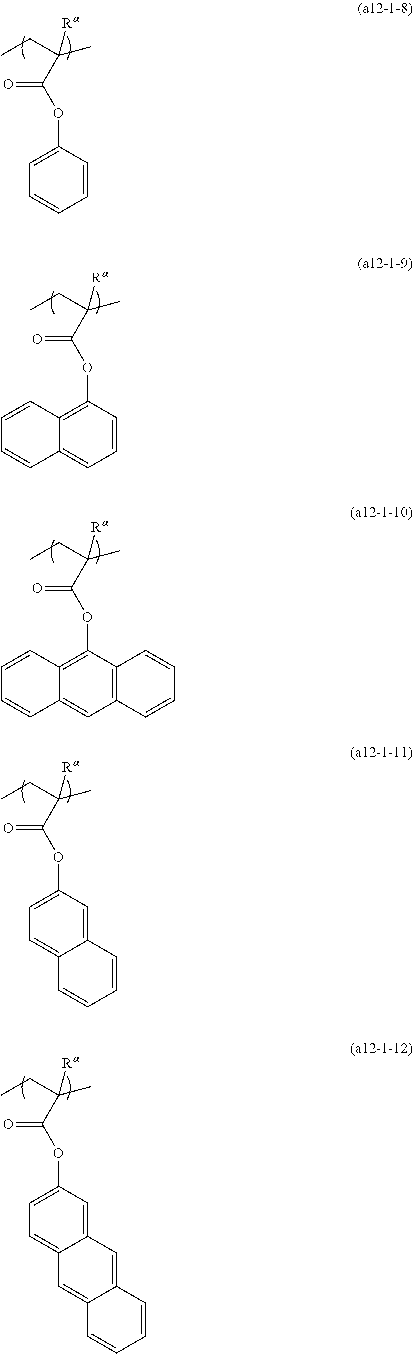

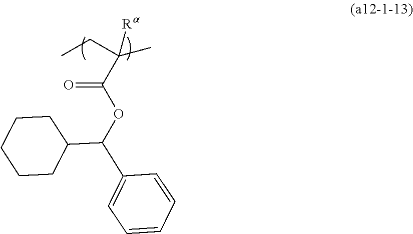

The constitutional unit (a02) contained in the component (P) may be one kind or may be two or more kinds.

As the constitutional unit (a02), one having high hydrophobicity is preferable because it easily segregates on the surface of the resist film. Among the above, the constitutional unit (a02) is preferably the constitutional unit (a5).

In a case where the component (P) has the constitutional unit (a02), the proportion of the constitutional unit (a02) in the component (P) is preferably 10% by mole or more, is more preferably 30% by mole or more, is still more preferably 40% by mole or more, and may be 100% by mole or more, with respect to the total (100% by mole) of all constitutional units constituting the component (P).

In a case where the proportion of the constitutional unit (a02) is set to be equal to or larger than the lower limit value of the above preferred range, the insolubility of the resist film is further suppressed, and thus the lithography characteristics such as the pattern shape are improved.

<<Another Constitutional Unit>>

The component (P) may have another constitutional unit in addition to the above-described constitutional units (a01) and/or (a02). Examples of the other constitutional unit include the following constitutional units (a1), (a2), (a3), (a9), and (a11). In the following description of the constitutional units (a1), (a2), (a3), (a9), and (a11), the fluorinated alkyl group is excluded from the halogenated alkyl group. In addition, the fluorine atom is excluded from the halogen atom.

Constitutional Unit (a1)

The constitutional unit (a1) is a constitutional unit containing an acid dissociable group (however, a constitutional unit corresponding to the constitutional unit (a01) is excluded).

Examples of the acid dissociable group are the same as those which have been proposed so far as acid dissociable groups for the base resin for a chemically amplified resist composition.

Specific examples of acid dissociable groups of the base resin proposed for a chemically amplified resist composition contains an “acetal-type acid dissociable group”, a “tertiary alkyl ester-type acid dissociable group”, and a “tertiary alkyloxycarbonyl acid dissociable group” described below.

Acetal-Type Acid Dissociable Group:

Examples of the acid dissociable group for protecting a carboxy group or a hydroxyl group as a polar group include the acid dissociable group represented by General Formula (a1-r-1) shown below (hereinafter, also referred to as an “acetal-type acid dissociable group”).

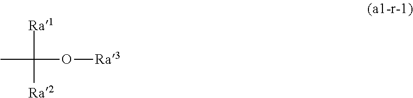

[In the formula, Ra′¹ and Ra′² represent a hydrogen atom or an alkyl group. Ra′³ represents a hydrocarbon group, and Ra′³ may be bonded to any one of Ra′¹ or Ra′² to form a ring.]

In General Formula (a1-r-1), it is preferable that at least one of Ra′¹ and Ra′² represents a hydrogen atom and more preferable that both Ra′¹ and Ra′² represent a hydrogen atom.

In a case where Ra′¹ or Ra′² represents an alkyl group, examples of the alkyl group include the same one as the alkyl group mentioned as the substituent which may be bonded to the carbon atom at the α-position in the description on the α-substituted acrylic acid ester, and the alkyl group preferably has 1 to 5 carbon atoms. Specific examples thereof preferably include a linear or branched alkyl group. Specific examples of the alkyl group include a methyl group, an ethyl group, a propyl group, an isopropyl group, an n-butyl group, an isobutyl group, a tert-butyl group, a pentyl group, an isopentyl group, and a neopentyl group. Among the above, a methyl group or an ethyl group is preferable, and a methyl group is particularly preferable.

In General Formula (a1-r-1), examples of the hydrocarbon group as Ra′³ include a linear or branched alkyl group and a cyclic hydrocarbon group.

The linear alkyl group has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group, and an isopropyl group is preferable.

In a case where Ra′³ represents a cyclic hydrocarbon group, the hydrocarbon group may be an aliphatic hydrocarbon group or an aromatic hydrocarbon group and may be a polycyclic group or a monocyclic group.

The aliphatic hydrocarbon group which is a monocyclic group is preferably a group obtained by removing one hydrogen atom from a monocycloalkane. The monocycloalkane preferably has 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane, where the polycycloalkane preferably has 7 to 12 carbon atoms. Specific examples thereof include adamantane, norbornane, isobornane, tricyclodecane, and tetracyclododecane.

In a case where the cyclic hydrocarbon group as Ra′³ is an aromatic hydrocarbon group, the aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms.

Specific examples of the aromatic ring include aromatic hydrocarbon rings such as benzene, naphthalene, anthracene, and phenanthrene; and an aromatic heterocyclic ring obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group as Ra′³ include a group obtained by removing one hydrogen atom from the above-described aromatic hydrocarbon ring or aromatic heterocyclic ring (an aryl group or a heteroaryl group); a group obtained by removing one hydrogen atom from an aromatic compound having two or more aromatic rings (biphenyl, fluorene or the like); and a group obtained by substituting one hydrogen atom of the above-described aromatic hydrocarbon ring or aromatic heterocyclic ring with an alkylene group (an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aromatic hydrocarbon ring or aromatic heterocyclic ring preferably has 1 to 4 carbon atoms, more preferably 1 or 2 carbon atoms, and particularly preferably 1 carbon atom.

The cyclic hydrocarbon group as Ra′³ may have a substituent. Examples of the substituent include, —R^{P1}, —R^{P2}—O—R^{P1}, —R^{P2}—CO—R^{P1}, —R^{P2}—CO—OR^{P1}, —R^{P2}—O—CO—R^{P1},—R^{P2}—OH, —R^{P2}—CN, and —R^{P2}—COOH (hereinafter, these substituents are also collectively referred to as “Ra^{x5}”).

Here, R^{P1} represents a monovalent chain-like saturated hydrocarbon group having 1 to 10 carbon atoms, a monovalent aliphatic cyclic saturated hydrocarbon group having 3 to 20 carbon atoms, or a monovalent aromatic hydrocarbon group having 6 to 30 carbon atoms. In addition, R^{P2} represents a single bond, a divalent chain-like saturated hydrocarbon group having 1 to 10 carbon atoms, a divalent aliphatic cyclic saturated hydrocarbon group having 3 to 20 carbon atoms, or a divalent aromatic hydrocarbon group having 6 to 30 carbon atoms. However, part or all hydrogen atoms contained in the chain-like saturated hydrocarbon group, the aliphatic cyclic saturated hydrocarbon group, and the aromatic hydrocarbon group of R^{P1} and R^{P2} may be substituted with a halogen atom. In the aliphatic cyclic hydrocarbon group, one or more of the above-described substituents may be included as a single kind, or one or more of the above-described substituents may be included as a plurality of kinds.

Examples of the monovalent chain-like saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms include monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo [3.3.1.13,7]decanyl group, a tetracyclo[6.2.1.13,6.02,7]dodecanyl group, and an adamantyl group.

Examples of the monovalent aromatic hydrocarbon group having 6 to 30 carbon atoms include groups obtained by removing one hydrogen atom from an aromatic hydrocarbon ring such as benzene, biphenyl, fluorene, naphthalene, anthracene, and phenanthrene.

In a case where Ra′³ is bonded to any one of Ra′¹ or Ra′² to form a ring, the cyclic group is preferably a 4-membered to 7-membered ring, and more preferably a 4-membered to 6-membered ring. Specific examples of the cyclic group include a tetrahydropyranyl group and a tetrahydrofuranyl group.

Tertiary Alkyl Ester-Type Acid Dissociable Group:

Among the above polar groups, examples of the acid dissociable group for protecting the carboxy group include the acid dissociable group represented by General Formula (a1-r-2) shown below.

Among the acid dissociable groups represented by General Formula (a1-r-2), for convenience, a group which is constituted of alkyl groups is referred to as a “tertiary alkyl ester-type acid dissociable group”.

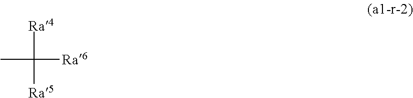

[In the formula, Ra′⁴ to Ra′⁶ each represent a hydrocarbon group, and Ra′⁵ and Ra′⁶ may be bonded to each other to form a ring.]

Examples of the hydrocarbon group as Ra′⁴ include a linear or branched alkyl group, a chain-like or cyclic alkenyl group, and a cyclic hydrocarbon group.

Examples of the linear or branched alkyl group and the cyclic hydrocarbon group (the aliphatic hydrocarbon group which is a monocyclic group, the aliphatic hydrocarbon group which is a polycyclic group, or the aromatic hydrocarbon group) as Ra′⁴ include the same one as Ra′³ described above.

The chain-like or cyclic alkenyl group as Ra′⁴ is preferably an alkenyl group having 2 to 10 carbon atoms.

Examples of the hydrocarbon group as Ra′⁵ and Ra′⁶ include the same one as Ra′³.

In a case where Ra′⁵ to Ra′⁶ are bonded to each other to form a ring, suitable examples thereof include groups represented by General Formula (a1-r2-1), General Formula (a1-r2-2), and General Formula (a1-r2-3) can be suitably mentioned.

On the other hand, in a case where Ra′⁴ to Ra′⁶ are not bonded to each other and represent an independent hydrocarbon group, suitable examples thereof include a group represented by General Formula (a1-r2-4).

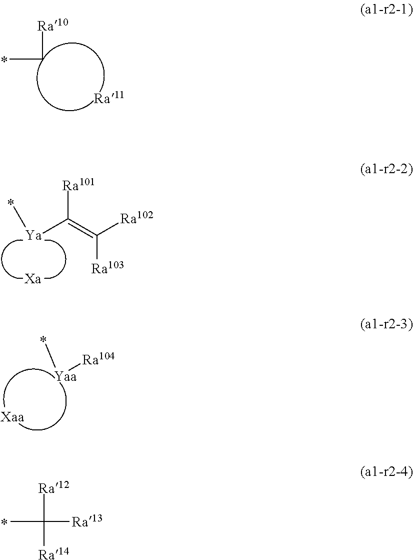

[In General Formula (a1-r2-1), Ra′¹⁰ represents a linear or branched alkyl group having 1 to 12 carbon atoms, a part of which may be substituted with a halogen atom or a hetero atom-containing group. Ra′¹¹ represents a group that forms an aliphatic cyclic group together with a carbon atom to which Ra′¹⁰ is bonded. In General Formula (a1-r2-2), Ya represents a carbon atom. Xa is a group that forms a cyclic hydrocarbon group together with Ya. Part or all hydrogen atoms contained in the cyclic hydrocarbon group may be substituted. Ra¹⁰¹ to Ra¹⁰³ each independently represents a hydrogen atom, a monovalent chain-like saturated hydrocarbon group having 1 to 10 carbon atoms, or a monovalent aliphatic cyclic saturated hydrocarbon group having 3 to 20 carbon atoms. Part or all hydrogen atoms contained in the chain-like saturated hydrocarbon group and the aliphatic cyclic saturated hydrocarbon group may be substituted. Two or more of Ra¹⁰¹ to Ra¹⁰³ may be bonded to each other to form a cyclic structure. In General Formula (a1-r2-3), Yaa represents a carbon atom. Xaa is a group that forms an aliphatic cyclic group together with Yaa. Ra¹⁰⁴ represents an aromatic hydrocarbon group which may have a substituent. In General Formula (a1-r2-4), Ra′¹² and Ra′¹³ each independently represent a monovalent chain-like saturated hydrocarbon group having 1 to 10 carbon atoms or a hydrogen atom. Part or all hydrogen atoms contained in the chain-like saturated hydrocarbon group may be substituted. Ra′¹⁴ represents a hydrocarbon group which may have a substituent. * represents a bonding site.]

In General Formula (a1-r2-1), Ra′¹⁰ represents a linear or branched alkyl group having 1 to 12 carbon atoms, a part of which may be substituted with a halogen atom or a hetero atom-containing group.

The linear alkyl group as Ra′¹⁰ has 1 to 12 carbon atoms, and preferably has 1 to 10 carbon atoms and particularly preferably 1 to 5 carbon atoms.

Examples of the branched alkyl group as Ra′¹⁰ include the same one as Ra′³.

A part of the alkyl group as Ra′¹⁰ may be substituted with a halogen atom or a hetero atom-containing group. For example, part of hydrogen atoms constituting the alkyl group may be substituted with a halogen atom or a hetero atom-containing group. Further, part of carbon atoms (such as a methylene group) constituting the alkyl group may be substituted with a hetero atom-containing group.

Examples of the hetero atom mentioned here include an oxygen atom, a sulfur atom, and a nitrogen atom. Examples of the hetero atom-containing group include (—O—), —C(═O)—O—, —O—C(═O)—, —C(═O)—, —O—C(═O)—O—, —C(═O)—NH—, —NH—, —S—, —S(═O)₂—, and —S(═O)₂—O—.

In General Formula (a1-r2-1), Ra′¹¹ (a group that forms an aliphatic cyclic group together with a carbon atom to which Ra′¹⁰ is bonded) is preferably the group mentioned as the aliphatic hydrocarbon group (the alicyclic hydrocarbon group) which is a monocyclic group or a polycyclic group as Ra′³ in General Formula (a1-r-1). Among them, a monocyclic alicyclic hydrocarbon group is preferable, specifically, a cyclopentyl group or a cyclohexyl group is more preferable, and a cyclopentyl group is still more preferable.

In General Formula (a1-r2-2), examples of the cyclic hydrocarbon group formed by Xa together with Ya include a group in which one or more hydrogen atoms are further removed from a cyclic monovalent hydrocarbon group (an aliphatic hydrocarbon group) as Ra′³ in General Formula (a1-r-1).

The cyclic hydrocarbon group that is formed by Xa together with Ya may have a substituent. Examples of this substituent include the same one as the substituent which may be contained in the cyclic hydrocarbon group as Ra′³.

In General Formula (a1-r2-2), examples of the monovalent chain-like saturated hydrocarbon group having 1 to 10 carbon atoms, as Ra¹⁰¹ to Ra¹⁰³, include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms, as Ra¹⁰¹ to Ra¹⁰³, include monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo [3.3.1.13,7]decanyl group, a tetracyclo[6.2.1.13,6.02,7]dodecanyl group, and an adamantyl group.

Among the above, Ra¹⁰¹ to Ra¹⁰³ are preferably a hydrogen atom or a monovalent chain-like saturated hydrocarbon group having 1 to 10 carbon atoms, and among them, a hydrogen atom, a methyl group, and an ethyl group are more preferable, and a hydrogen atom is particularly preferable from the viewpoint of easy synthesis.

Examples of the substituent contained in the chain-like saturated hydrocarbon group represented by Ra¹⁰¹ to Ra¹⁰³ or the aliphatic cyclic saturated hydrocarbon group include the same group as Ra^{x5} described above.

Examples of the group containing a carbon-carbon double bond generated by forming a cyclic structure, which is obtained by bonding two or more of Ra¹⁰¹ to Ra¹⁰³ to each other, include a cyclopentenyl group, a cyclohexenyl group, a methylcyclopentenyl group, a methylcyclohexenyl group, a cyclopentylideneethenyl group, and a cyclohexylideneethenyl group. Among these, a cyclopentenyl group, a cyclohexenyl group, and a cyclopentylideneethenyl group are preferable from the viewpoint of easy synthesis.

In General Formula (a1-r2-3), an aliphatic cyclic group that is formed by Xaa together with Yaa is preferably the group mentioned as the aliphatic hydrocarbon group which is a monocyclic group or a polycyclic group as Ra′³ in General Formula (a1-r-1).

In General Formula (a1-r2-3), Examples of the aromatic hydrocarbon group as Ra¹⁰⁴ include a group in which one or more hydrogen atoms have been removed from an aromatic hydrocarbon ring having 5 to 30 carbon atoms. Among them, Ra¹⁰⁴ is preferably a group obtained by removing one or more hydrogen atoms from an aromatic hydrocarbon ring having 6 to 15 carbon atoms, more preferably a group obtained by removing one or more hydrogen atoms from benzene, naphthalene, anthracene, or phenanthrene, still more preferably a group obtained by removing one or more hydrogen atoms from benzene, naphthalene, or anthracene, particularly preferably a group obtained by removing one or more hydrogen atoms from benzene or naphthalene, and most preferably a group obtained by removing one or more hydrogen atoms from benzene.

Examples of the substituent which may be contained in Ra¹⁰⁴ in General Formula (a1-r2-3) include a methyl group, an ethyl group, propyl group, a hydroxy group, a carboxy group, a halogen atom, an alkoxy group (a methoxy group, an ethoxy group, a propoxy group, a butoxy group, and the like), and an alkyloxycarbonyl group.

In General Formula (a1-r2-4), Ra′¹² and Ra′¹³ each independently represent a monovalent chain-like saturated hydrocarbon group having 1 to 10 carbon atoms or a hydrogen atom. Examples of the monovalent chain-like saturated hydrocarbon group having 1 to 10 carbon atoms as Ra′¹² and Ra′¹³ include the same one as the monovalent chain-like saturated hydrocarbon group having 1 to 10 carbon atoms as Ra¹⁰¹ to Ra¹⁰³ as described above. Part or all hydrogen atoms contained in the chain-like saturated hydrocarbon group may be substituted.

Among them, Ra′¹² and Ra′¹³ are preferably a hydrogen atom or an alkyl group having 1 to 5 carbon atoms, more preferably an alkyl group having 1 to 5 carbon atoms, still more preferably a methyl group or an ethyl group, and particularly preferably a methyl group.

In a case where the chain-like saturated hydrocarbon groups represented by Ra′¹² and Ra′¹³ are substituted, examples of the substituent include the same group as Ra^{x5} described above.

In Formula (a1-r2-4), Ra′¹⁴ represents a hydrocarbon group which may have a substituent. Examples of the hydrocarbon group as Ra′¹⁴ include a linear or branched alkyl group and a cyclic hydrocarbon group.

The linear alkyl group as Ra′¹⁴ has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group as Ra′¹⁴ has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group, and an isopropyl group is preferable.

In a case where Ra′¹⁴ represents a cyclic hydrocarbon group, the hydrocarbon group may be an aliphatic hydrocarbon group or an aromatic hydrocarbon group and may be a polycyclic group or a monocyclic group.

The aliphatic hydrocarbon group which is a monocyclic group is preferably a group obtained by removing one hydrogen atom from a monocycloalkane. The monocycloalkane preferably has 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane, where the polycycloalkane preferably has 7 to 12 carbon atoms. Specific examples thereof include adamantane, norbornane, isobornane, tricyclodecane, and tetracyclododecane.

Examples of the aromatic hydrocarbon group as Ra′¹⁴ include the same one as the aromatic hydrocarbon group as Ra¹⁰⁴. Among them, Ra′¹⁴ is preferably a group in which one or more hydrogen atoms have been removed from an aromatic hydrocarbon ring having 6 to 15 carbon atoms, more preferably a group in which one or more hydrogen atoms have been removed from benzene, naphthalene, anthracene, or phenanthrene, still more preferably a group in which one or more hydrogen atoms have been removed from benzene, naphthalene, or anthracene, particularly preferably a group in which one or more hydrogen atoms have been removed from naphthalene or anthracene, and most preferably a group in which one or more hydrogen atoms have been removed from naphthalene.

Examples of the substituent which may be contained in Ra′¹⁴ include the same one as the substituent which may be contained in Ra¹⁰⁴.

In a case where Ra′¹⁴ in General Formula (a1-r2-4) is a naphthyl group, the position at which the tertiary carbon atom in General Formula (a1-r2-4) is bonded may be any of the 1-position and the 2-position of the naphthyl group.

In a case where Ra′¹⁴ in General Formula (a1-r2-4) is an anthryl group, the position at which the tertiary carbon atom in General Formula (a1-r2-4) is bonded may be any of the 1-position, the 2-position, and 9-position of the anthryl group.

Specific examples of the group represented by General Formula (a1-r2-1) are shown below.

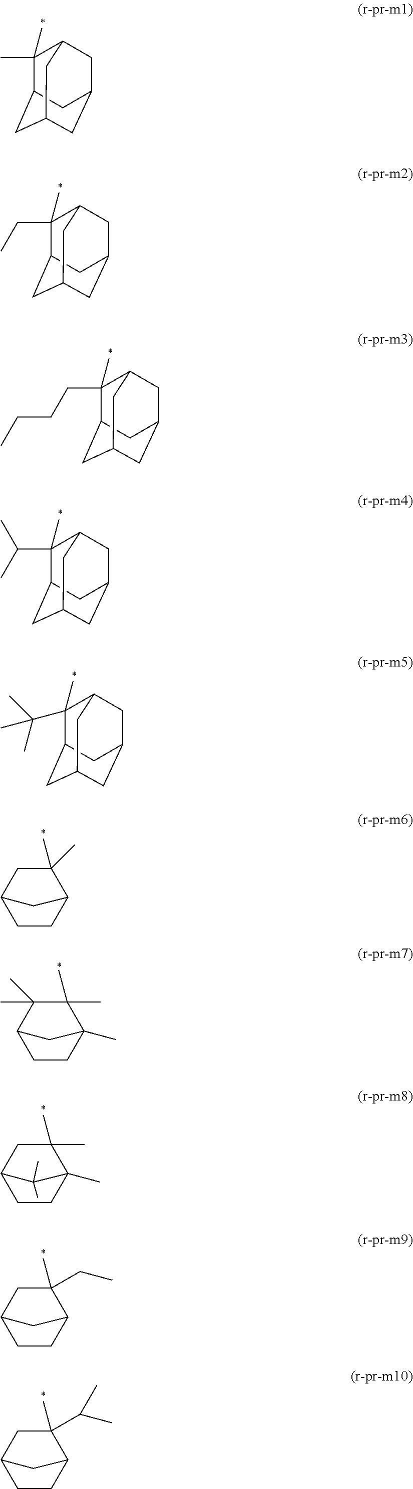

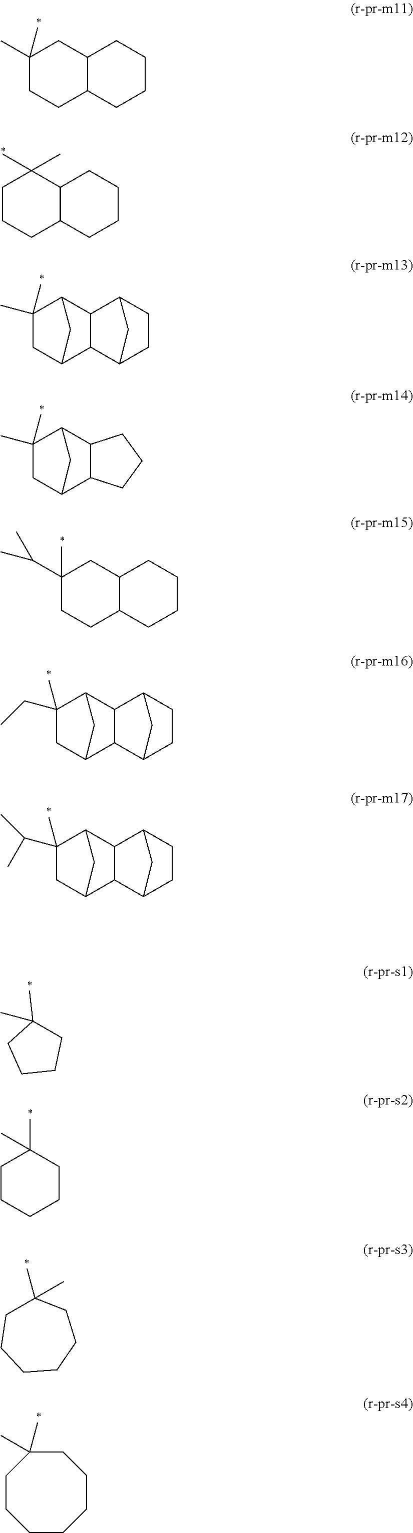

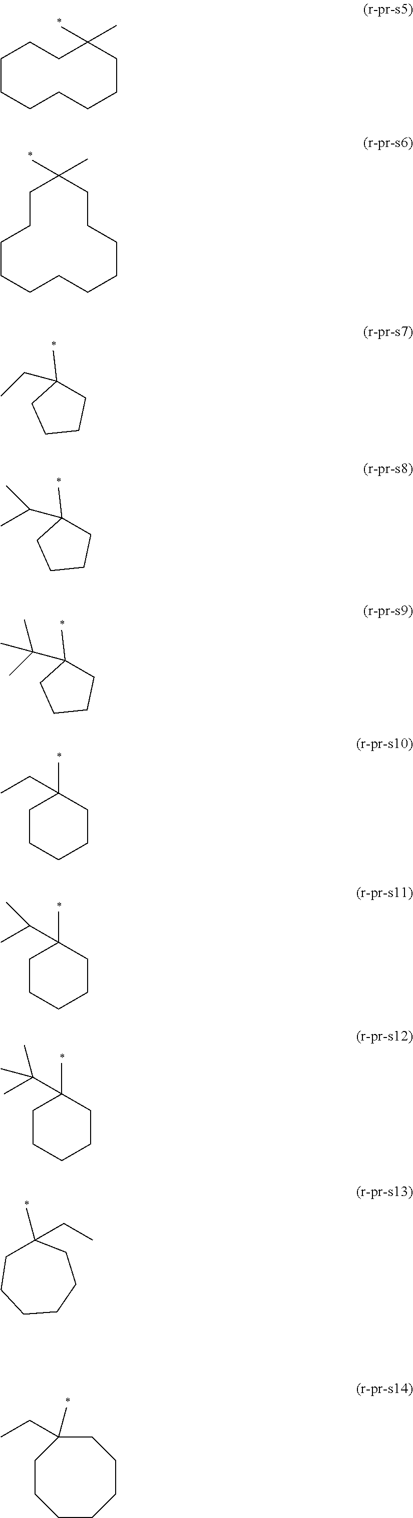

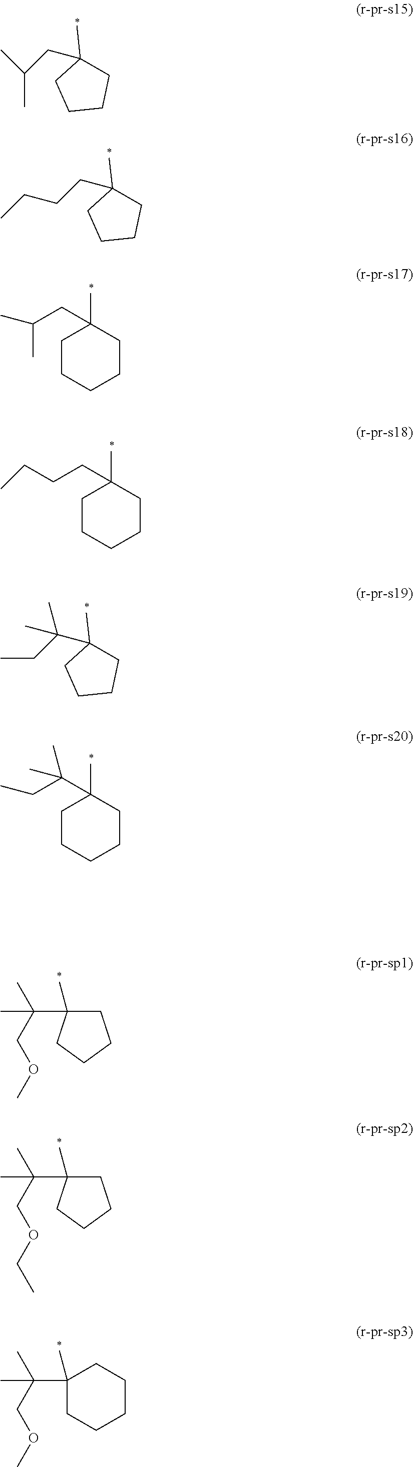

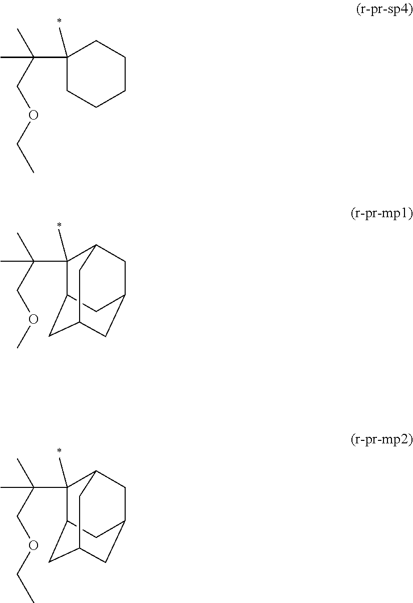

Specific examples of the group represented by General Formula (a1-r2-2) are shown below.

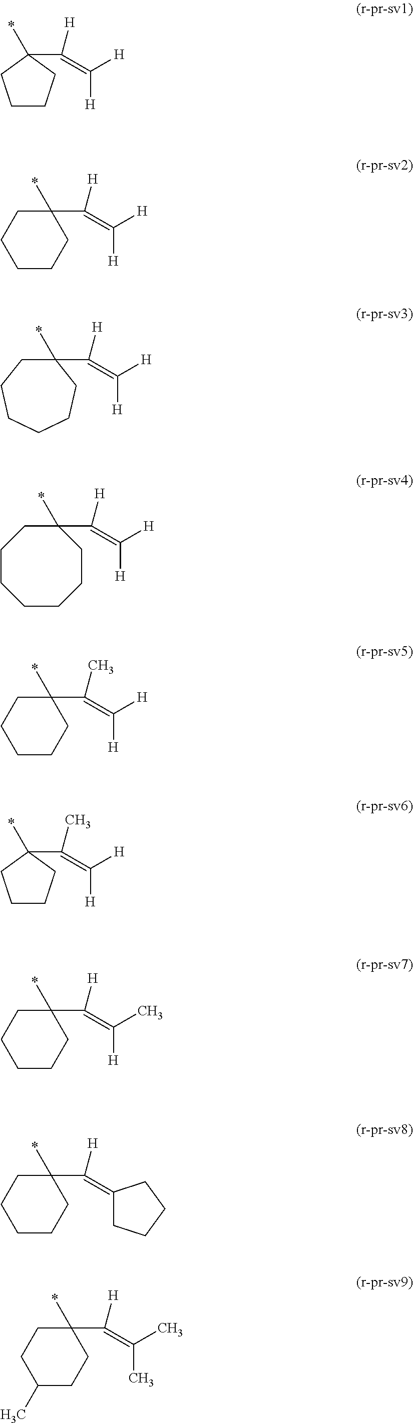

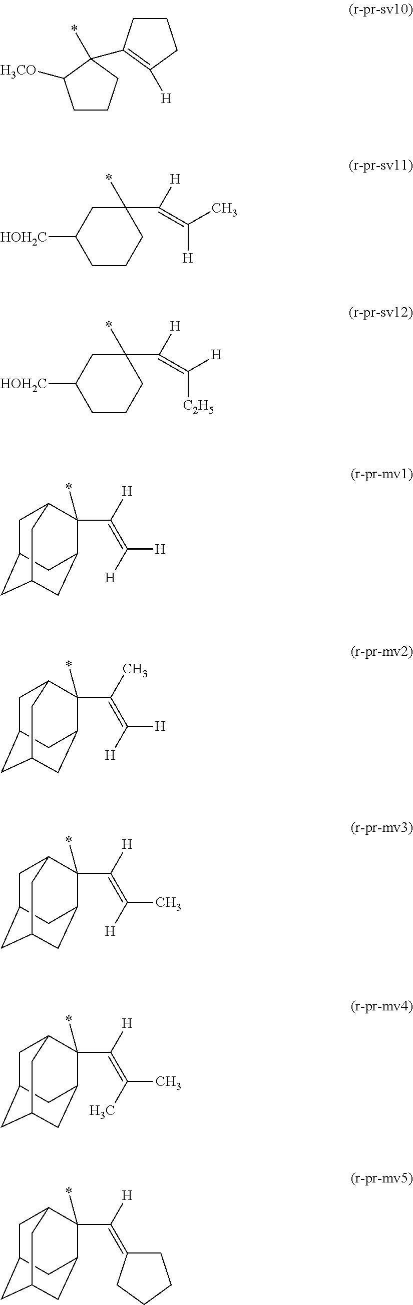

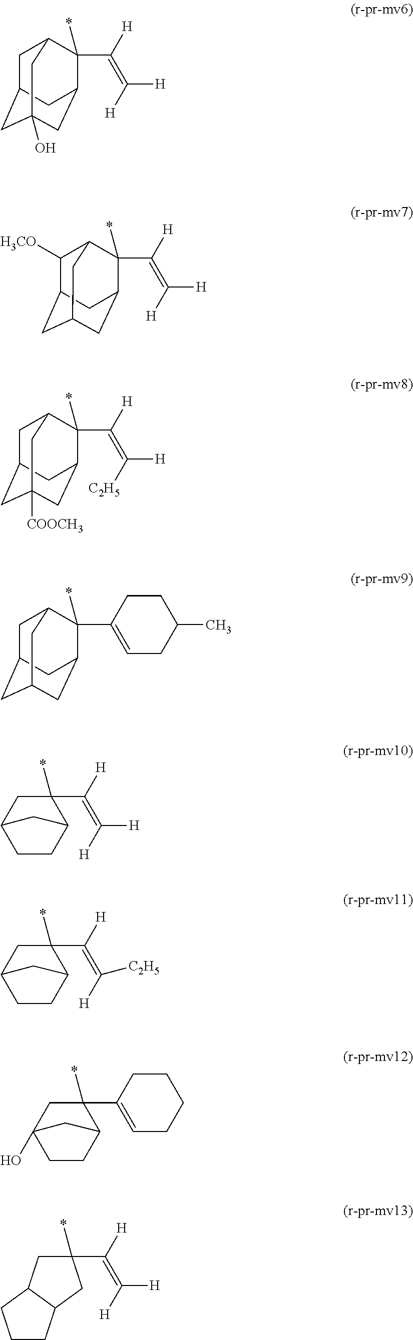

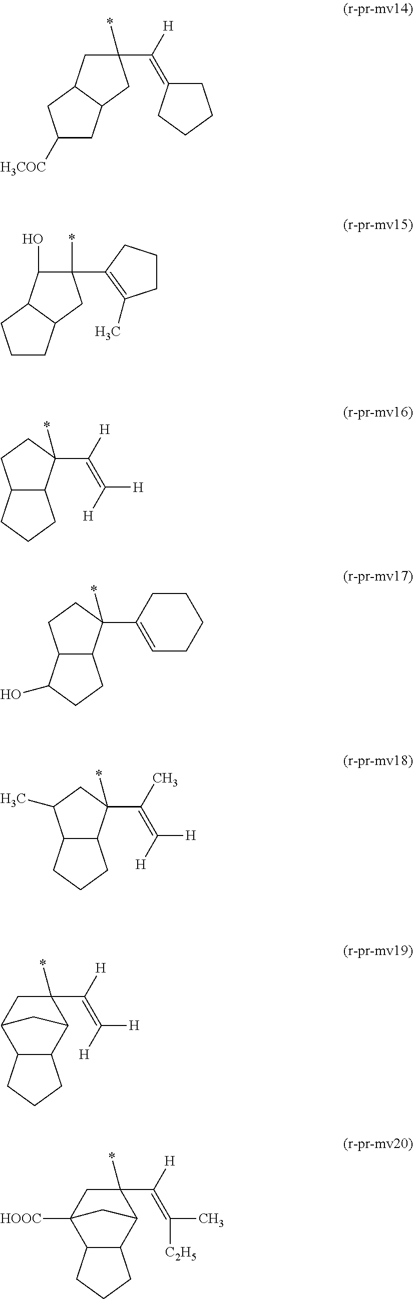

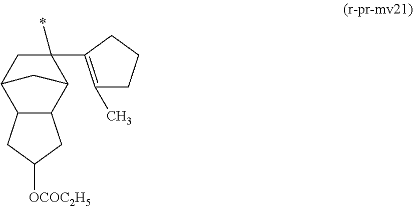

Specific examples of the group represented by General Formula (a1-r2-3) are shown below.

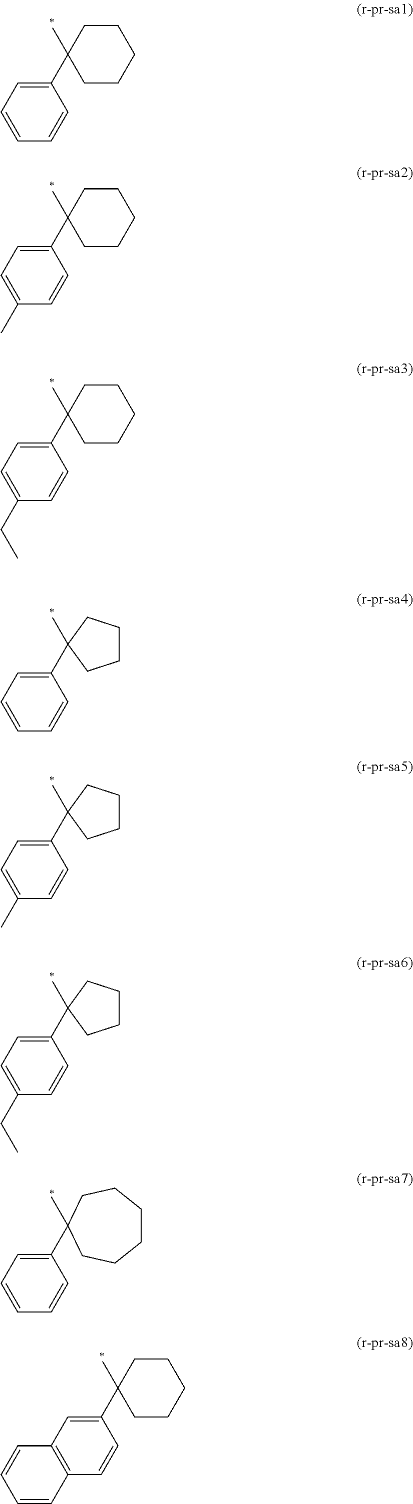

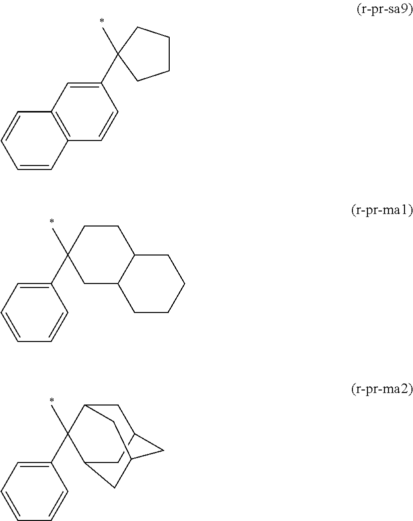

Specific examples of the group represented by General Formula (a1-r2-4) are shown below.

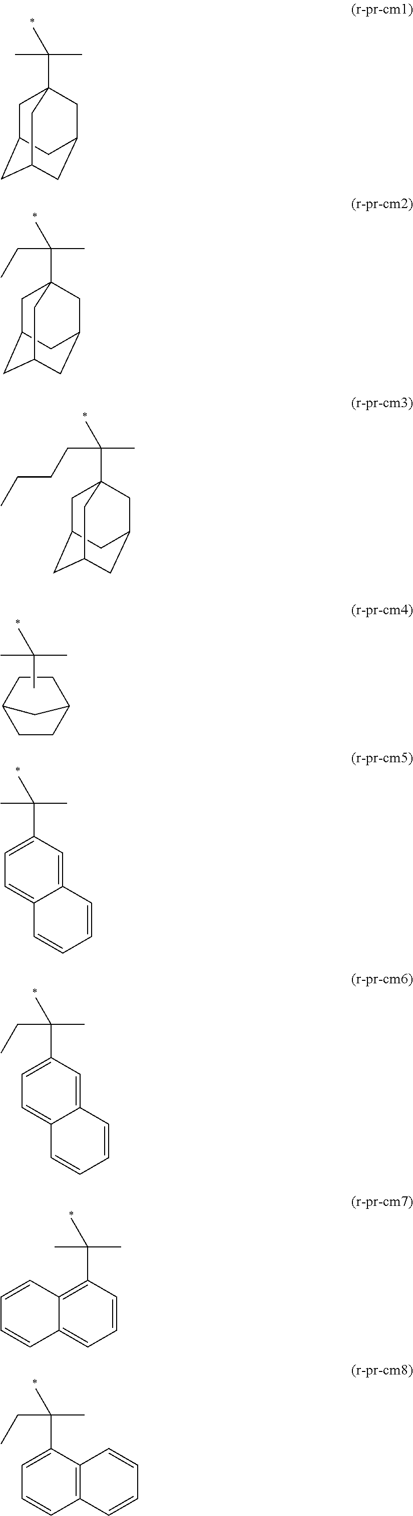

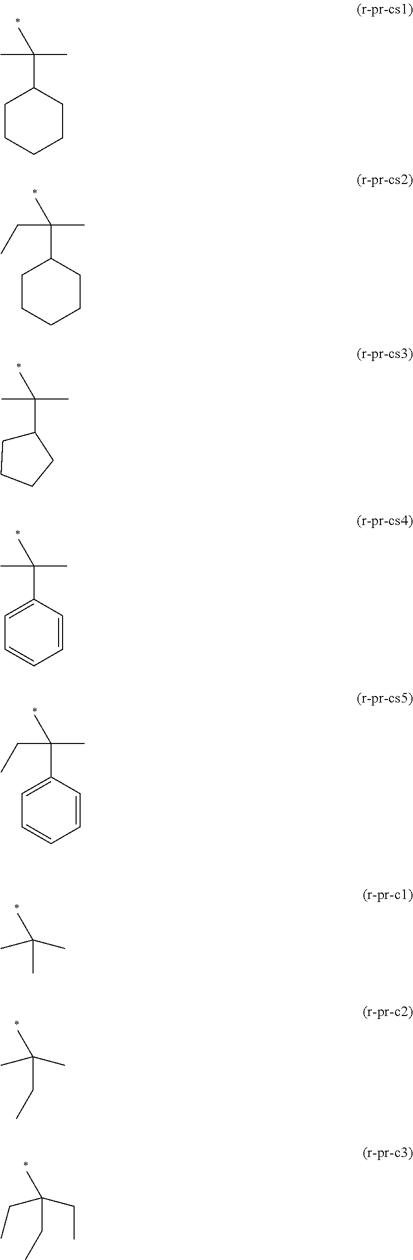

Tertiary Alkyloxycarbonyl Acid Dissociable Group:

Among the polar groups, examples of the acid dissociable group for protecting a hydroxyl group include an acid dissociable group (hereinafter, for convenience, also referred to as a “tertiary alkyloxycarbonyl acid dissociable group”) represented by General Formula (a1-r-3) shown below.

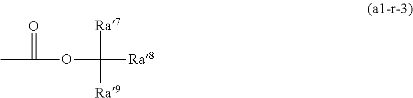

[In the formula, Ra′⁷ to Ra′⁹ each represent an alkyl group.]

In General Formula (a1-r-3), Ra′⁷ to Ra′⁹ are each preferably an alkyl group having 1 to 5 carbon atoms and more preferably an alkyl group having 1 to 3 carbon atoms.

Further, the total number of carbon atoms in each of the alkyl groups is preferably in a range of 3 to 7, more preferably in a range of 3 to 5, and most preferably 3 or 4.

Examples of the constitutional unit (a1) include a constitutional unit derived from acrylic acid ester in which the hydrogen atom bonded to the carbon atom at the α-position may be substituted with a substituent; a constitutional unit derived from acrylamide; a constitutional unit in which at least part of hydrogen atoms in a hydroxyl group of a constitutional unit derived from hydroxystyrene or a hydroxystyrene derivative are protected by a substituent including an acid decomposable group; and a constitutional unit in which at least part of hydrogen atoms in —C(═O)—OH of a constitutional unit derived from vinylbenzoic acid or a vinylbenzoic acid derivative are protected by the substituent including an acid decomposable group.

Among the above, the constitutional unit (a1) is preferably a constitutional unit derived from acrylic acid ester in which the hydrogen atom bonded to the carbon atom at the α-position may be substituted with a substituent.

Preferred specific examples of such a constitutional unit (a1) include constitutional units represented by General Formula (a1-1) or (a1-2).

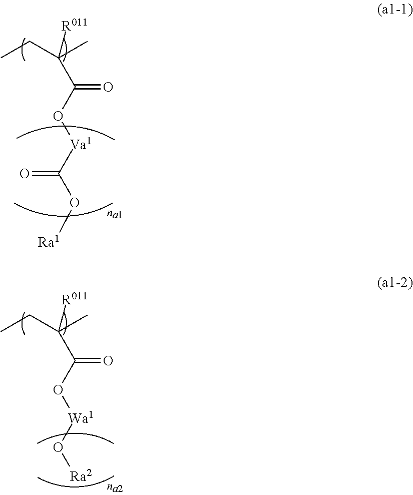

[In the formula, R is the same as R in General Formula (a02-1). Va¹ represents a divalent hydrocarbon group which may have an ether bond. nₐ₁ represents an integer in a range of 0 to 2. Ra¹ represents an acid dissociable group represented by General Formula (a1-r-1) or (a1-r-2). Wa¹ represents an (nₐ2+1)-valent hydrocarbon group, nₐ₂ represents an integer in a range of 1 to 3, and Ra² represents an acid dissociable group represented by General Formula (a1-r-1) or (a1-r-3).]

In General Formula (a1-1), R is the same as R in General Formula (a02-1).

In General Formula (a1-1), the divalent hydrocarbon group as Va¹ may be an aliphatic hydrocarbon group or an aromatic hydrocarbon group.

The aliphatic hydrocarbon group as the divalent hydrocarbon group represented by Va¹ may be saturated or unsaturated. In general, it is preferable that the aliphatic hydrocarbon group is saturated.

More specific examples of the aliphatic hydrocarbon group include a linear or branched aliphatic hydrocarbon group and an aliphatic hydrocarbon group containing a ring in the structure thereof.

The linear aliphatic hydrocarbon group described above preferably has 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group described above preferably has 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

Examples of the aliphatic hydrocarbon group containing a ring in the structure thereof include an alicyclic hydrocarbon group (a group obtained by removing two hydrogen atoms from an aliphatic hydrocarbon ring), a group obtained by bonding an alicyclic hydrocarbon group to the terminal of a linear or branched aliphatic hydrocarbon group, and a group obtained by interposing an alicyclic hydrocarbon group in the middle of a linear or branched aliphatic hydrocarbon group. Examples of the linear or branched aliphatic hydrocarbon group include the same one as the above-described linear aliphatic hydrocarbon group or the above-described branched aliphatic hydrocarbon group.

The alicyclic hydrocarbon group preferably has 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group obtained by removing two hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing two hydrogen atoms from a polycycloalkane, and the polycycloalkane is preferably a group having 7 to 12 carbon atoms. Specific examples of the polycyclic alicyclic hydrocarbon group include adamantane, norbornane, isobornane, tricyclodecane, and tetracyclododecane.

The aromatic hydrocarbon group as the divalent hydrocarbon group represented by Va¹ is a hydrocarbon group having an aromatic ring.

The aromatic hydrocarbon group preferably has 3 to 30 carbon atoms, more preferably 5 to 30 carbon atoms, still more preferably 5 to 20 carbon atoms, particularly preferably 6 to 15 carbon atoms, and most preferably 6 to 12 carbon atoms. Here, the number of carbon atoms in a substituent is not included in the number of carbon atoms.

Specific examples of the aromatic ring contained in the aromatic hydrocarbon group include aromatic hydrocarbon rings such as benzene, biphenyl, fluorene, naphthalene, anthracene, and phenanthrene; and an aromatic heterocyclic ring obtained by substituting part of carbon atoms constituting the above-described aromatic hydrocarbon rings with a hetero atom. Examples of the hetero atom in the aromatic heterocyclic rings include an oxygen atom, a sulfur atom, and a nitrogen atom.

Specific examples of the aromatic hydrocarbon group include a group in which two hydrogen atoms have been removed from the above-described aromatic hydrocarbon ring (an arylene group); and a group in which one hydrogen atom of a group (an aryl group) formed by removing one hydrogen atom from the aromatic hydrocarbon ring has been substituted with an alkylene group (for example, a group in which one or more hydrogen atoms have been removed from an aryl group in arylalkyl groups such as a benzyl group, a phenethyl group, a 1-naphthylmethyl group, a 2-naphthylmethyl group, a 1-naphthylethyl group, or a 2-naphthylethyl group). The alkylene group (an alkyl chain in the arylalkyl group) preferably has 1 to 4 carbon atoms, more preferably 1 or 2 carbon atoms, and particularly preferably 1 carbon atom.

In General Formula (a1-1), Ra¹ is an acid dissociable group represented by General Formula (a1-r-1) or (a1-r-2).

In General Formula (a1-2), the (nₐ₂+1)-valent hydrocarbon group as Wa¹ may be an aliphatic hydrocarbon group or an aromatic hydrocarbon group. The aliphatic hydrocarbon group indicates a hydrocarbon group that has no aromaticity and may be saturated or unsaturated.

In general, it is preferable that the aliphatic hydrocarbon group be saturated. Examples of the aliphatic hydrocarbon group include a linear or branched aliphatic hydrocarbon group, an aliphatic hydrocarbon group containing a ring in the structure thereof, and a combination of the linear or branched aliphatic hydrocarbon group and the aliphatic hydrocarbon group containing a ring in the structure thereof.

The valency of (nₐ₂+1) is preferably divalent, trivalent, or tetravalent, and more preferably divalent or trivalent.

In General Formula (a1-2), Ra² is an acid dissociable group represented by General Formula (a1-r-1) or (a1-r-3).

Specific examples of the constitutional unit represented by General Formula (a1-1) are shown below. In each of the following formulae, R^{α} represents a hydrogen atom or a methyl group.

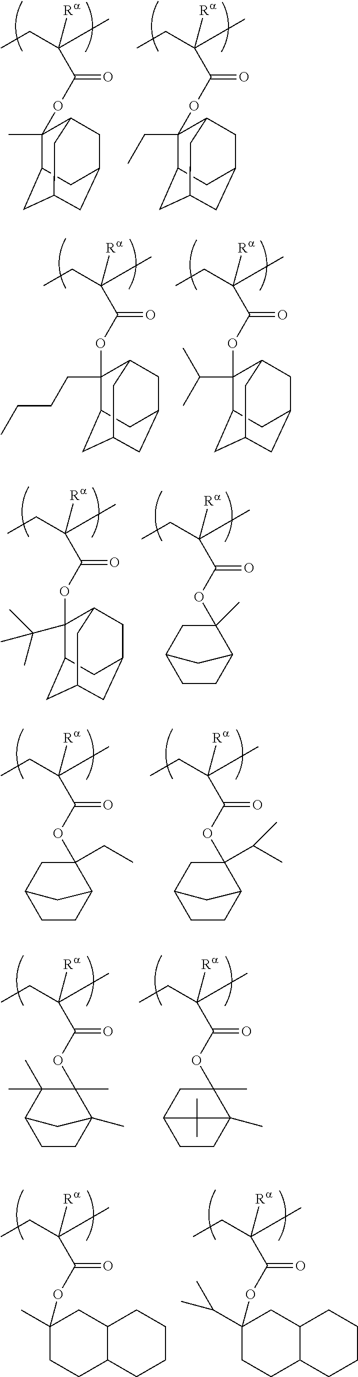

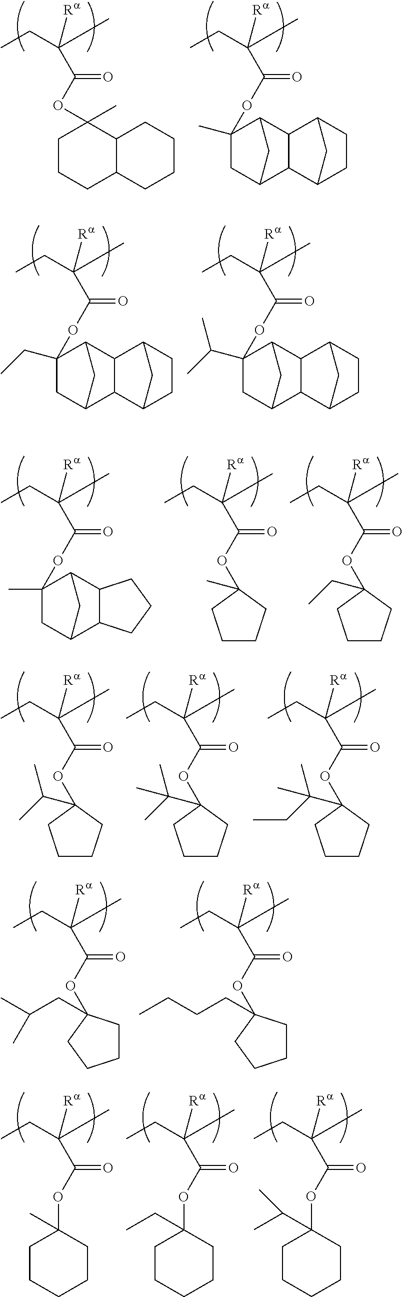

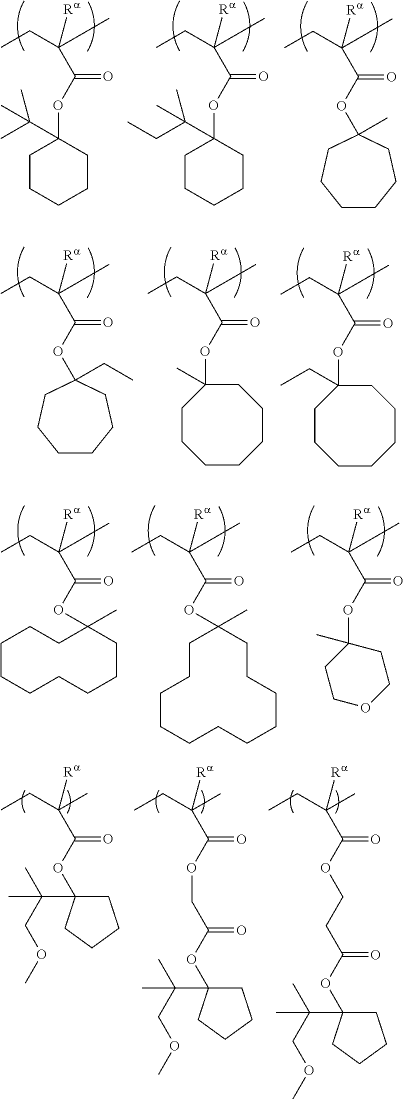

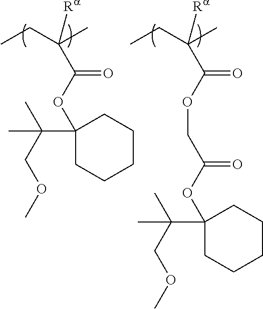

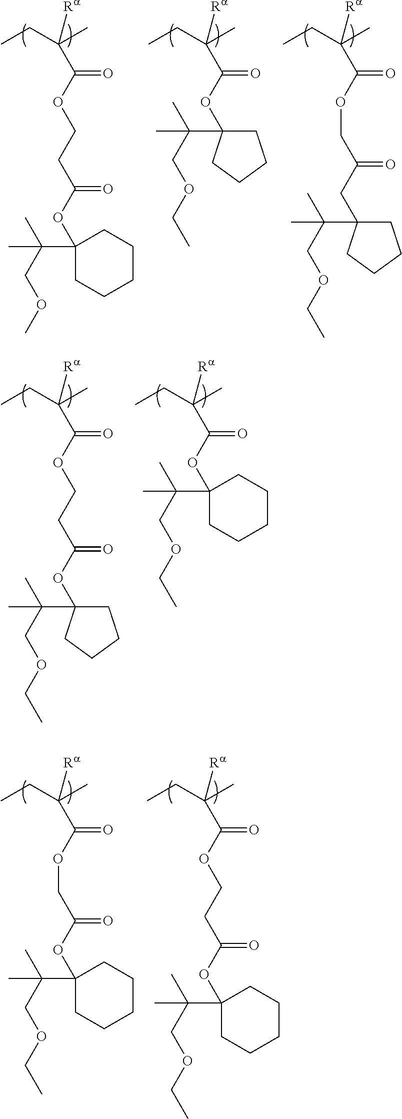

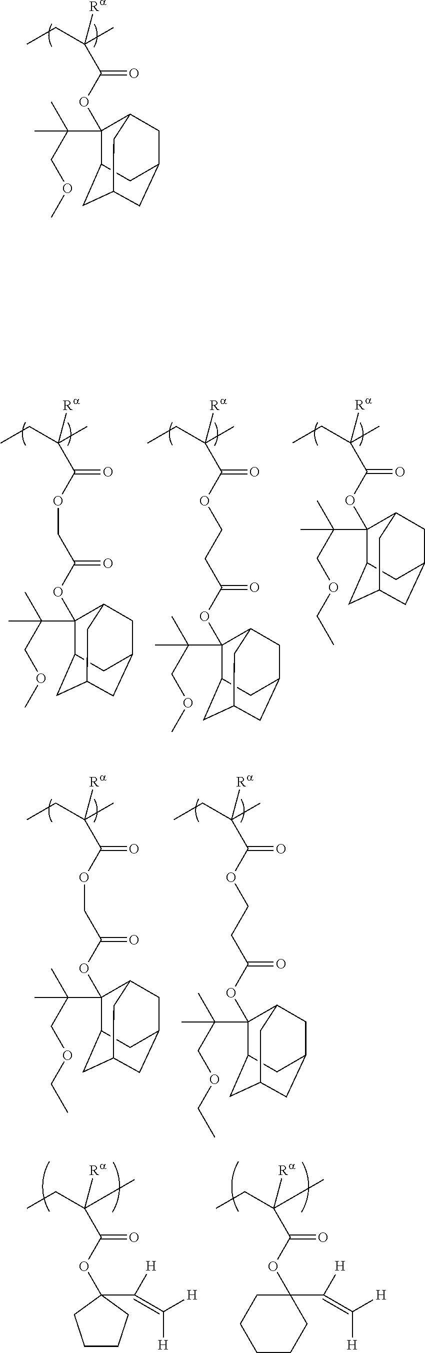

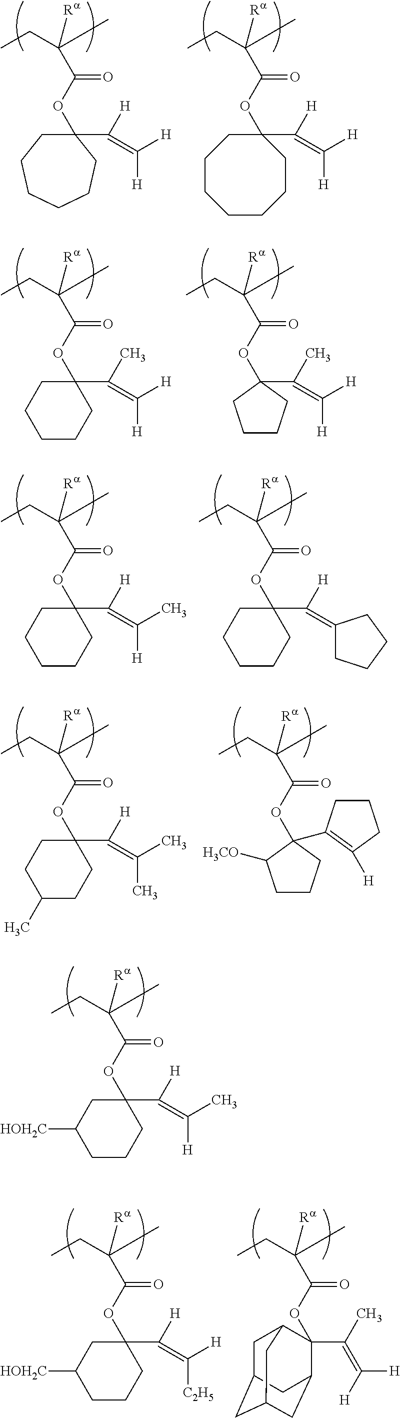

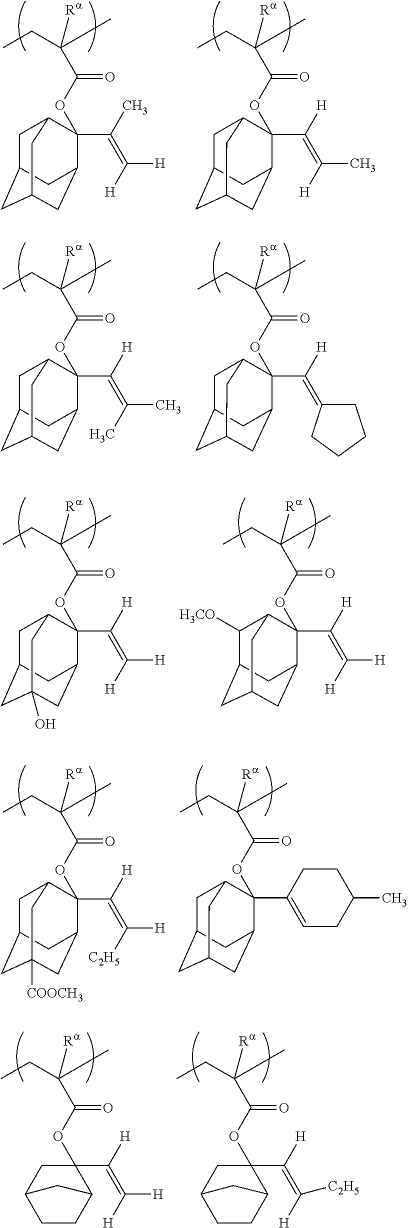

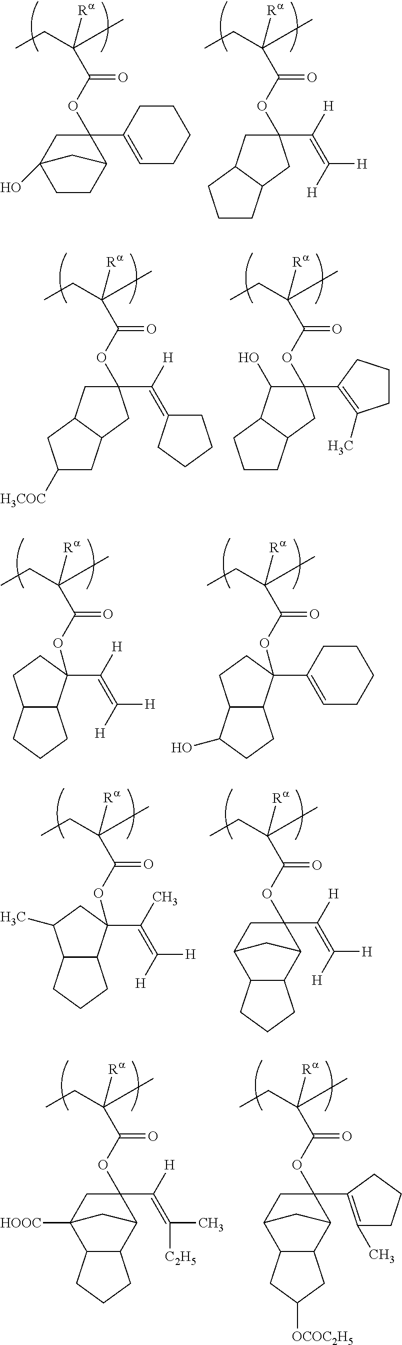

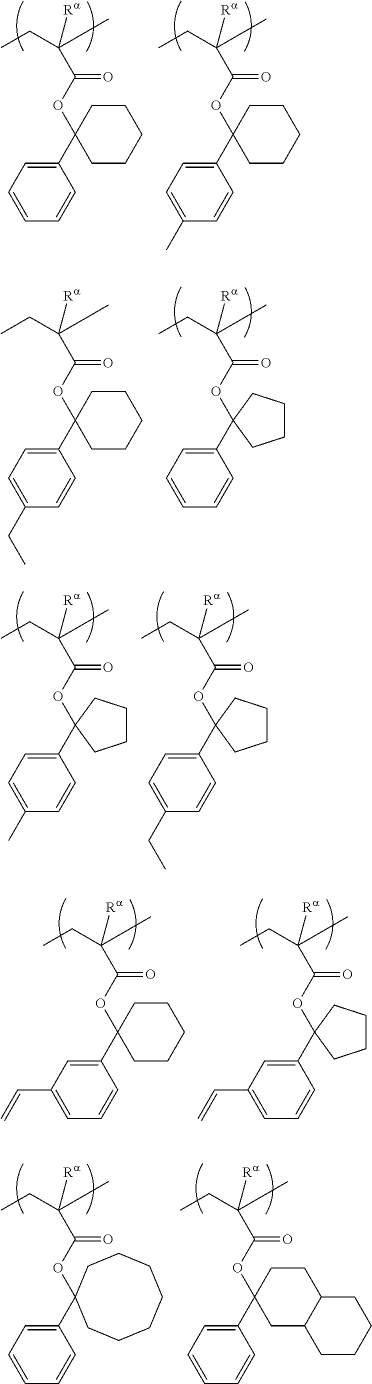

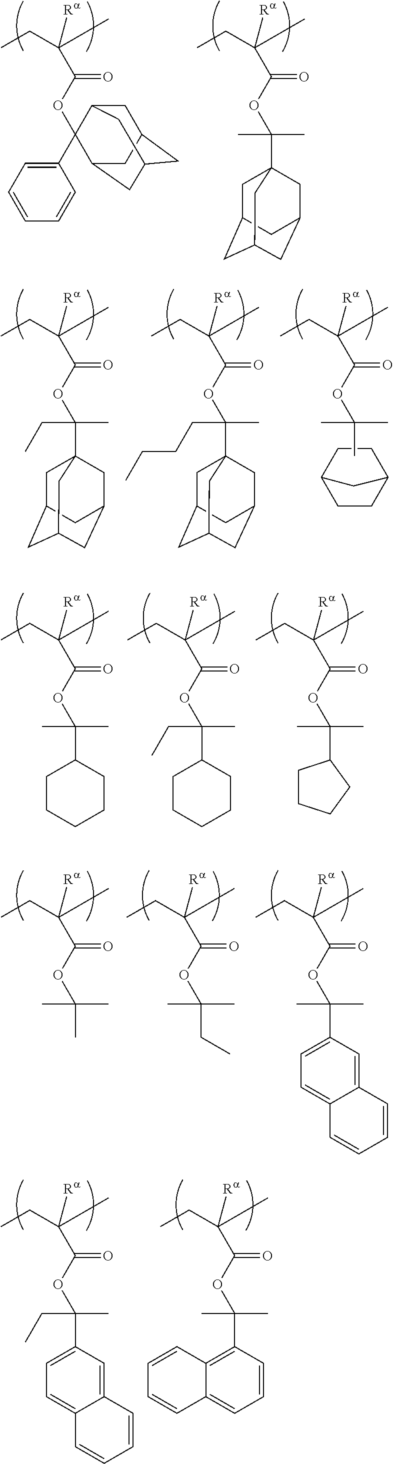

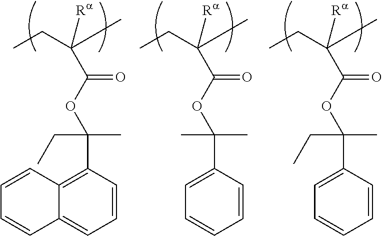

One kind of the constitutional unit (a1) may be used alone, or a combination of two or more kinds thereof may be used.

In a case where the component (P) has the constitutional unit (a1), the proportion of the constitutional unit (a1) in the component (P) is preferably in a range of 1% to 60% by mole, more preferably in a range of 10% to 50% by mole, and still more preferably in a range of 20% to 40% by mole, with respect to the total (100% by mole) of all constitutional units constituting the component (P).

On the other hand, in a case where the proportion of the constitutional unit (a1) is set to be equal to or larger than the lower limit value of the above preferred range, balance with other constitutional units is easily obtained.

Constitutional Unit (a2)

The constitutional unit (a2) is a constitutional unit containing a lactone-containing cyclic group, a —SO₂—-containing cyclic group, or a carbonate-containing cyclic group (however, a constitutional unit containing an acid dissociable group is excluded).

The term “lactone-containing cyclic group” indicates a cyclic group that contains a ring (lactone ring) containing a —O—C(═O)— in the ring skeleton. In a case where the lactone ring is counted as the first ring and the group contains only the lactone ring, the group is referred to as a monocyclic group. Further, in a case where the group has other ring structures, the group is referred to as a polycyclic group regardless of the structures. The lactone-containing cyclic group may be a monocyclic group or a polycyclic group.

The lactone-containing cyclic group for the constitutional unit (a2) is not particularly limited, and any lactone-containing cyclic group may be used. Specific examples thereof include groups each represented by General Formulae (a2-r-1) to (a2-r-7) shown below.

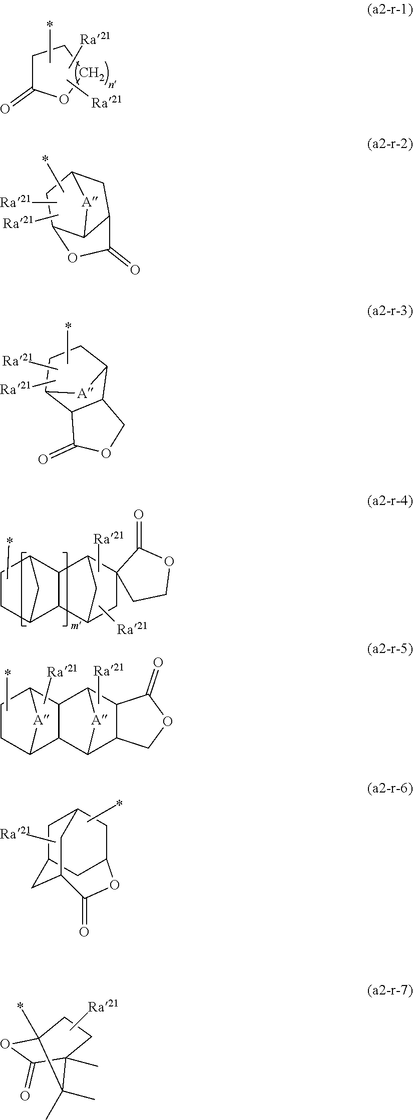

[In the formulae, Ra′²¹s each independently represent a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂—-containing cyclic group; A″ represents an oxygen atom, a sulfur atom, or an alkylene group having 1 to 5 carbon atoms, which may contain an oxygen atom (—O—) or a sulfur atom (—S—); and n′ represents an integer in a range of 0 to 2, and m′ is 0 or 1.]

In General Formulae (a2-r-1) to (a2-r-7), the alkyl group as Ra′²¹ is preferably an alkyl group having 1 to 6 carbon atoms. The alkyl group is preferably a linear alkyl group or a branched alkyl group. Specific examples thereof include a methyl group, an ethyl group, a propyl group, an isopropyl group, an n-butyl group, an isobutyl group, a tert-butyl group, a pentyl group, an isopentyl group, a neopentyl group, and a hexyl group. Among these, a methyl group or ethyl group is preferable, and a methyl group is particularly preferable.

The alkoxy group as Ra′²¹ is preferably an alkoxy group having 1 to 6 carbon atoms. Further, the alkoxy group is preferably a linear or branched alkoxy group. Specific examples of the alkoxy groups include a group formed by linking the above-described alkyl group mentioned as the alkyl group represented by Ra′²¹ to an oxygen atom (—O—).

Examples of the halogenated alkyl group as Ra′²¹ include a group obtained by substituting part or all hydrogen atoms in the above-described alkyl group as Ra′²¹ with the above-described halogen atoms.

In —COOR″ and —OC(═O)R″ as Ra′²¹, R″ represents a hydrogen atom, an alkyl group, a lactone-containing cyclic group, a carbonate-containing cyclic group, or a —SO₂—-containing cyclic group.

The alkyl group as R″ may be linear, branched, or cyclic, and preferably has 1 to 15 carbon atoms.

In a case where R″ represents a linear or branched alkyl group, it is preferably an alkyl group having 1 to 10 carbon atoms, more preferably an alkyl group having 1 to 5 carbon atoms, and particularly preferably a methyl group or an ethyl group.

In a case where R″ represents a cyclic alkyl group, the cyclic alkyl group preferably has 3 to 15 carbon atoms, more preferably 4 to 12 carbon atoms, and particularly preferably 5 to 10 carbon atoms. Specific examples thereof include a group obtained by removing one or more hydrogen atoms from a monocycloalkane, which may be or may not be substituted with a halogen atom or a halogenated alkyl group; and a group obtained by removing one or more hydrogen atoms from a polycycloalkane such as bicycloalkane, tricycloalkane, or tetracycloalkane. More specific examples thereof include a group obtained by removing one or more hydrogen atoms from a monocycloalkane such as cyclopentane or cyclohexane; and a group obtained by removing one or more hydrogen atoms from a polycycloalkane such as adamantane, norbornane, isobornane, tricyclodecane, or tetracyclododecane.

Examples of the lactone-containing cyclic group as R″ include the same ones as the groups each represented by General Formulae (a2-r-1) to (a2-r-7).

The carbonate-containing cyclic group as R″ has the same definition as that for the carbonate-containing cyclic group described below.

Specific examples of the carbonate-containing cyclic group include groups each represented by General Formulae (ax3-r-1) to (ax3-r-3).

The —SO₂—-containing cyclic group as R″ has the same definition as that for the —SO₂—-containing cyclic group described below.

Specific examples thereof include groups each represented by General Formulae (a5-r-1) to (a5-r-4).

The hydroxyalkyl group as Ra′²¹ preferably has 1 to 6 carbon atoms, and specific examples thereof include a group obtained by substituting at least one hydrogen atom in the alkyl group as Ra′²¹ with a hydroxyl group.

In General Formulae (a2-r-2), (a2-r-3) and (a2-r-5), as the alkylene group having 1 to 5 carbon atoms as A″, a linear or branched alkylene group is preferable, and examples thereof include a methylene group, an ethylene group, an n-propylene group, and an isopropylene group. Specific examples of the alkylene groups that contain an oxygen atom or a sulfur atom include a group obtained by interposing —O— or —S— in the terminal of the alkylene group or between the carbon atoms of the alkylene group, and examples thereof include —O—CH₂—, —CH₂—O—CH₂—, —S—CH₂—, and —CH₂—S—CH₂—. A″ is preferably an alkylene group having 1 to 5 carbon atoms or —O—, more preferably an alkylene group having 1 to 5 carbon atoms, and most preferably a methylene group.

Specific examples of the groups each represented by General Formulae (a2-r-1) to (a2-r-7) are shown below.

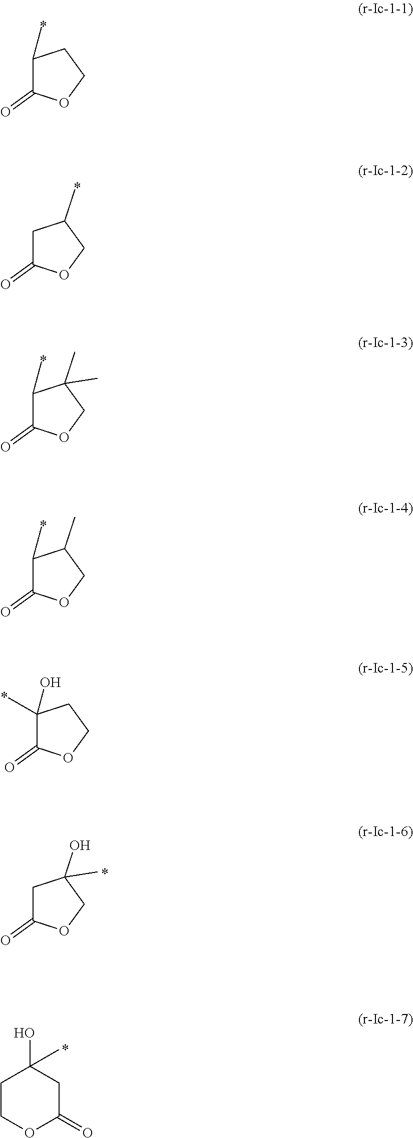

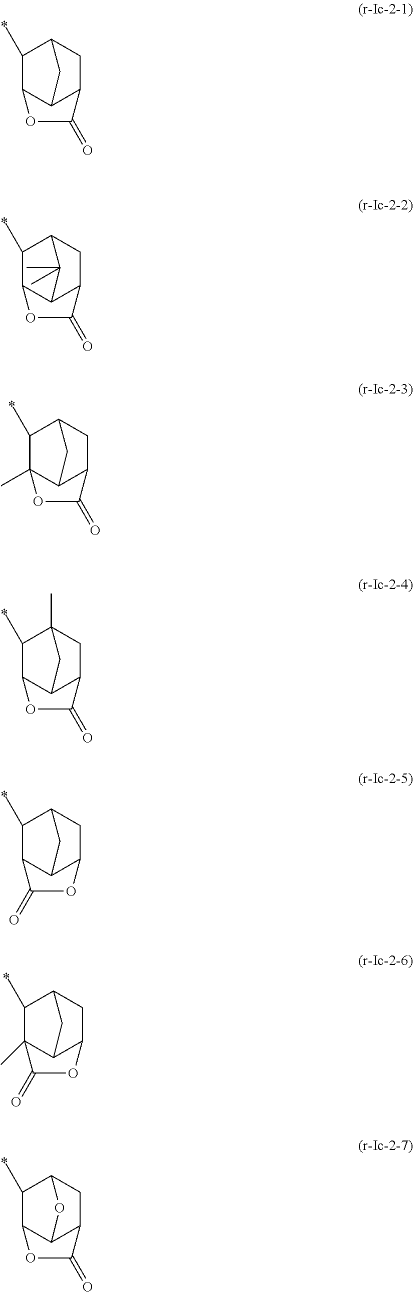

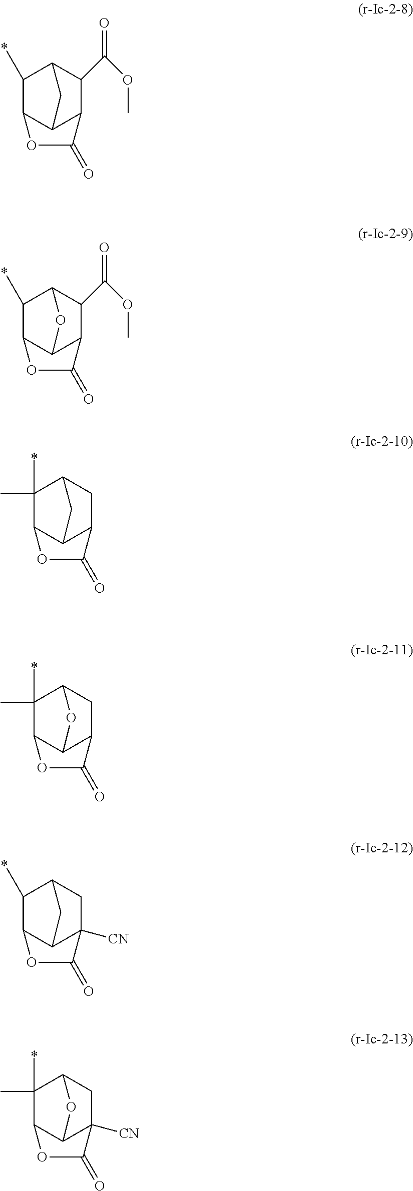

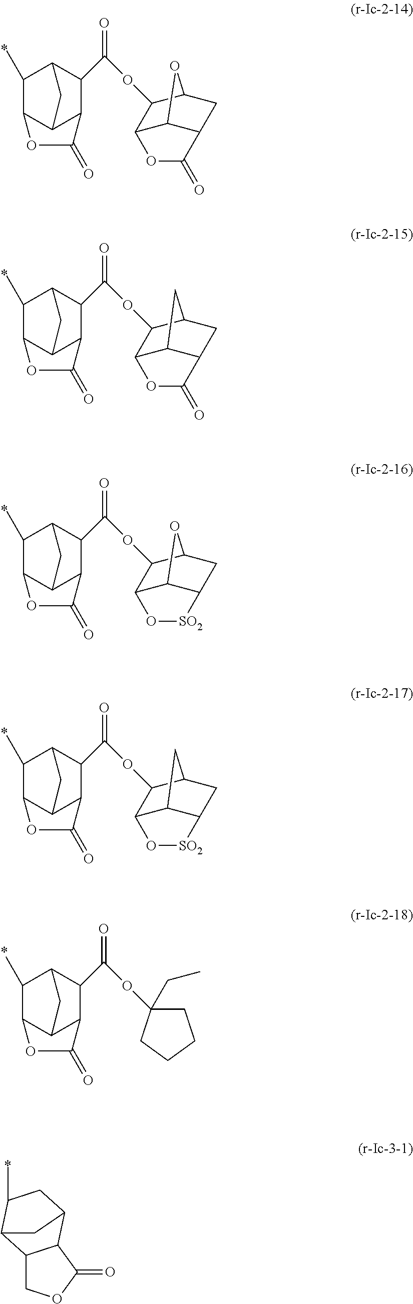

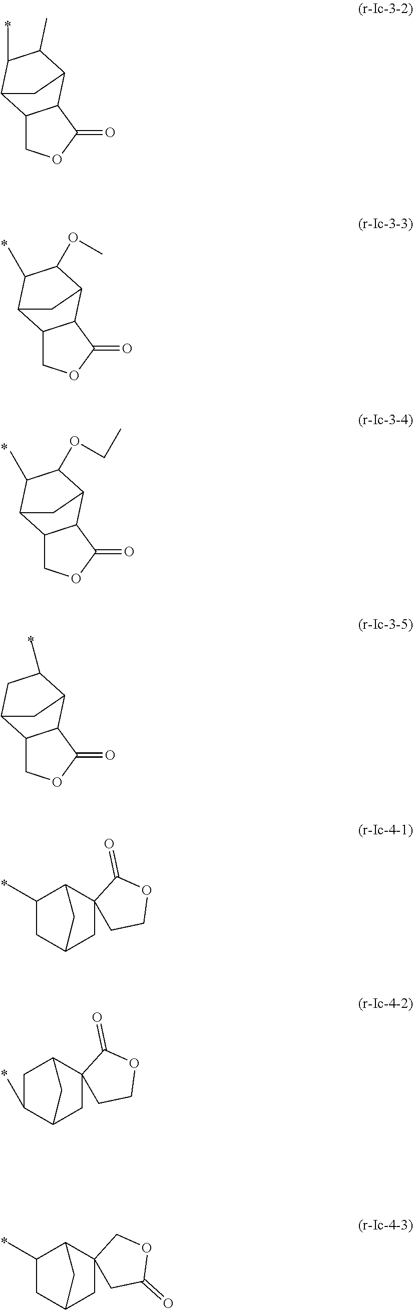

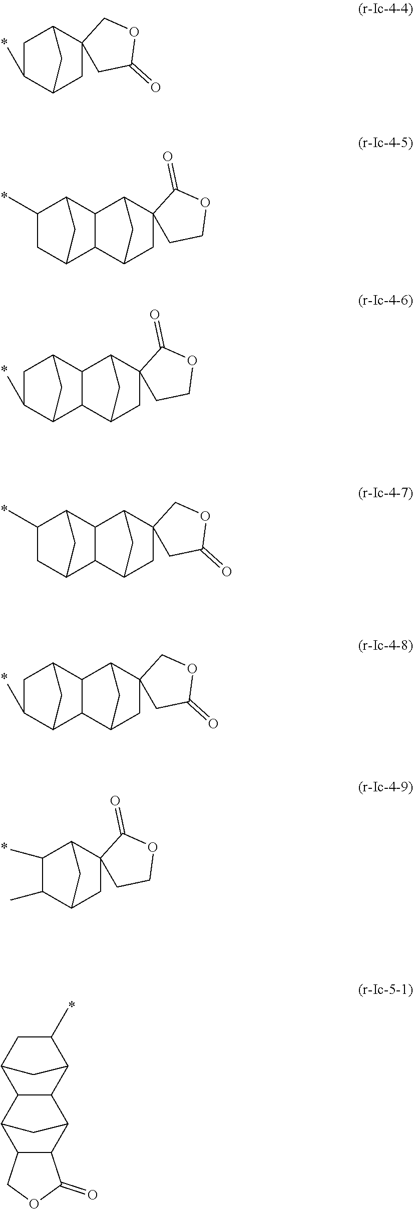

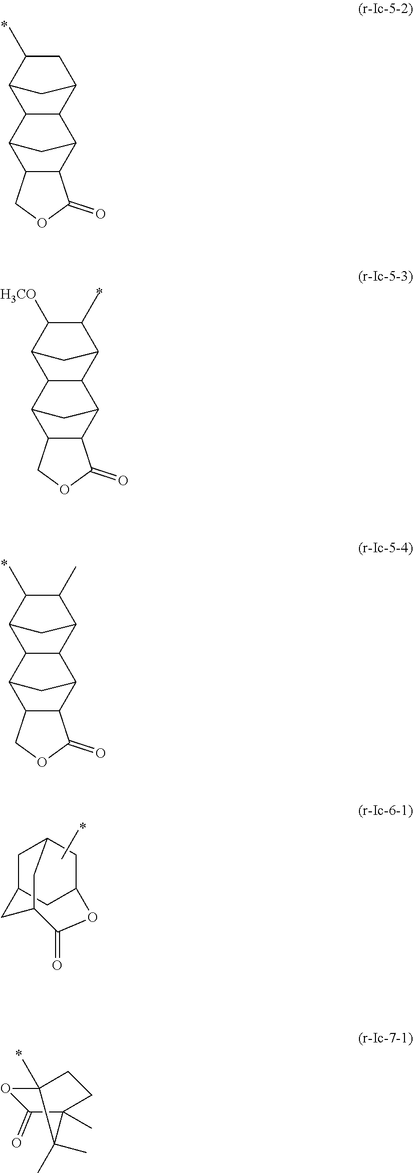

The “—SO₂—-containing cyclic group” indicates a cyclic group having a ring containing —SO₂— in the ring skeleton thereof. Specifically, the —SO₂—-containing cyclic group is a cyclic group in which the sulfur atom (S) in —SO₂— forms a part of the ring skeleton of the cyclic group. In a case where the ring containing —SO₂— in the ring skeleton thereof is counted as the first ring and the group contains only the ring, the group is referred to as a monocyclic group. In a case where the group further has other ring structures, the group is referred to as a polycyclic group regardless of the structures. The —SO₂—-containing cyclic group may be a monocyclic group or a polycyclic group.

The —SO₂—-containing cyclic group is particularly preferably a cyclic group containing —O—SO₂— in the ring skeleton thereof, in other words, a cyclic group containing a sultone ring in which —O—S— in the —O—SO₂— group forms a part of the ring skeleton thereof.

More specific examples of the —SO₂—-containing cyclic group include groups each represented by General Formulae (a5-r-1) to (a5-r-4) shown below.

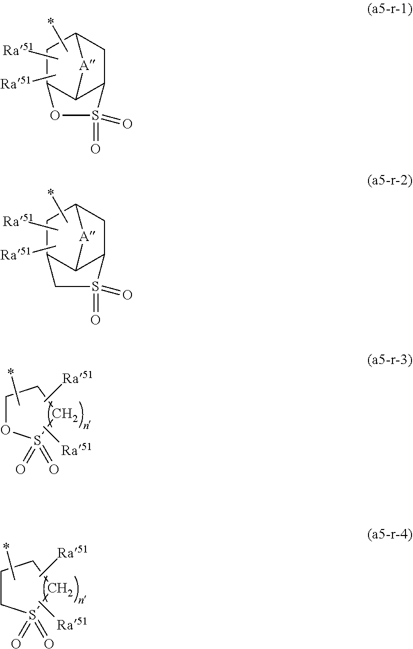

[In the formulae, Ra′⁵¹s each independently represent a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂—-containing cyclic group; A″ represents an oxygen atom, a sulfur atom, or an alkylene group having 1 to 5 carbon atoms, which may contain an oxygen atom or a sulfur atom; and n′ represents an integer in a range of 0 to 2.]

In General Formulae (a5-r-1) and (a5-r-2), A″ has the same definition as that for A″ in General Formulae (a2-r-2), (a2-r-3) and (a2-r-5).

Examples of the alkyl group, the alkoxy group, the halogen atom, the halogenated alkyl group, —COOR″, —OC(═O)R″, and the hydroxyalkyl group as Ra′ each include the same ones as those mentioned in the explanation of Ra′²¹ in General Formulae (a2-r-1) to (a2-r-7).

Specific examples of the groups each represented by General Formulae (a5-r-1) to (a5-r-4) are shown below. In the formulae shown below, “Ac” represents an acetyl group.

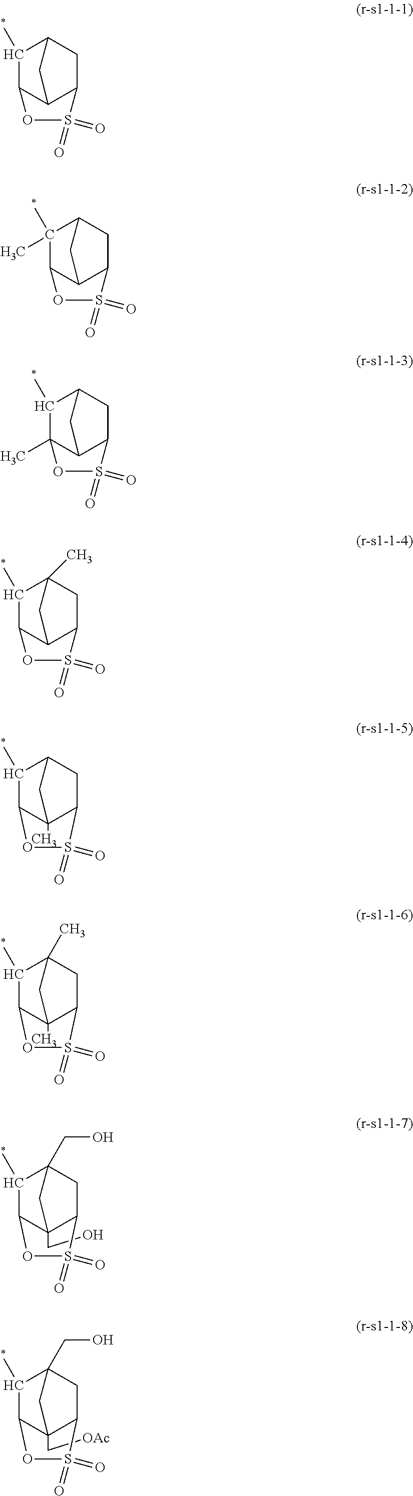

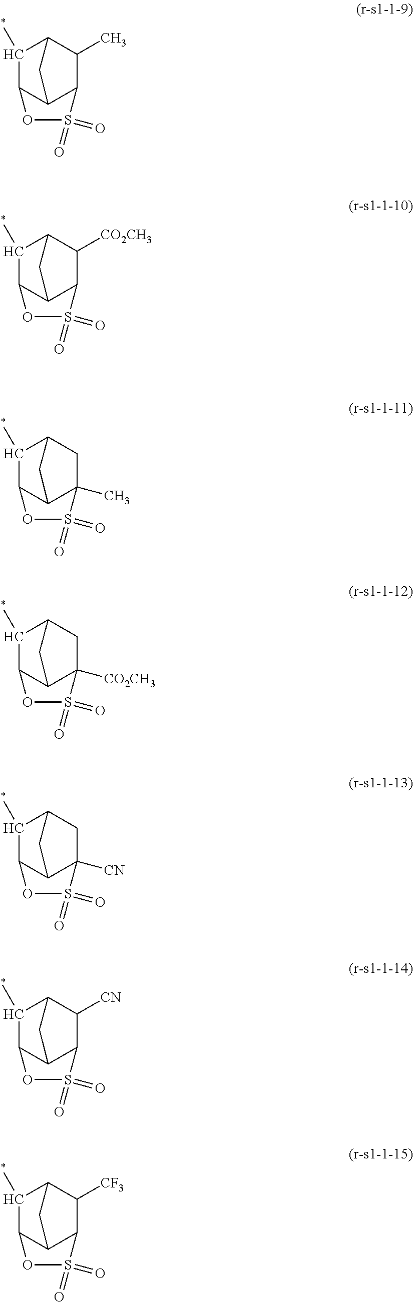

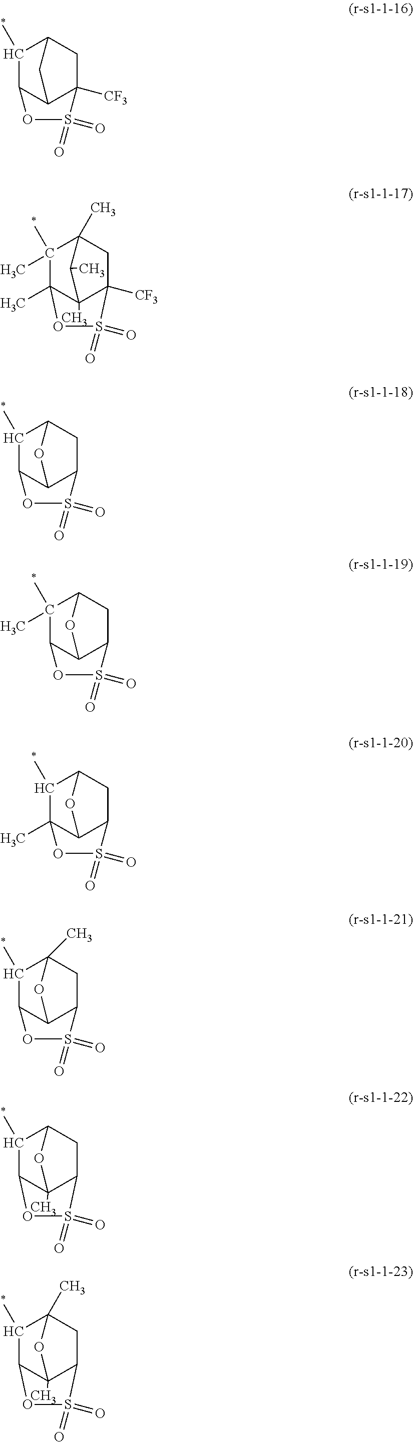

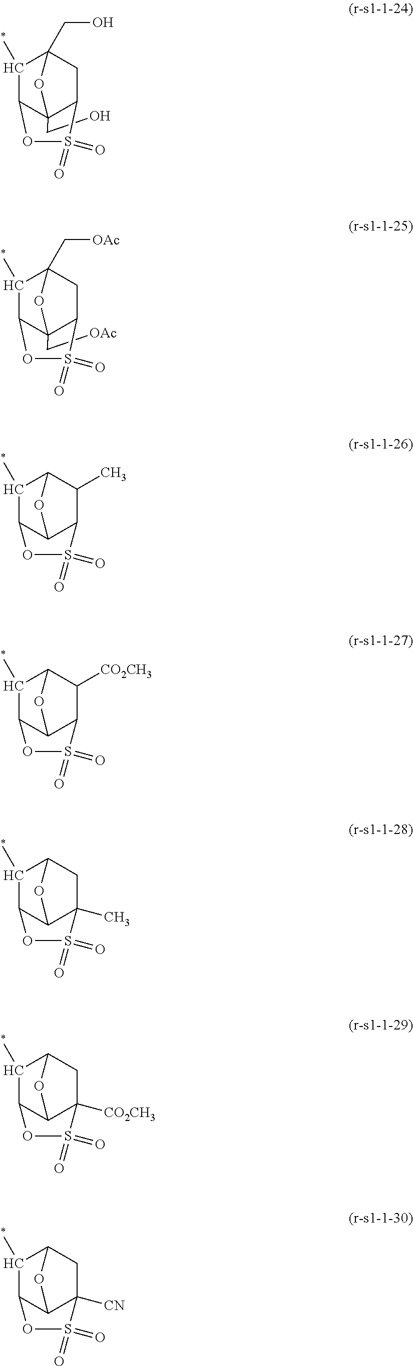

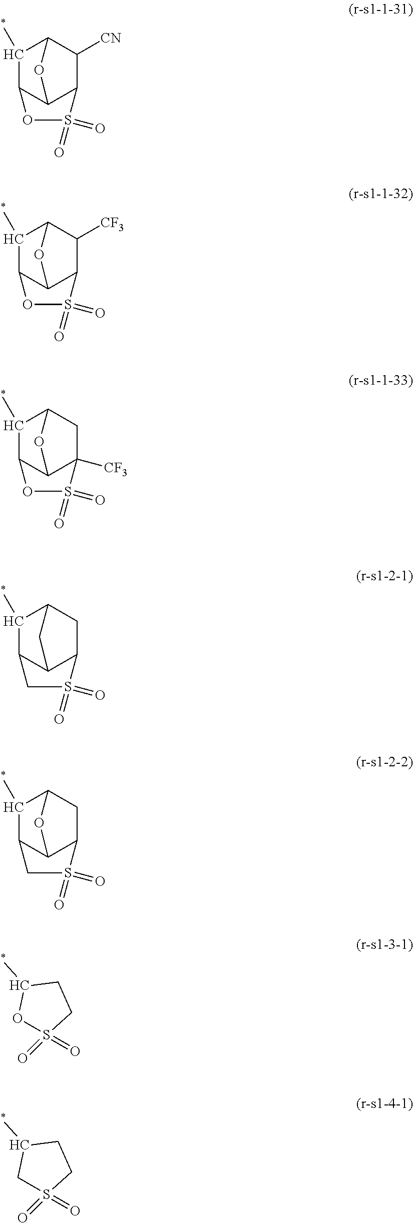

The “carbonate-containing cyclic group” indicates a cyclic group having a ring (a carbonate ring) containing —O—C(═O)—O— in the ring skeleton thereof. In a case where the carbonate ring is counted as the first ring and the group contains only the carbonate ring, the group is referred to as a monocyclic group. Further, in a case where the group has other ring structures, the group is referred to as a polycyclic group regardless of the structures. The carbonate-containing cyclic group may be a monocyclic group or a polycyclic group.

The carbonate ring-containing cyclic group is not particularly limited, and any carbonate ring-containing cyclic group may be used. Specific examples thereof include groups each represented by General Formulae (ax3-r-1) to (ax3-r-3) shown below.

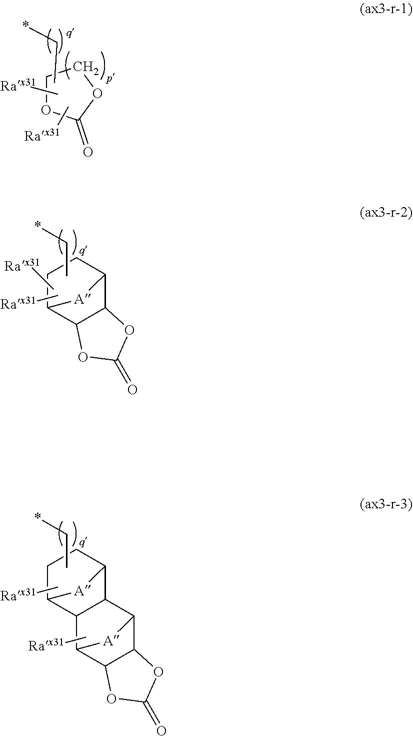

[In the formulae, Ra′^{x31}s each independently represent a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂—-containing cyclic group; A″ represents an oxygen atom, a sulfur atom, or an alkylene group having 1 to 5 carbon atoms, which may contain an oxygen atom or a sulfur atom; and p′ represents an integer in a range of 0 to 3, and q′ is 0 or 1.]

In General Formulae (ax3-r-2) and (ax3-r-3), A″ has the same definition as that for A″ in General Formulae (a2-r-2), (a2-r-3) and (a2-r-5).

Examples of the alkyl group, the alkoxy group, the halogen atom, the halogenated alkyl group, —COOR″, —OC(═O)R″, and the hydroxyalkyl group as Ra′³¹ each include the same ones as those mentioned in the explanation of Ra′²¹ in General Formulae (a2-r-1) to (a2-r-7).

Specific examples of the groups each represented by General Formulae (ax3-r-1) to (ax3-r-3) are shown below.

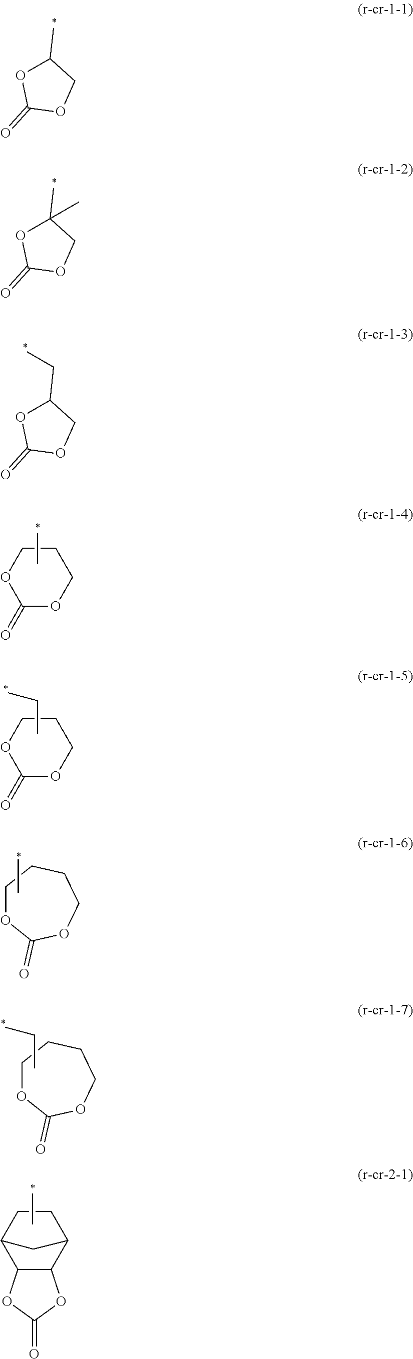

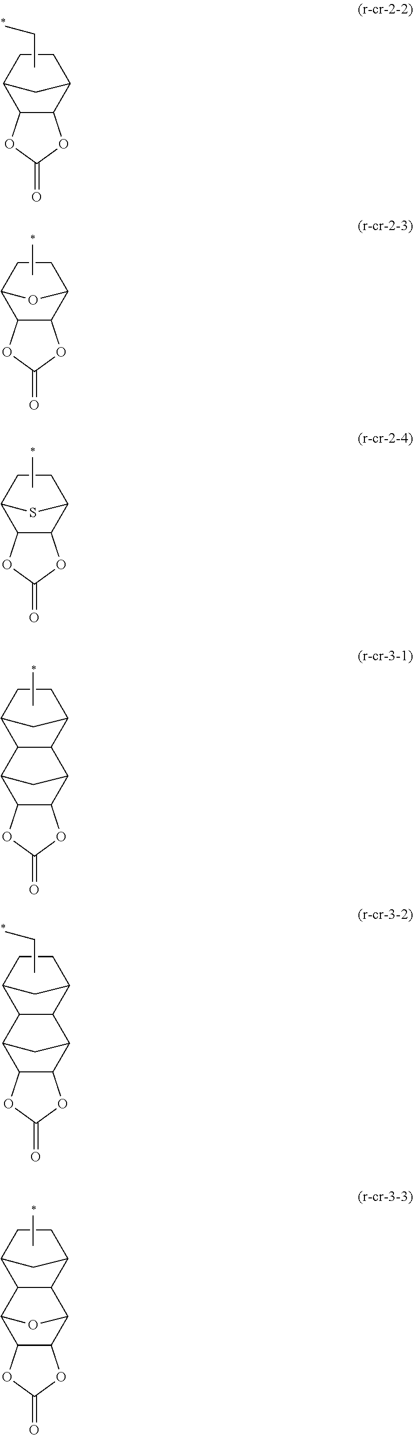

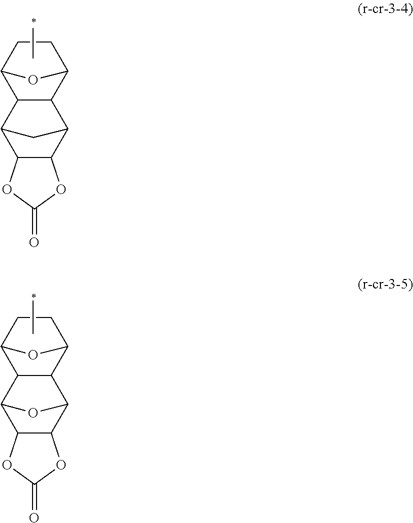

Among them, the constitutional unit (a2) is preferably a constitutional unit derived from acrylic acid ester in which the hydrogen atom bonded to the carbon atom at the α-position may be substituted with a substituent.

The constitutional unit (a2) is preferably a constitutional unit represented by General Formula (a2-1).

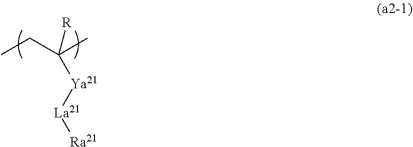

[In the formula, R is the same as R in General Formula (a02-1). Ya²¹ represents a single bond or a divalent linking group. La²¹ represents —O—, —COO—, —CON(R′)—, —OCO—, —CONHCO— or —CONHCS—, and R represents a hydrogen atom or a methyl group. However, in a case where La²¹ represents —O—, Ya²¹ does not represent —CO—. Ra²¹ represents a lactone-containing cyclic group, a carbonate-containing cyclic group, or a —SO₂—-containing cyclic group.]

In General Formula (a2-1), R has the same definition as described above.

In General Formula (a2-1), the divalent linking group as Ya²¹ is not particularly limited, and suitable examples thereof include a divalent hydrocarbon group which may have a substituent and a divalent linking group having a hetero atom.

Divalent Hydrocarbon Group which May have Substituent:

In a case where Ya²¹ represents a divalent hydrocarbon group which may have a substituent, the hydrocarbon group may be an aliphatic hydrocarbon group or an aromatic hydrocarbon group.

Aliphatic Hydrocarbon Group as Ya²¹

The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

Examples of the aliphatic hydrocarbon group include a linear or branched aliphatic hydrocarbon group, and an aliphatic hydrocarbon group containing a ring in the structure thereof.

Linear or Branched Aliphatic Hydrocarbon Group

The linear aliphatic hydrocarbon group described above preferably has 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group described above preferably has 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The linear or branched aliphatic hydrocarbon group may have or may not have a substituent. Examples of the substituent include a halogen atom, a halogenated alkyl group having 1 to 5 carbon atoms, which has been substituted with a halogen atom, and a carbonyl group.

Aliphatic Hydrocarbon Group Containing Ring in Structure Thereof

Examples of the aliphatic hydrocarbon group containing a ring in the structure thereof include a cyclic aliphatic hydrocarbon group which may have a substituent containing a hetero atom in the ring structure thereof (a group obtained by removing two hydrogen atoms from an aliphatic hydrocarbon ring), a group obtained by bonding the cyclic aliphatic hydrocarbon group to the terminal of a linear or branched aliphatic hydrocarbon group, and a group obtained by interposing the cyclic aliphatic hydrocarbon group in a linear or branched aliphatic hydrocarbon group. Examples of the linear or branched aliphatic hydrocarbon group include the same ones as those described above.

The cyclic aliphatic hydrocarbon group preferably has 3 to 20 carbon atoms and more preferably 3 to 12 carbon atoms.

The cyclic aliphatic hydrocarbon group may be a polycyclic group or a monocyclic group. The monocyclic alicyclic hydrocarbon group is preferably a group obtained by removing two hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing two hydrogen atoms from a polycycloalkane, and the polycycloalkane is preferably a group having 7 to 12 carbon atoms. Specific examples of the polycyclic alicyclic hydrocarbon group include adamantane, norbornane, isobornane, tricyclodecane, and tetracyclododecane.

The cyclic aliphatic hydrocarbon group may have or may not have a substituent. Examples of the substituent include an alkyl group, an alkoxy group, a halogen atom, a halogenated alkyl group, a hydroxyl group, and a carbonyl group.

The alkyl group as the substituent is preferably an alkyl group having 1 to 5 carbon atoms, and most preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group or an ethoxy group.

Examples of the halogenated alkyl group as the substituent include groups obtained by substituting part or all hydrogen atoms in the above-described alkyl groups with the above-described halogen atoms.

In the cyclic aliphatic hydrocarbon group, part of carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.

Aromatic Hydrocarbon Group as Ya²¹

The aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. Here, the number of carbon atoms in a substituent is not included in the number of carbon atoms.

Specific examples of the aromatic ring include aromatic hydrocarbon rings such as benzene, naphthalene, anthracene, and phenanthrene; and an aromatic heterocyclic ring obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group include a group (an arylene group or a heteroarylene group) obtained by removing two hydrogen atoms from the above-described aromatic hydrocarbon ring or the above-described aromatic heterocyclic ring; a group obtained by removing two hydrogen atoms from an aromatic compound having two or more aromatic rings (such as biphenyl or fluorene); and a group (for example, a group obtained by further removing one hydrogen atom from an aryl group in arylalkyl groups such as a benzyl group, a phenethyl group, a 1-naphthylmethyl group, a 2-naphthylmethyl group, a 1-naphthylethyl group, or a 2-naphthylethyl group) obtained by substituting one hydrogen atom of a group (an aryl group or a heteroaryl group) obtained by removing one hydrogen atom from the above aromatic hydrocarbon ring or the above aromatic heterocyclic ring, with an alkylene group. The alkylene group bonded to the aryl group or the heteroaryl group preferably has 1 to 4 carbon atoms, more preferably 1 or 2 carbon atoms, and particularly preferably 1 carbon atom.

With respect to the aromatic hydrocarbon group, the hydrogen atom contained in the aromatic hydrocarbon group may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group having 1 to 5 carbon atoms, and most preferably a methyl group, an ethyl group, a propyl group, an n-butyl group, or a tert-butyl group.

Examples of the alkoxy group, the halogen atom, and the halogenated alkyl group, as the substituent, include those the same as those exemplified as the substituent that is substituted for a hydrogen atom contained in the cyclic aliphatic hydrocarbon group.

Divalent Linking Group Containing Hetero Atom:

In a case where Ya²¹ represents a divalent linking group containing a hetero atom, preferred examples of the linking group include —O—, —C(═O)—O—, —O—C(═O)—, —C(═O)—, —O—C(═O)—O—, —C(═O)—NH—, —NH—, —NH—C(═NH)— (H may be substituted with a substituent such as an alkyl group, an acyl group, or the like), —S—, —S(═O)₂—, —S(═O)₂—O—, and a group represented by General Formula —Y²¹—O—Y²²—, —Y²¹—O—, —Y²¹—C(═O)—O—, —C(═O)—O—Y²¹—, —[Y²¹—C(═O)—O]ₘ″-Y²²—, —Y²¹—O—C(═O)—Y²²— or —Y²¹—S(═O)₂—O—Y²²— [in the formulae, Y²¹ and Y²² each independently represent a divalent hydrocarbon group which may have a substituent, O represents an oxygen atom, and m″ represents an integer in a range of 0 to 3].

In a case where the divalent linking group containing a hetero atom is —C(═O)—NH—, —C(═O)—NH—C(═O)—, —NH—, or —NH—C(═NH)—, H may be substituted with a substituent such as an alkyl group, an acyl group, or the like. The substituent (an alkyl group, an acyl group, or the like) preferably has 1 to 10 carbon atoms, more preferably 1 to 8 carbon atoms, and particularly preferably 1 to 5 carbon atoms.

In General Formulae —Y²¹—O—Y²²—, —Y²¹—O—, —Y²¹—C(═O)—O—, —C(═O)—O—Y²¹—, —[Y²¹—C(═O)—O]ₘ″-Y²²—, —Y²¹—O—C(═O)—Y²²—, and —Y²¹—S(═O)₂—O—Y²²—, Y²¹, and Y²² each independently represent a divalent hydrocarbon group which may have a substituent. Examples of the divalent hydrocarbon group include the same one as the divalent hydrocarbon group which may have a substituent, mentioned in the explanation of the above-described divalent linking group as Ya²¹.

Y²¹ is preferably a linear aliphatic hydrocarbon group, more preferably a linear alkylene group, still more preferably a linear alkylene group having 1 to 5 carbon atoms, and particularly preferably a methylene group or an ethylene group.

Y²² is preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by Formula —[Y²¹—C(═O)—O]ₘ″-Y²²—, m″ represents an integer in a range of 0 to 3, preferably an integer in a range of 0 to 2, more preferably 0 or 1, and particularly preferably 1. In other words, it is particularly preferable that the group represented by Formula —[Y²¹—C(═O)—O]ₘ″-Y²²— represents a group represented by Formula —Y²¹—C(═O)—O—Y²²—. Among these, a group represented by Formula —(CH₂)ₐ′-C(═O)—O—(CH₂)_{b}′— is preferable. In the formula, a′ represents an integer in a range of 1 to 10, preferably an integer in a range of 1 to 8, more preferably an integer in a range of 1 to 5, still more preferably 1 or 2, and most preferably 1. b′ represents an integer in a range of 1 to 10, preferably an integer in a range of 1 to 8, more preferably an integer in a range of 1 to 5, still more preferably 1 or 2, and most preferably 1.

Among the above, Ya²¹ is preferably a single bond, an ester bond [—C(═O)—O—], an ether bond (—O—), a linear or branched alkylene group, or a combination thereof.

In General Formula (a2-1), Ra²¹ represents a lactone-containing cyclic group, a —SO₂—-containing cyclic group, or a carbonate-containing cyclic group.

Suitable examples of the lactone-containing cyclic group, the —SO₂—-containing cyclic group, and the carbonate-containing cyclic group as Ra²¹ include groups each represented by General Formulae (a2-r-1) to (a2-r-7), groups each represented by General Formulae (a5-r-1) to (a5-r-4), and groups each represented by General Formulae (ax3-r-1) to (ax3-r-3) described above.

Among them, a lactone-containing cyclic group or a —SO₂—-containing cyclic group is preferable, and groups each represented by General Formula (a2-r-1), (a2-r-2), (a2-r-6), or (a5-r-1) are more preferable. Specifically, groups each represented by any of Chemical Formulae (r-1c-1-1) to (r-1c-1-7), (r-1c-2-1) to (r-1c-2-18), (r-1c-6-1), (r-s1-1-1), and (r-s1-1-18) are more preferable.

Constitutional Unit (a3)

The constitutional unit (a3) is a constitutional unit containing a polar group (however, a constitutional unit containing an acid dissociable group and a constitutional unit corresponding to the constitutional unit (a2) are excluded). The constitutional unit (a3) is preferably a constitutional unit containing a polar group-containing aliphatic hydrocarbon group.

Examples of the polar group include a hydroxyl group, a cyano group, a carboxy group, or a hydroxyalkyl group obtained by substituting part of hydrogen atoms of the alkyl group with a halogen atom, and an oxy group (—O—), and a hydroxyl group is particularly preferable.

In a case where the constitutional unit (a3) contains a polar group-containing aliphatic hydrocarbon group, the aliphatic hydrocarbon group is a linear or branched hydrocarbon group having 1 to 10 carbon atoms (preferably an alkylene group) or a cyclic aliphatic hydrocarbon group (a cyclic group). The cyclic group may be a monocyclic group or a polycyclic group. For example, these cyclic groups can be appropriately selected from a large number of groups that have been proposed in resins for a resist composition for an ArF excimer laser.

In a case where the cyclic group is a monocyclic group, the monocyclic group preferably has 3 to 10 carbon atoms. Among them, a constitutional unit derived from an acrylic acid ester that contains an aliphatic monocyclic group containing a hydroxyl group, a cyano group, a carboxy group, or a hydroxyalkyl group obtained by substituting part of hydrogen atoms of an alkyl group with a halogen atom is more preferable. Examples of the monocyclic group include a group obtained by removing two or more hydrogen atoms from a monocycloalkane. Specific examples of the monocyclic group include a group obtained by removing two or more hydrogen atoms from a monocycloalkane such as cyclopentane, cyclohexane, or cyclooctane. Among these monocyclic groups, a group obtained by removing two or more hydrogen atoms from cyclopentane or a group obtained by removing two or more hydrogen atoms from cyclohexane are industrially preferable.

In a case where the cyclic group is a polycyclic group, the polycyclic group preferably has 7 to 30 carbon atoms. Among them, a constitutional unit derived from an acrylic acid ester that contains an aliphatic polycyclic group containing a hydroxyl group, a cyano group, a carboxy group, or a hydroxyalkyl group obtained by substituting part of hydrogen atoms of an alkyl group with a halogen atom is more preferable. Examples of the polycyclic group include groups obtained by removing two or more hydrogen atoms from a bicycloalkane, tricycloalkane, tetracycloalkane, or the like. Specific examples thereof include a group obtained by removing two or more hydrogen atoms from a polycycloalkane such as adamantane, norbornane, isobornane, tricyclodecane, or tetracyclododecane. Among these polycyclic groups, a group obtained by removing two or more hydrogen atoms from adamantane, a group obtained by removing two or more hydrogen atoms from norbornane, or a group obtained by removing two or more hydrogen atoms from tetracyclododecane are industrially preferable.

The constitutional unit (a3) is not particularly limited, and any constitutional unit may be used as long as the constitutional unit contains a polar group.

The constitutional unit (a3) is preferably a constitutional unit derived from an acrylic acid ester in which the hydrogen atom bonded to the carbon atom at the α-position may be substituted with a substituent, where the constitutional unit contains a polar group-containing aliphatic hydrocarbon group.

In a case where the hydrocarbon group in the polar group-containing aliphatic hydrocarbon group is a linear or branched hydrocarbon group having 1 to 10 carbon atoms, the constitutional unit (a3) is preferably a constitutional unit derived from a hydroxyethyl ester of acrylic acid.

In addition, in a case where the hydrocarbon group in the polar group-containing aliphatic hydrocarbon group is a polycyclic group, preferred examples of the constitutional unit (a3) include a constitutional unit represented by General Formula (a3-1) and a constitutional unit represented by General Formula (a3-2), shown below.

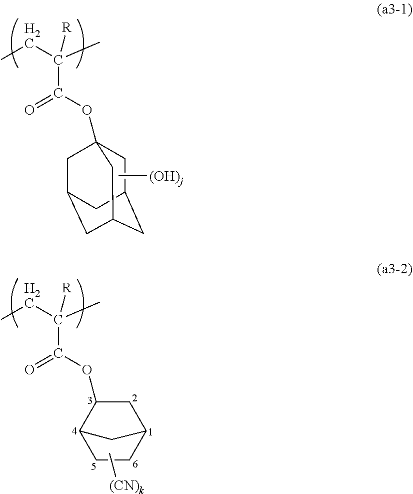

[In the formulae, R has the same definition as described above, j represents an integer in a range of 1 to 3, k represents an integer in a range of 1 to 3, C represents an integer in a range of 1 to 3, 1 represents an integer in a range of 0 to 5, and s represents an integer in a range of 1 to 3.]

In General Formula (a3-1), j preferably represents 1 or 2 and more preferably 1. In a case where j represents 2, it is preferable that the hydroxyl groups are bonded to the 3-position and the 5-position of the adamantyl group. In a case where j represents 1, it is preferable that the hydroxyl group is bonded to the 3-position of the adamantyl group.

It is preferable that j represent 1, and it is particularly preferable that the hydroxyl group is bonded to the 3-position of the adamantyl group.

In General Formula (a3-2), k preferably represents 1. The cyano group is preferably bonded to the 5- or 6-position of the norbornyl group.

Specific examples of the constitutional unit (a3) are shown below but are not limited thereto. In each of the following formulae, R^{α} represents a hydrogen atom or a methyl group.

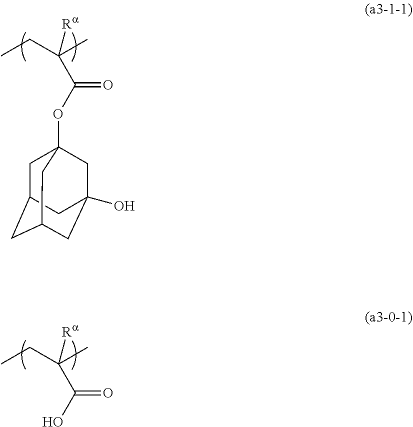

Constitutional Unit (a9)

The constitutional unit (a9) is a constitutional unit represented by General Formula (a9-1).

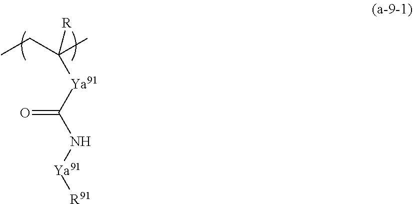

[In the formula, R is the same as R in General Formula (a02-1). Ya⁹¹ represents a single bond or a divalent linking group. Ya⁹² represents a divalent linking group. R⁹¹ represents a hydrocarbon group which may have a substituent.

In General Formula (a9-1), R is the same as R in General Formula (a02-1).

In General Formula (a9-1), the divalent linking group as Ya⁹¹ is the same as the content described in Ya^{x0} described above. Among the above, Ya⁹¹ is preferably a single bond.

In General Formula (a9-1), the divalent linking group as Ya⁹² is the same as the content described in Ya^{x0} described above.

In the divalent linking group as Ya⁹², the divalent hydrocarbon group which may have a substituent is preferably a linear or branched aliphatic hydrocarbon group.

In addition, in the divalent linking group as Ya⁹², examples of the divalent linking group containing a hetero atom include —O—, —C(═O)—O—, —C(═O)—, —O—C(═O)—O—, —C(═O)—NH—, —NH—, —NH—C(═NH)—(H may be substituted with a substituent such as an alkyl group, an acyl group, or the like), —S—, —S(═O)₂—, —S(═O)₂—O—, —C(═S)—, and a group represented by General Formula —Y²¹—O—Y²²—, —Y²¹—O—, —Y²¹—C(═O)—O—, —C(═O)—O—Y²¹, [Y²¹—C(═O)—O]ₘ′-Y²²—, or —Y²¹—O—C(═O)—Y²²— [in the formulae, Y²¹ and Y²² each independently represent a divalent hydrocarbon group which may have a substituent, O represents an oxygen atom, and m′ represents an integer in a range of 0 to 3]. Among the above, —C(═O)— or —C(═S)— is preferable.

In General Formula (a9-1), examples of the hydrocarbon group as R⁹¹ include an alkyl group, a monovalent alicyclic hydrocarbon group, an aryl group, and an aralkyl group.

The alkyl group as R⁹¹ preferably has 1 to 8 carbon atoms, more preferably 1 to 6 carbon atoms, and still more preferably 1 to 4 carbon atoms, and it may be linear or may be branched. Specifically, preferred examples thereof include a methyl group, an ethyl group, a propyl group, a butyl group, a hexyl group, and an octyl group.

The monovalent alicyclic hydrocarbon group as R⁹¹ preferably has 3 to 20 carbon atoms and more preferably 3 to 12 carbon atoms, and it may be polycyclic or may be monocyclic. The monocyclic alicyclic hydrocarbon group is preferably a group obtained by removing one or more hydrogen atoms from a monocycloalkane. The monocycloalkane preferably has 3 to 6 carbon atoms, and specific examples thereof include cyclobutane, cyclopentane, and cyclohexane. The polycyclic alicyclic hydrocarbon group is preferably a group obtained by removing one or more hydrogen atoms from a polycycloalkane, and the polycycloalkane is preferably a group having 7 to 12 carbon atoms. Specific examples of the polycyclic alicyclic hydrocarbon group include adamantane, norbornane, isobornane, tricyclodecane, and tetracyclododecane.

The aryl group as R⁹¹ preferably has 6 to 18 carbon atoms, more preferably 6 to 10 carbon atoms, and particularly preferably a phenyl group.

The aralkyl group as R⁹¹ is preferably an aralkyl group obtained by bonding an alkylene group having 1 to 8 carbon atoms to the above-described “aryl group as R⁹¹” more preferably an aralkyl group obtained by bonding an alkylene group having 1 to 6 carbon atoms to the above-described “aryl group as R⁹¹”, and particularly preferably an aralkyl group obtained by bonding an alkylene group having 1 to 4 carbon atoms to the above-described “aryl group as R⁹¹”.

The hydrocarbon group as R⁹¹ may have a substituent. Examples of the substituent include a halogen atom, an oxo group (═O), a hydroxyl group (—OH), an amino group (—NH₂), and —SO₂—NH₂. In addition, part of carbon atoms constituting the hydrocarbon group may be substituted with a substituent containing a hetero atom. Examples of the substituent containing a hetero atom include —O—, —NH—, —N═, —C(═O)—O—, —S—, —S(═O)₂—, and —S(═O)₂—O—.

As R⁹¹, examples of the hydrocarbon group having a substituent include lactone-containing cyclic groups each represented by General Formulae (a2-r-1) to (a2-r-7).

Further, as R⁹¹, examples of the hydrocarbon group having a substituent include —SO₂—-containing cyclic groups each represented by General Formulae (a5-r-1) to (a5-r-4); and substituted aryl groups and monovalent heterocyclic groups represented by the following chemical formulae.

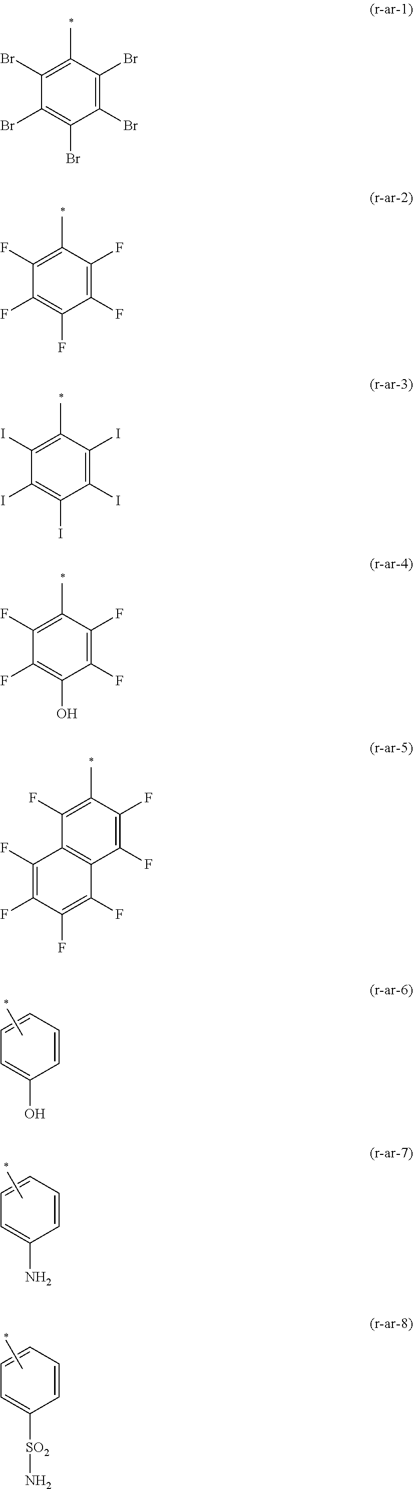

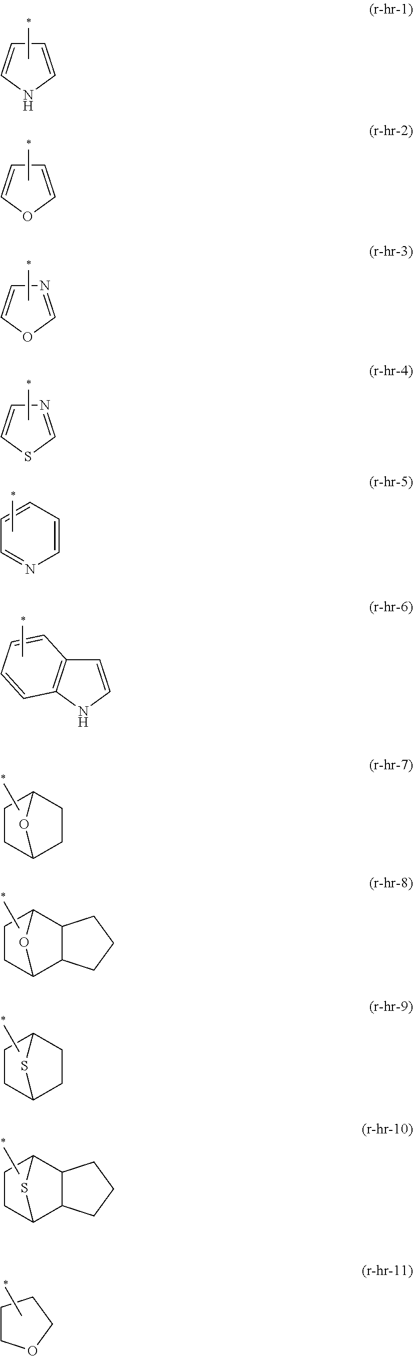

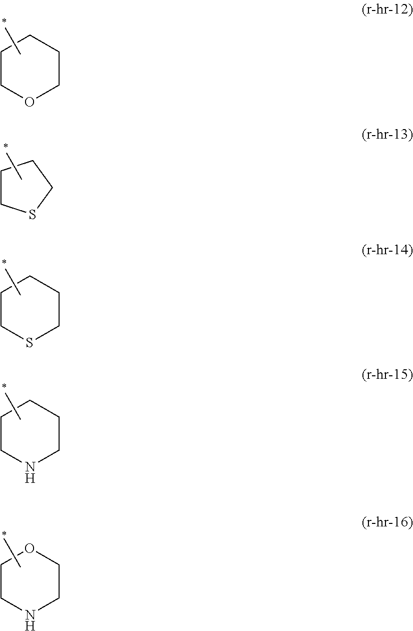

Among the constitutional units (a9), a constitutional unit represented by General Formula (a9-1-1) is preferable.

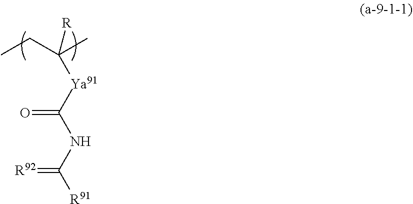

[In the formula, R is the same as described above, Ya⁹¹ represents a single bond or divalent linking group, R⁹¹ represents a hydrocarbon group which may have a substituent, and R⁹² represents an oxygen atom or a sulfur atom.]

The description for Ya⁹¹, R⁹¹, and R in General Formula (a9-1-1) is the same as described above. In addition, R⁹² represents an oxygen atom or a sulfur atom.

Specific examples of the constitutional unit represented by General Formula (a9-1) or General Formula (a9-1-1) are shown below. In the following formula, R^{α} represents a hydrogen atom or a methyl group.

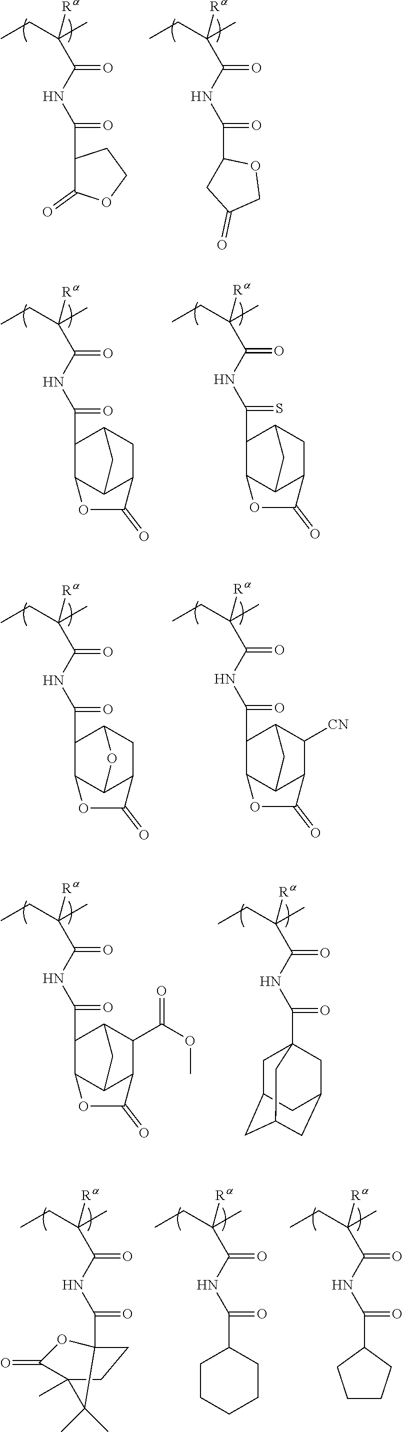

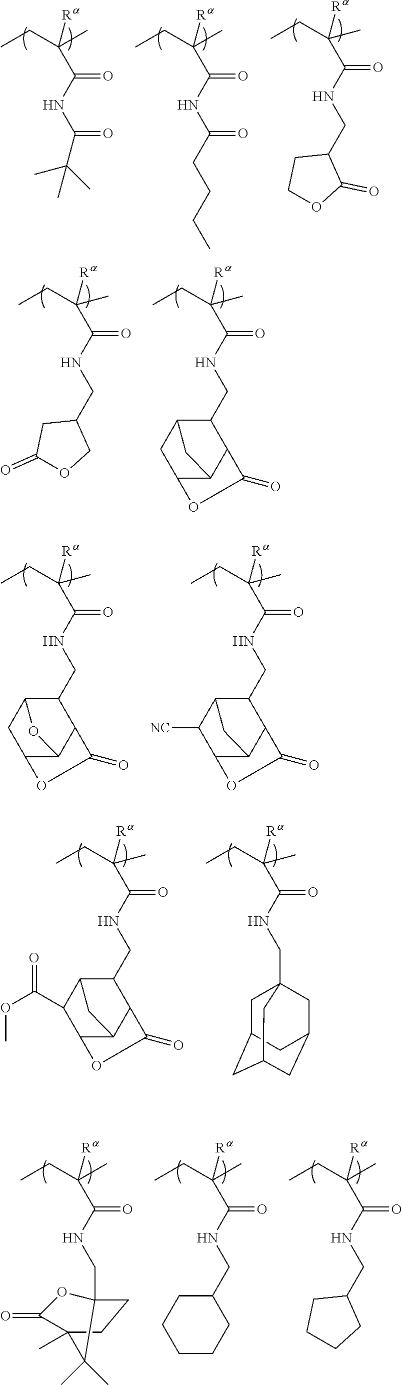

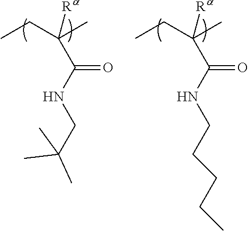

Constitutional Unit (a11)

The constitutional unit (a11) is a constitutional unit represented by General Formula (a11-1).

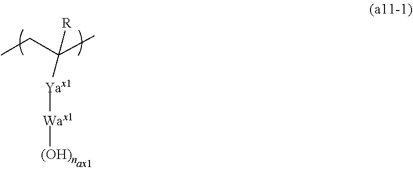

[In the formula, R is the same as R in General Formula (a02-1). Ya^{x1} represents a single bond or a divalent linking group. Wa^{x1} represents an aromatic hydrocarbon group which may have a substituent. nₐₓ₁ represents an integer of 1 or more.]

In General Formula (a11-1), R is the same as R in General Formula (a02-1).

In General Formula (a11-1), Ya^{x1} represents a single bond or a divalent linking group.

In the above chemical formula, the divalent linking group as Ya^{x1} is not particularly limited; however, examples thereof include the same one as the divalent linking group as Ya²¹ in General Formula (a2-1).

In General Formula (a11-1), Wa^{x1} represents an aromatic hydrocarbon group which may have a substituent.

Examples of the aromatic hydrocarbon group as Wa^{x1} include a group in which (nₐₓ₁+1) hydrogen atoms have been removed from an aromatic ring which may have a substituent. Here, the aromatic ring is not particularly limited as long as it is a cyclic conjugated system having (4n+2) π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. Specific examples of the aromatic ring include aromatic hydrocarbon rings such as benzene, naphthalene, anthracene, and phenanthrene; and aromatic heterocyclic rings obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Examples of the aromatic hydrocarbon group as Wa^{x1} also include a group obtained by removing (nₐₓ₁+1) hydrogen atoms from an aromatic compound including an aromatic ring (for example, biphenyl and fluorene) which may have two or more substituents.

Among the above, Wa^{x1} is preferably a group in which (nₐₓ₁+1) hydrogen atoms have been removed from benzene, naphthalene, anthracene, or biphenyl, more preferably a group in which (nₐₓ₁+1) hydrogen atoms have been removed from benzene or naphthalene, and still more preferably a group in which (nₐₓ₁+1) hydrogen atoms have been removed from benzene.

The aromatic hydrocarbon group as Wa^{x1} may have a substituent or may not have a substituent. Examples of substituents include an alkyl group, an alkoxy group, a halogen atom, and a halogenated alkyl group. Examples of the alkyl group, the alkoxy group, the halogen atom, and the halogenated alkyl group, as the substituent, include the same ones as those described as the substituent of the cyclic aliphatic hydrocarbon group as Ya²¹ in General Formula (a2-1). The substituent is preferably a linear or branched alkyl group having 1 to 5 carbon atoms, more preferably a linear or branched alkyl group having 1 to 3 carbon atoms, still more preferably an ethyl group or a methyl group, and particularly preferably a methyl group. The aromatic hydrocarbon group as Wa^{x1} preferably has no substituent.

In General Formula (a11-1), nₐₓ₁ represents an integer of 1 or more, preferably an integer in a range of 1 to 10, more preferably an integer in a range of 1 to 5, still more preferably an integer in a range of 1 to 3, and particularly preferably 1 or 2.

Specific examples of the constitutional unit (a11) represented by General Formula (a11-1) are shown below.

In each of the following formulae, R^{α} represents a hydrogen atom or a methyl group.

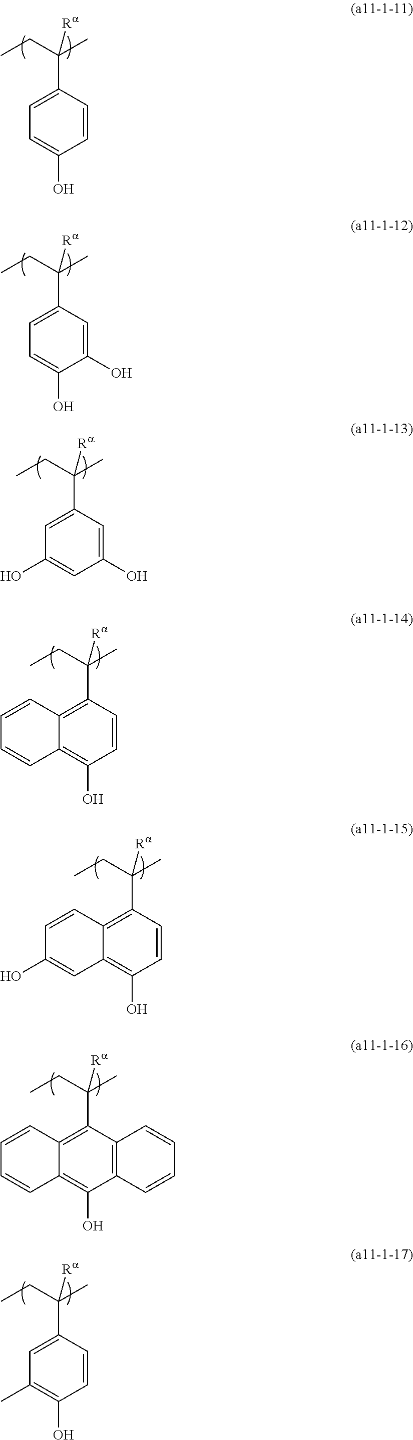

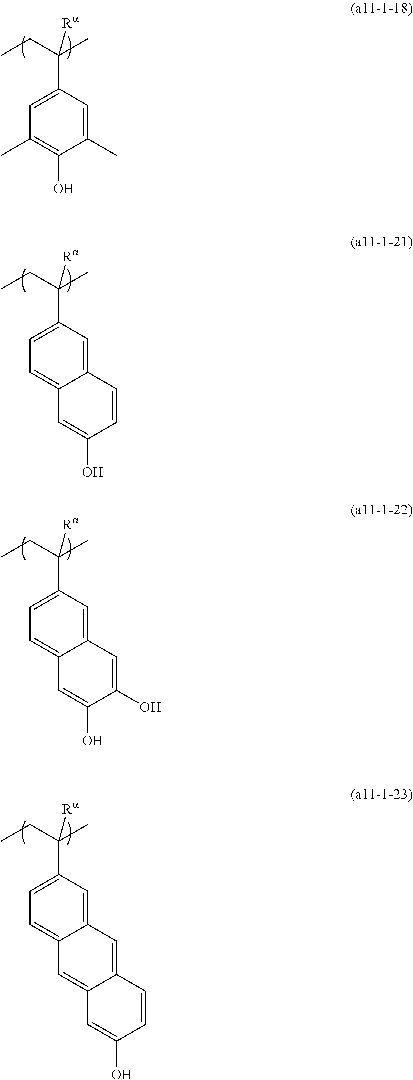

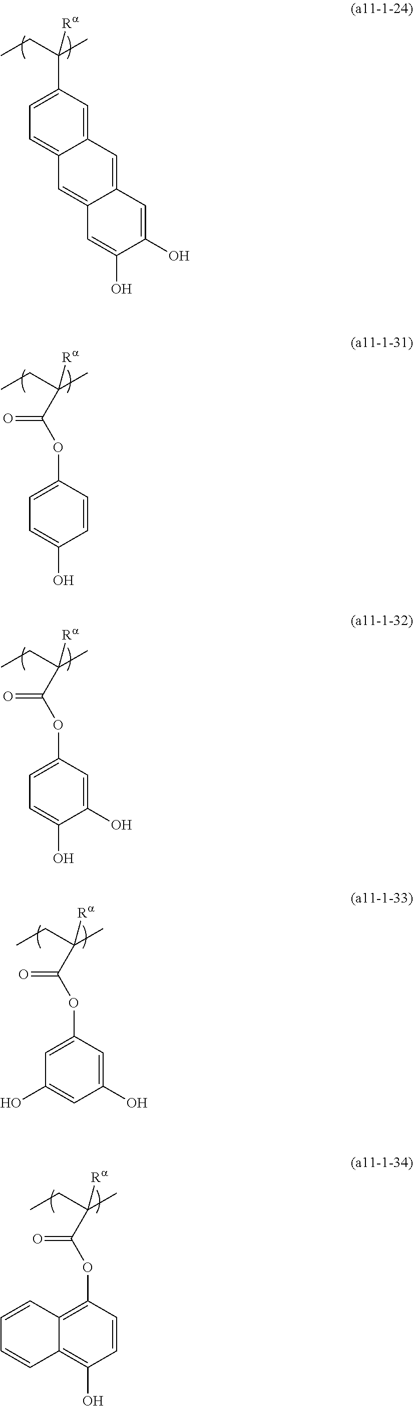

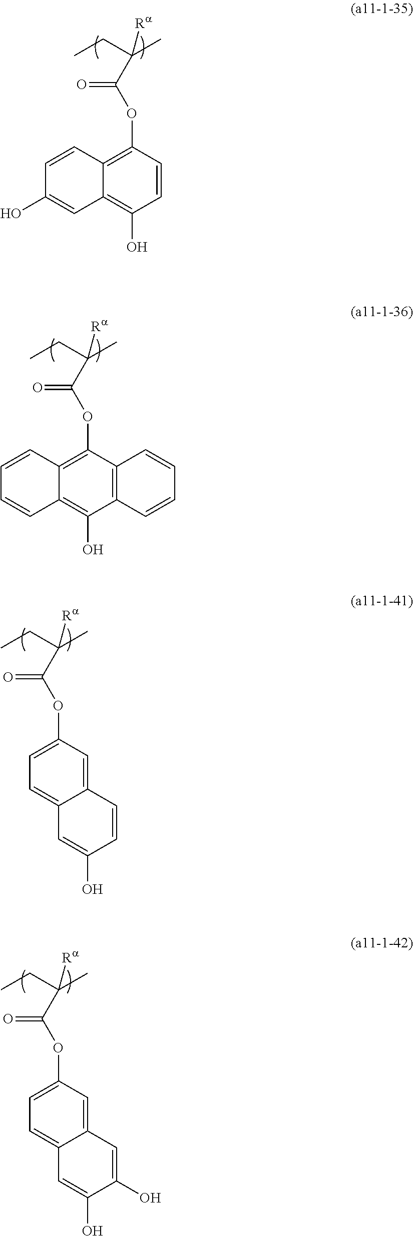

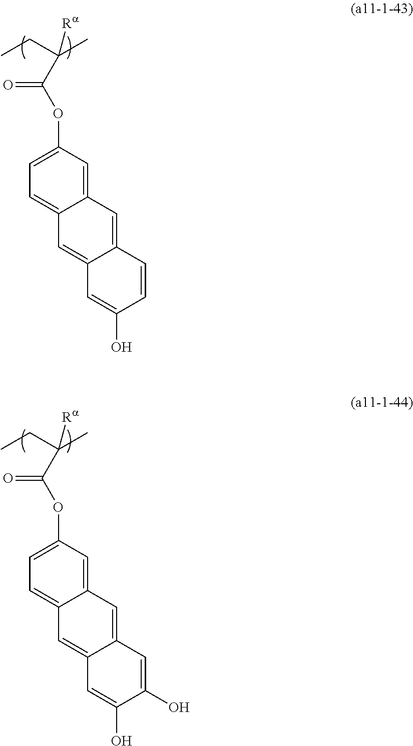

Examples of the component (P) include a polymeric compound having a repeating structure of the constitutional unit (a01); a polymeric compound having a repeating structure of the constitutional unit (a02); a polymeric compound having a repeating structure of the constitutional unit (a01) and the constitutional unit (a02); a polymeric compound having a repeating structure of the constitutional unit (a01) and any constitutional unit (for example, the constitutional unit (a1), (a2), (a3), (a9), or (a11)); a polymeric compound having a repeating structure of the constitutional unit (a02) and any constitutional unit (for example, the constitutional unit (a1), (a2), (a3), (a9), or (a11)); and a polymeric compound having a repeating structure of the constitutional unit (a01), the constitutional unit (a02), and any constitutional unit (for example, the constitutional unit (a1), (a2), (a3), (a9), or (a11)).

The component (P) preferably has a constitutional unit (a01) and more preferably has a constitutional unit (a01) and a constitutional unit other than the constitutional unit (a01). The constitutional unit other than the constitutional unit (a01) may be any one of the constitutional unit (a02), the constitutional unit (a1), the constitutional unit (a2), the constitutional unit (a3), the constitutional unit (a9), and the constitutional unit (a11); however, it is preferably the constitutional unit (a02). Among the constitutional units (a02), the constitutional unit (a5) is preferable, and the constitutional unit (a5) having an alicyclic group is more preferable.

Preferred examples of the component (P) include a polymeric compound having a repeating structure of the constitutional unit (a01); a polymeric compound having a repeating structure of the constitutional unit (a01) and the constitutional unit (a02); polymeric compound having a repeating structure of the constitutional unit (a01) and the constitutional unit (a1); and a polymeric compound having a repeating structure of the constitutional unit (a01), the constitutional unit (a02), and the constitutional unit (a1).

More preferred examples of the component (P) is preferably a polymeric compound having a repeating structure of the constitutional unit (a01) and the constitutional unit (a02); a polymeric compound having a repeating structure of the constitutional unit (a01) and the constitutional unit (a1); or a polymeric compound having a repeating structure of the constitutional unit (a01), the constitutional unit (a02), and the constitutional unit (a1). A polymeric compound having a repeating structure of the constitutional unit (a01) and the constitutional unit (a02) is more preferable.

In a case where the component (P) has a constitutional unit (a01) and another constitutional unit, the molar ratio of the constitutional unit (a01) to the other constitutional unit, that is, “the constitutional unit (a01): the other constitutional unit (the constitutional unit (a02), the constitutional unit (a1), the constitutional unit (a2), the constitutional unit (a3), the constitutional unit (a9), or the constitutional unit (a11))” is preferably in a range of 2:8 to 8:2, and more preferably in a range of 3:7 to 7:3, and still more preferably in a range of 4:6 to 6:4.

One kind of the component (P) may be used alone, or a combination of two or more kinds thereof may be used.

The component (P) can be produced by dissolving, in a polymerization solvent, each of monomers from which constitutional units are derived, adding thereto a radical polymerization initiator such as azobisisobutyronitrile (AIBN) or dimethyl azobisisobutyrate (for example, V-601) to carry out polymerization.

The weight average molecular weight (Mw) (based on the polystyrene equivalent value determined by gel permeation chromatography (GPC)) of the component (P), which is not particularly limited, is preferably in a range of 1,000 to 50,000, more preferably in a range of 2,000 to 30,000, and still more preferably in a range of 3,000 to 20,000.

In a case where the Mw of the component (P) is equal to or smaller than the upper limit value of the above range, the component (P) has solubility, in a resist solvent, which is sufficient for use in a resist, and in a case where it is equal to or larger than the lower limit value of the above range, lithography characteristics are good.

The dispersity (Mw/Mn) of the component (P) is not particularly limited; however, it is preferably in a range of 1.0 to 4.0, more preferably in a range of 1.0 to 3.0, and particularly preferably in a range of 1.0 to 2.0. Mn represents the number average molecular weight.

The content of the component (P) in the resist composition according to the present embodiment is not particularly limited; however, it is preferably in a range of 0.1 to 50 parts by mass, more preferably in a range of 1 to 40 parts by mass, still more preferably in a range of 3 to 20 parts by mass, and particularly preferably in a range of 5 to 15 parts by mass, with respect to 100 parts by mass of the component (M).

The content of the component (P) in the resist composition according to the present embodiment is preferably in a range of 0.001% to 3% by mass, more preferably in a range of 0.001% to 1% by mass, and still more preferably in a range of 0.01% to 0.1% by mass, with respect to the total mass (100% by mass) of the resist composition.

In a case where the content of the component (P) is equal to or larger than the lower limit value of the above range, the contact between the resist film and the air is easily suppressed, and the insolubility of the resist film is easily suppressed. In a case where the content of the component (P) is equal to or smaller than the upper limit value of the above range, balance with other components is easily achieved.

Preferred examples of the component (P) are shown below but are not limited thereto.

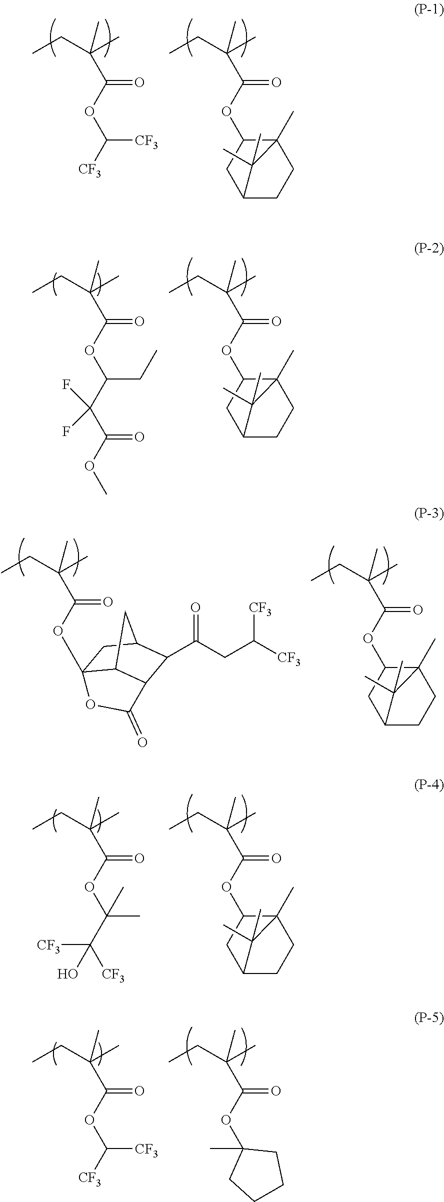

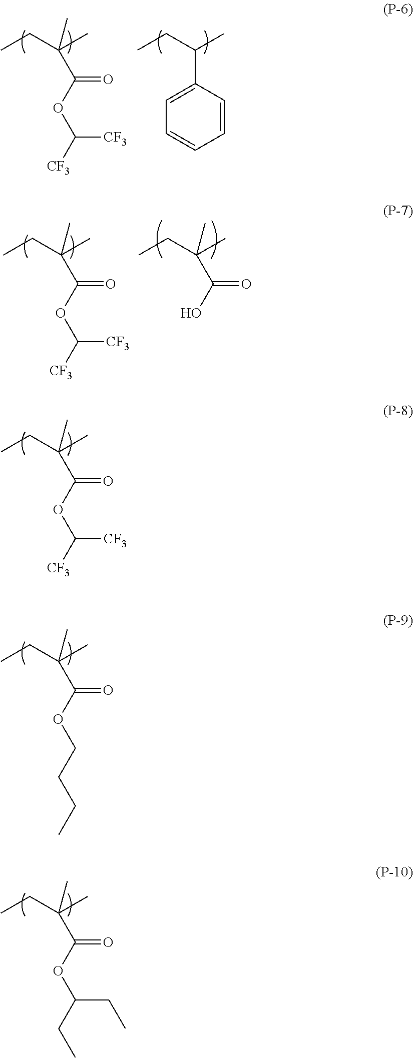

<Another Component: Component (E)>

The resist composition according to the present embodiment may contain another component in addition to the component (M) and the component (P), described above.

<<Crosslinking Accelerator: Component>>

The resist composition according to the present embodiment may contain a crosslinking accelerator. A crosslinking accelerator is a compound that generates acid or base by light or heat. In a case where a crosslinking accelerator is contained, resist pattern forming properties and etching selectivity can be improved. Examples of the crosslinking accelerator include an onium salt compound and an N-sulfonyloxyimide compound. The crosslinking accelerator is preferably a thermal crosslinking accelerator that generates acid or a base by heat, and an onium salt compound is particularly preferable.

Examples of the onium salt compound include a sulfonium salt, a tetrahydrothiophenium salt, an iodonium salt, and an ammonium salt.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, 4-cyclohexylphenyldiphenylsulfonium trifluoromethanesulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium 2-bicyclo[2.2.1]hept-2-yl-1,1,2,2-tetrafluoroethanesulfonate, 4-methanesulfonylphenyldiphenylsulfonium trifluoromethanesulfonate, 4-methanesulfonylphenyldiphenylsulfonium nonafluoro-n-butanesulfonate, 4-methanesulfonylphenyldiphenylsulfonium perfluoro-n-octanesulfonate, 4-methanesulfonylphenyldiphenylsulfonium 2-bicyclo[2.2.1]hept-2-yl-1,1,2,2-tetrafluoroethanesulfonate, and triphenylsulfonium 1,1,2,2-tetrafluoro-6-(1-adamantancarbonyloxy)-hexane-1-sulfonate.

Examples of the tetrahydrothiophenium salt include 1-(4-n-butoxynaphthalene-1-yl)tetrahydrothiophenium trifluoromethanesulfonate, 1-(4-n-butoxynaphthalene-1-yl)tetrahydrothiophenium nonafluoro-n-butanesulfonate, 1-(4-n-butoxynaphthalene-1-yl)tetrahydrothiophenium perfluoro-n-octanesulfonate, 1-(4-n-butoxynaphthalene-1-yl)tetrahydrothiophenium 2-bicyclo[2.2.1]hept-2-yl-1,1,2,2-tetrafluoroethanesulfonate, 1-(6-n-butoxynaphthalene-2-yl)tetrahydrothiophenium trifluoromethanesulfonate, 1-(6-n-butoxynaphthalene-2-yl)tetrahydrothiophenium nonafluoro-n-butanesulfonate, 1-(6-n-butoxynaphthalene-2-yl)tetrahydrothiophenium perfluoro-n-octanesulfonate, 1-(6-n-butoxynaphthalene-2-yl)tetrahydrothiophenium 2-bicyclo[2.2.1]hept-2-yl-1,1,2,2-tetrafluoroethanesulfonate, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, and 1-(3,5-dimethyl-4-hydroxyphenyl)tetrahydrothiophenium 2-bicyclo[2.2.1]hept-2-yl-1,1,2,2-tetrafluoroethanesulfonate.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t) butylphenyl)iodonium perfluoro-n-octanesulfonate, and bis(4-t-butylphenyl)iodonium 2-bicyclo[2.2.1]hept-2-yl-1,1,2,2-tetrafluoroethanesulfonate.

Examples of the ammonium salt include ammonium formate, ammonium maleate, ammonium fumarate, ammonium phthalate, ammonium malonate, ammonium succinate, ammonium tartrate, ammonium malate, ammonium lactate, ammonium citrate, ammonium acetate, ammonium propionate, ammonium butanoate, ammonium pentanoate, ammonium hexanoate, ammonium heptanoate, ammonium octanoate, ammonium nonanoate, ammonium decanoate, ammonium oxalate, ammonium adipate, ammonium sebacate, ammonium butyrate, ammonium oleate, ammonium stearate, ammonium linoleate, ammonium linolenate, ammonium salicylate, ammonium benzenesulfonate, ammonium benzoate, ammonium p-aminobenzoate, ammonium p-toluenesulfonate, ammonium methanesulfonate, ammonium trifluoromethanesulfonate, and ammonium trifluoroethanesulfonate. In addition, examples thereof include an ammonium salt in which the ammonium ion of the above ammonium salt is substituted with a methylammonium ion, a dimethylammonium ion, a trimethylammonium ion, a tetramethylammonium ion, an ethylammonium ion, a diethylammonium ion, a triethylammonium ion, a tetraethylammonium ion, a propylammonium ion, a dipropylammonium ion, a tripropylammonium ion, a tetrapropylammonium ion, a butylammonium ion, a dibutylammonium ion, a tributylammonium ion, a tetrabutylammonium ion, a trimethylethylammonium ion, a dimethyldiethylammonium ion, a dimethylethylpropylammonium ion, a methylethylpropylbutylammonium ion, an ethanolammonium ion, a diethanolammonium ion, or a triethanolammonium ion; a 1,8-diazabicyclo[5.4.0]undec-7-ene salt such as a 1,8-diazabicyclo[5.4.0]undec-7-ene formic acid salt or a 1,8-diazabicyclo[5.4.0]undec-7-ene p-toluenesulfonic acid salt; and a 1,5-diazabicyclo[4.3.0]-5-nonene salt such as a 1,5-diazabicyclo[4.3.0]-5-nonene formic acid salt or a 1,5-diazabicyclo[4.3.0]-5-nonene p-toluenesulfonate.

Examples of the N-sulfonyloxyimide compound include N-(trifluoromethanesulfonyloxy)bicyclo[2.2.1]hept-5-en-2,3-dicarboxyimide, N-(nonafluoro-n-butanesulfonyloxy)bicyclo[2.2.1]hept-5-en-2,3-dicarboxyimide, N-(perfluoro-n-octanesulfonyloxy)bicyclo[2.2.1]hept-5-en-2,3-dicarboxyimide, and N-(2-bicyclo[2.2.1]hept-2-yl-1,1,2,2-tetrafluoroethanesulfonyloxy)bicyclo[2.2.1]hept-5-en-2,3-dicarboxyimide.

Among them, an onium salt compound is preferable, a tetrahydrothiophenium salt, an iodonium salt, or an ammonium salt is more preferable, and 1-(4-n-butoxynaphthalene-1-yl)tetrahydrothiophenium trifluoromethanesulfonate, diphenyliodonium trifluoromethanesulfonate, tetramethylammonium acetate, or a 1,8-diazabicyclo[5.4.0]undec-7-ene p-toluenesulfonic acid salt is still more preferable.

The crosslinking accelerator (P) may be used alone, or a combination of two or more kinds thereof may be used. The content of the crosslinking accelerator is preferably 0 parts by mass or more and 10 parts by mass or less, and more preferably 0 parts by mass or more and 5 parts by mass or less, with respect to 100 parts by mass of the component (M).

<<Surfactant>>

The resist composition according to the present embodiment may contain a surfactant.

The surfactant is a component that exhibits effects of improving coatability, striation, and the like. In addition to nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate, examples of the surfactant include, as the following product names, KP341 (Shin-Etsu Chemical Co., Ltd.); Polyflow No. 75 and Polyflow No. 95 (all manufactured by Kyoeisha Chemical Co., Ltd.); Eftop EF301, Eftop EF303, and Eftop EF352 (all manufactured by Tochem Products Co., Ltd.); MEGAFACE F171, MEGAFACE F173 (all manufactured by DIC Corporation); Florard FC430 and Florard FC431 (all manufactured by Sumitomo 3M Limited); and AsahiGuard AG710, Surflon S-382, Surflon SC-101, Surflon SC-102, Surflon SC-103, Surflon SC-104, Surflon SC-105, and Surflon SC-106 (all manufactured by AGC Inc.).

The surfactant may be used alone, or a combination of two or more kinds thereof may be used. The blending amount of the surfactant can be appropriately determined depending on the intended purpose.

<<Another Additive: Component (G)>>

The resist composition according to the present embodiment may contain an additive other than the crosslinking accelerator and the surfactant. Examples of the other additive include, but are not limited to, the following compounds.

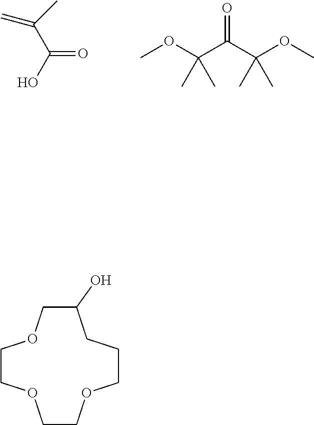

<<Organic Solvent Component (S)>>

The resist composition according to the present embodiment may be produced by dissolving the resist materials in an organic solvent component (hereinafter, referred to as a “component (S)”).

The component (S) may be any organic solvent that can dissolve or disperse the respective components to be used to obtain a homogeneous solution or a dispersion liquid, and optional organic solvent can be appropriately selected and used from those which are known as solvents for a resist composition in the related art.

Examples of the component (S) include lactones such as γ-butyrolactone; ketones such as acetone, methyl ethyl ketone, cyclohexanone, methyl-n-pentyl ketone, and methyl isopentyl ketone, 2-heptanone; monoalcohols such as methanol, ethanol, n-propanol, isopropanol, n-butanol, sec-butanol, t-butanol, n-pentanol, 4-methyl-2-pentanol, and 2-methylbutyl alcohol; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate, polyhydric alcohol derivatives including compounds having an ether bond, such as a monoalkyl ether (such as monomethyl ether, monoethyl ether, monopropyl ether or monobutyl ether) or monophenyl ether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzyl ether, cresylmethyl ether, diphenyl ether, dibenzyl ether, phenetole, butylphenyl ether, ethyl benzene, diethyl benzene, pentyl benzene, isopropyl benzene, toluene, xylene, cymene and mesitylene; and dimethylsulfoxide (DMSO).

In the resist composition according to the present embodiment, the component (S) may be used alone or as a mixed solvent of two or more kinds thereof. Among these, PGMEA, PGME, γ-butyrolactone, EL, cyclohexanone, or 4-methyl-2-pentanol is preferable.

Further, a mixed solvent obtained by mixing PGMEA with a polar solvent is also preferable as the component (S). The blending ratio (mass ratio) of the mixed solvent can be appropriately determined, taking into consideration the compatibility of the PGMEA with the polar solvent, but is preferably in a range of 1:9 to 9:1 and more preferably in a range of 2:8 to 8:2.

More specifically, in a case where EL or cyclohexanone is blended as the polar solvent, the PGMEA:EL or cyclohexanone mass ratio is preferably in a range of 1:9 to 9:1 and more preferably in a range of 2:8 to 8:2. Alternatively, in a case where PGME is blended as the polar solvent, the PGMEA:PGME mass ratio is preferably in a range of 1:9 to 9:1, more preferably in a range of 2:8 to 8:2, and still more preferably in a range of 3:7 to 7:3. Furthermore, a mixed solvent of PGMEA, PGME, and cyclohexanone is also preferable.

Further, the component (S) is also preferably a mixed solvent of at least one selected from PGMEA and EL and γ-butyrolactone. In this case, as the mixing ratio, the mass ratio of the former to the latter is preferably in a range of 70:30 to 95:5.

The amount of the component (S) to be used is not particularly limited and is appropriately set, depending on a thickness of a film to be coated, to a concentration at which the component (S) can be applied onto a substrate or the like. Generally, the component (S) is used such that the solid content concentration of the resist composition is in a range of 0.1% to 20% by mass and preferably in a range of 0.2% to 15% by mass.

As desired, other miscible additives can also be added to the resist composition according to the present embodiment. For example, for improving the performance of the resist film, an additive resin, a dissolution inhibitor, a plasticizer, a stabilizer, a colorant, a halation prevention agent, and a dye can be appropriately contained therein.

After dissolving the resist material in the component (S), the resist composition according to the present embodiment may be subjected to removal of impurities and the like by using a porous polyimide membrane, a porous polyamideimide membrane, or the like. For example, the resist composition may be filtered using a filter made of a porous polyimide membrane, a filter made of a porous polyamideimide membrane, or a filter made of a porous polyimide membrane and a porous polyamideimide membrane. Examples of the porous polyimide membrane and the porous polyamideimide membrane include those described in Japanese Unexamined Patent Application, First Publication No. 2016-155121.

The resist composition according to the present embodiment described above contains the metal compound (the polymer (the component (P)) having at least one constitutional unit selected from the group consisting of the constitutional unit (a01) and the constitutional unit (a02)) in the resist composition containing the metal compound (the component (M)) as the base material component). As a result, the insolubility after forming the resist film is suppressed, lithography characteristics such as a pattern shape are improved, and good etching resistance is maintained.

It is conceived to be because in a case where the resist film is formed, the component (P) segregates on the surface of the resist film, hinders the contact between the resist film and air, and thus suppresses the insolubility of the resist film.

(Method of Forming Resist Pattern)

The method of forming a resist pattern according to the second aspect of the present invention includes a step of forming a resist film on a support using the above-described resist composition, a step of exposing the resist film, and a step of developing the exposed resist film to form a resist pattern.

Examples of one embodiment of such a method of forming a resist pattern include a method of forming a resist pattern carried out as described below.

First, the resist composition of the above-described embodiment is applied onto a support with a spinner or the like, and a baking (post-apply baking (PAB)) treatment is carried out, for example, at a temperature condition of 80° C. to 150° C. for 40 to 120 seconds, preferably for 60 to 90 seconds to form a resist film.

Following the selective exposure carried out on the resist film by, for example, exposure through a mask (mask pattern) having a predetermined pattern formed on the mask by using an exposure apparatus such as an electron beam lithography apparatus or an EUV exposure apparatus, or direct irradiation of the resist film for drawing with an electron beam without using a mask pattern, baking treatment (post-exposure baking (PEB)) is carried out, for example, under a temperature condition of 80° C. to 150° C. for 40 to 120 seconds and preferably 60 to 90 seconds.

Next, the resist film is subjected to a developing treatment. The developing treatment is carried out using an alkali developing solution in a case of an alkali developing process, and a developing solution containing an organic solvent (organic developing solution) in a case of a solvent developing process. The developing treatment is usually carried out by a solvent developing process.

After the developing treatment, it is preferable to carry out a rinse treatment. As the rinse treatment, water rinsing using pure water is preferable in a case of an alkali developing process, and rinsing using a rinse liquid containing an organic solvent is preferable in a case of a solvent developing process.

In a case of a solvent developing process, after the developing treatment or the rinse treatment, the developing solution or the rinse liquid remaining on the pattern can be removed by a treatment using a supercritical fluid.

After the developing treatment or the rinse treatment, drying is carried out. As desired, baking treatment (post-baking) can be carried out following the developing treatment.

In this manner, a resist pattern can be formed.

The support is not specifically limited, and a known support in the related art can be used. For example, substrates for electronic components, and such substrates having predetermined wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the support, any support having the above-described substrate on which an inorganic and/organic film is provided may be used. As the inorganic film, an inorganic antireflection film (inorganic BARC) can be used. Examples of the organic film include an organic antireflection film (organic BARC) and an organic film such as a lower-layer organic film used in a multilayer resist method.

Here, the multilayer resist method is a method in which at least one layer of an organic film (lower-layer organic film) and at least one layer of a resist film (upper-layer resist film) are provided on a substrate, and a resist pattern formed on the upper-layer resist film is used as a mask to carry out patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film (triple-layer resist method).

The wavelength to be used for exposure is not particularly limited and the exposure can be carried out using radiation such as an ArF excimer laser, a KrF excimer laser, an F₂ excimer laser, an extreme ultraviolet ray (EUV), a vacuum ultraviolet ray (VUV), an electron beam (EB), an X ray, or a soft X ray. The resist composition is highly useful for a KrF excimer laser, an ArF excimer laser, EB, or EUV, more useful for an ArF excimer laser, EB, or EUV, and particularly useful for EB or EUV. That is, the method of forming a resist pattern according to the present embodiment is a method particularly useful in a case where the step of exposing the resist film includes an operation of exposing the resist film to an extreme ultraviolet ray (EUV) or an electron beam (EB).

The exposure method of the resist film can be a general exposure (dry exposure) carried out in air or an inert gas such as nitrogen, or liquid immersion exposure (liquid immersion lithography).

In liquid immersion lithography is an exposure method in which the region between the resist film and the lens at the lowermost position of the exposure apparatus is pre-filled with a solvent (liquid immersion medium) that has a larger refractive index than the refractive index of air, and the exposure (immersion exposure) is carried out in this state.

The liquid immersion medium is preferably a solvent that exhibits a refractive index larger than the refractive index of air but smaller than the refractive index of the resist film to be exposed. The refractive index of such a solvent is not particularly limited as long as it satisfies the above-described requirements.

Examples of the solvent which exhibits a refractive index that is larger than the refractive index of air but smaller than the refractive index of the resist film include water, fluorine-based inert liquids, silicone-based solvents, and hydrocarbon-based solvents.

Specific examples of the fluorine-based inert liquids include liquids containing a fluorine-based compound such as C₃HCl₂F₅, C₄F₉OCH₃, C₄F₉OC₂H₅, or C₅H₃F₇ as the main component, and the boiling point is preferably in a range of 700 to 180° C. and more preferably in a range of 80° to 160° C. A fluorine-based inert liquid having a boiling point in the above-described range is advantageous in that removing the medium used in the liquid immersion after the exposure can be carried out by a simple method.

A fluorine-based inert liquid is particularly preferably a perfluoroalkyl compound obtained by substituting all hydrogen atoms of the alkyl group with a fluorine atom. Specific examples of the perfluoroalkyl compound include perfluoroalkyl ether compounds and perfluoroalkyl amine compounds.

Specifically, an example of a suitable perfluoroalkyl ether compound is perfluoro(2-butyl-tetrahydrofuran) (boiling point of 102° C.), and an example of a suitable perfluoroalkyl amine compound is perfluorotributyl amine (boiling point of 174° C.).

As the liquid immersion medium, water is preferable in terms of cost, safety, environment, and versatility.

Examples of the alkali developing solution used for a developing treatment in an alkali developing process include an aqueous solution of 0.1 to 10% by mass of tetramethylammonium hydroxide (TMAH).

As the organic solvent contained in the organic developing solution, which is used for a developing treatment in a solvent developing process, any one of the conventionally known organic solvents capable of dissolving the component (A) (component (A) prior to exposure) can be appropriately selected from the conventionally known organic solvents. Specific examples of the organic solvent include polar solvents such as a ketone-based solvent, an ester-based solvent, an alcohol-based solvent, a nitrile-based solvent, an amide-based solvent, and an ether-based solvent, and hydrocarbon-based solvents.

A ketone-based solvent is an organic solvent containing C—C(═O)—C in the structure thereof. An ester-based solvent is an organic solvent containing C—C(═O)—O—C in the structure thereof. An alcohol-based solvent is an organic solvent containing an alcoholic hydroxyl group in the structure thereof. An “alcoholic hydroxyl group” indicates a hydroxyl group bonded to a carbon atom of an aliphatic hydrocarbon group. A nitrile-based solvent is an organic solvent containing a nitrile group in the structure thereof. An amide-based solvent is an organic solvent containing an amide group in the structure thereof. An ether-based solvent is an organic solvent containing C—O—C in the structure thereof.

Some organic solvents have a plurality of the functional groups which characterize the above-described solvents in the structure thereof. In such a case, the organic solvent can be classified as any type of solvent having a characteristic functional group. For example, diethylene glycol monomethyl ether can be classified as an alcohol-based solvent or an ether-based solvent.

A hydrocarbon-based solvent consists of a hydrocarbon which may be halogenated and does not have any substituent other than a halogen atom. Examples of the halogen atom include a fluorine atom, a chlorine atom, a bromine atom, and an iodine atom, and a fluorine atom is preferable.

Among the above, the organic solvent contained in the organic developing solution is preferably a polar solvent and more preferably a ketone-based solvent, an ester-based solvent, or a nitrile-based solvent.

Examples of ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, propylenecarbonate, γ-butyrolactone and methylamyl ketone (2-heptanone). Among these examples, the ketone-based solvent is preferably methylamyl ketone (2-heptanone).

Examples of the ester-based solvent include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, the ester-based solvent is preferably butyl acetate.

Examples of the nitrile-based solvent include acetonitrile, propionitrile, valeronitrile, and butyronitrile.

As desired, the organic developing solution may have a conventionally known additive blended. Examples of the additive include surfactants. The surfactant is not particularly limited, and for example, an ionic or non-ionic fluorine-based and/or a silicone-based surfactant can be used. The surfactant is preferably a non-ionic surfactant and more preferably a non-ionic fluorine surfactant or a non-ionic silicone-based surfactant.

In a case where a surfactant is blended, the amount of the surfactant to be blended is typically in a range of 0.001% to 5% by mass, preferably in a range of 0.005% to 2% by mass, and more preferably in a range of 0.01% to 0.5% by mass with respect to the total amount of the organic developing solution.

The developing treatment can be carried out by a conventionally known developing method. Examples thereof include a method in which the support is immersed in the developing solution for a predetermined time (a dip method), a method in which the developing solution is cast upon the surface of the support by surface tension and maintained for a predetermined time (a puddle method), a method in which the developing solution is sprayed onto the surface of the support (spray method), and a method in which a developing solution is continuously ejected from a developing solution ejecting nozzle and applied to a support which is scanned at a constant rate while being rotated at a constant rate (dynamic dispense method).

As the organic solvent contained in the rinse liquid used in the rinse treatment after the developing treatment in a case of a solvent developing process, an organic solvent hardly dissolving the resist pattern can be appropriately selected and used, among the organic solvents mentioned as organic solvents that are used for the organic developing solution. In general, at least one kind of solvent selected from the group consisting of a hydrocarbon-based solvent, a ketone-based solvent, an ester-based solvent, an alcohol-based solvent, an amide-based solvent, and an ether-based solvent is used. Among these, at least one kind of solvent selected from the group consisting of a hydrocarbon-based solvent, a ketone-based solvent, an ester-based solvent, an alcohol-based solvent, and an amide-based solvent is preferable, at least one kind of solvent selected from the group consisting of an alcohol-based solvent and an ester-based solvent is more preferable, and an alcohol-based solvent is particularly preferable.

The alcohol-based solvent used for the rinse liquid is preferably a monohydric alcohol of 6 to 8 carbon atoms, and the monohydric alcohol may be linear, branched, or cyclic. Specific examples thereof include 1-hexanol, 1-heptanol, 1-octanol, 2-hexanol, 2-heptanol, 2-octanol, 3-hexanol, 3-heptanol, 3-octanol, 4-octanol, and benzyl alcohol. Among these, 1-hexanol, 2-heptanol, and 2-hexanol are preferable, and 1-hexanol and 2-hexanol are more preferable.

Any one of the above organic solvents may be used alone, or a combination of two or more kinds thereof may be used. Further, an organic solvent other than the above-described examples or water may be mixed thereto. However, in consideration of the development characteristics, the amount of water to be blended in the rinse liquid is preferably 30% by mass or less, more preferably 10% by mass or less, still more preferably 5% by mass or less, and particularly preferably 3% by mass or less with respect to the total amount of the rinse liquid.

A conventionally known additive can be blended with the rinse liquid as necessary. Examples of the additive include surfactants. Examples of the surfactant include the same ones as those described above, the surfactant is preferably a non-ionic surfactant and more preferably a non-ionic fluorine surfactant or a non-ionic silicone-based surfactant.

In a case where a surfactant is blended, the amount of the surfactant to be blended is typically in a range of 0.001% to 5% by mass, preferably in a range of 0.005% to 2% by mass, and more preferably in a range of 0.01% to 0.5% by mass with respect to the total amount of the rinse liquid.

The rinse treatment using a rinse liquid (washing treatment) can be carried out by a conventionally known rinse method. Examples of the rinse treatment method include a method in which the rinse liquid is continuously applied to the support while rotating it at a constant rate (rotational coating method), a method in which the support is immersed in the rinse liquid for a predetermined time (dip method), and a method in which the rinse liquid is sprayed onto the surface of the support (spray method).

According to the method of forming a resist pattern according to the present embodiment described above, since the resist composition of the first aspect described above is used, the insolubility of the resist film is suppressed. As a result, it is possible to form a resist pattern that has excellent lithography characteristics such as a pattern shape and maintains good etching resistance.

### EXAMPLES

Hereinafter, the present invention will be described in more detail based on Examples, but the present invention is not limited to these Examples.

<Manufacturing of Metal Compound>

### Production Example 1: Metal Compound (M-1)

38.3 g of zirconium (IV) butoxide and 50 g of propylene glycol monomethyl ether (PGME) were mixed and stirred at 25° C. for 10 minutes, 43.0 g of methacrylic acid was mixed thereto, and then heating and stirring was carried out at 80° C. for 4 hours. After completion of the reaction, the mixture was cooled to room temperature and low boiling point substances were removed by an evaporator to obtain a powder of a metal compound (M-1). This sample was heated at 600° C., and the metal atom content of the metal compound (M-1) was calculated based on the residual mass of ZrO₂. As a result of the above, it was found that the metal atom content is 32% by mass.

### Production Example 2: Metal Compound (M-2)

38.3 g of zirconium (IV) butoxide and 50 g of propylene glycol monomethyl ether (PGME) were mixed and stirred at 25° C. for 10 minutes, 34.4 g of methacrylic acid and 5.99 g of acetic acid were mixed thereto, and then heating and stirring was carried out at 60° C. for 4 hours. After completion of the reaction, the mixture was cooled to room temperature and low boiling point substances were removed by an evaporator to obtain a powder of a metal compound (M-2). This sample was heated at 600° C., and the metal content of the metal compound (M-2) was calculated based on the residual mass of ZrO₂. As a result of the above, it was found that the metal atom content is 33% by mass.

### Production Example 3: Metal Compound (M-3)

47.0 g of hafnium (IV) ethoxide and 50 g of tetrahydrofuran (THF) were mixed and stirred at 25° C. for 10 minutes, 43.0 g of methacrylic acid was mixed thereto, and then heating and stirring was carried out at 80° C. for 5 hours. After completion of the reaction, the mixture was cooled to room temperature and low boiling point substances were removed by an evaporator to obtain a powder of a metal compound (M-3). This sample was heated at 600° C., and the metal content of the metal compound (M-3) was calculated based on the residual mass of HfO₂. As a result of the above, it was found that the metal atom content is 51% by mass.

### Production Example 4: Metal Compound (M-4)

Hafnium (IV) trifluoromethanesulfonate (product code: T1708) was purchased from Tokyo Chemical Industry Co., Ltd. and used as a metal compound (M-4). This sample was heated at 600° C., and the metal content of the metal compound (M-4) was calculated based on the residual mass of HfO₂. As a result of the above, it was found that the metal atom content is 23% by mass.

### Production Example 5: Metal Compound (M-5)

0.209 g of a monobutyltin oxide hydrate (BuSnOOH) powder was added to 10 mL of 4-methyl-2-pentanol. The solution was placed in a locking vial and stirred for 24 hours. The obtained mixture was centrifuged at 4,000 rpm for 15 minutes, filtered through a 0.45 μm PTFE syringe filter, and low boiling point substances were removed by an evaporator to obtain a powder of a metal compound (M-5). This sample was heated at 600° C., and the metal content of the metal compound (M-5) was calculated based on the residual mass of SnO₂. As a result of the above, it was found that the metal atom content is 57% by mass.

### Production Example 6: Metal Compound (M-6)

Each of the following monomers was mixed at a predetermined molar ratio and stirred in the presence of the polymerization initiator V-601 and tetrahydrofuran in a nitrogen gas atmosphere at room temperature. Then, the temperature was raised to 70° C., the mixture was heated and stirred for 5 hours, and then allowed to cool to room temperature. The reaction solution was added dropwise to heptane to precipitate the reaction product and filtration was carried out. The filtered solid was washed with heptane. Then, the washed solid was subjected to drying under reduced pressure to obtain a metal compound (M-6). The weight average molecular weight (Mw) in terms of polystyrene equivalent value, acquired by the GPC measurement, is 9,800, and the polydispersity (Mw/Mn) is 1.78. The copolymer composition ratio (the proportion (molar ratio) among constitutional units in the structural formula) determined by ¹³C-NMR was l/m/n/o=25/25/40/10. This sample was heated at 600° C., and the metal content of the metal compound (M-6) was calculated based on the residual mass of FeO₂. As a result of the above, it was found that the metal atom content is 3.0% by mass.

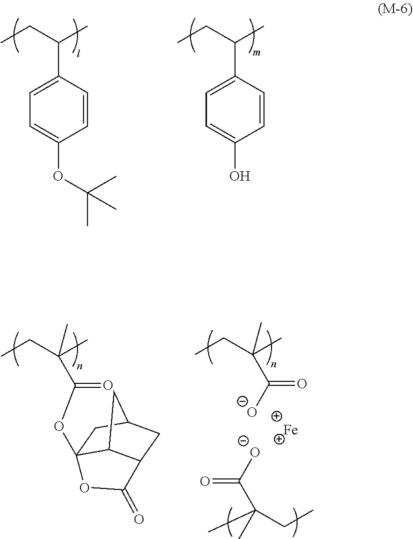

Table 1 summarizes the (M1) component (the metal ion or the metal oxide) and the (M2) component (the bonder) in the metal compounds (M-1) to (M-6).

TABLE 1

| Component | Component | |
|---|---|---|
| (M) | (M1) | Component (M2) |
| M-1 | Zr₆O₄(OH)₄ | 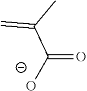 |
| M-2 | Zr₆O₄(OH)₄ | 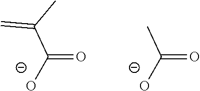 |
| M-3 | Hf₆O₄(OH)₄ | 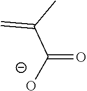 |
| M-4 | Hf⁴⁺ | 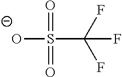 |
| M-5 | Sn₁₂O₁₄(OH)₆ | 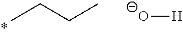 |
| M-6 | Fe²⁺ | 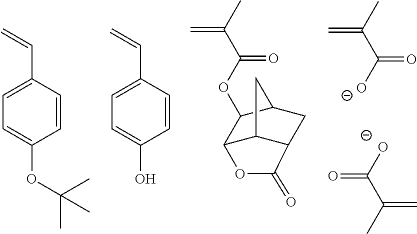 |

<Preparation of Resist Composition>

### Examples 1 to 17 and Comparative Examples 1 to 6

Each of the components shown in Tables 2 and 3 was mixed and dissolved to prepare a resist composition of each Example.

TABLE 2

| | Component | Component | Component | Component |
|---|---|---|---|---|
| | (M) | (P) | (G) | (S) |
| Example 1 | (M)-1 | (P)-1 | — | (S)-1 |
| | [100] | [10] | | [3000] |
| Example 2 | (M)-1 | (P)-2 | — | (S)-1 |
| | [100] | [10] | | [3000] |
| Example 3 | (M)-1 | (P)-3 | — | (S)-1 |
| | [100] | [10] | | [3000] |
| Example 4 | (M)-1 | (P)-4 | — | (S)-1 |
| | [100] | [10] | | [3000] |
| Example 5 | (M)-2 | (P)-1 | — | (S)-1 |
| | [100] | [10] | | [3000] |
| Example 6 | (M)-3 | (P)-1 | — | (S)-1 |
| | [100] | [10] | | [3000] |
| Example 7 | (M)-4 | (P)-1 | — | (S)-2 |
| | [100] | [10] | | [3000] |
| Example 8 | (M)-5 | (P)-1 | — | (S)-3 |
| | [100] | [10] | | [3000] |
| Example 9 | (M)-1 | (P)-5 | — | (S)-1 |
| | [100] | [10] | | [3000] |
| Example 10 | (M)-1 | (P)-6 | — | (S)-1 |
| | [100] | [10] | | [3000] |
| Example 11 | (M)-1 | (P)-7 | — | (S)-1 |
| | [100] | [10] | | [3000] |
| Example 12 | (M)-1 | (P)-8 | — | (S)-1 |
| | [100] | [10] | | [3000] |
| Example 13 | (M)-1 | (P)-9 | — | (S)-1 |
| | [100] | [10] | | [3000] |
| Example 14 | (M)-1 | (P)-10 | — | (S)-1 |
| | [100] | [10] | | [3000] |
| Example 15 | (M)-1 | (P)-1 | (G)-1 | (S)-1 |
| | [100] | [10] | [5] | [3000] |
| Example 16 | (M)-1 | (P)-1 | (G)-2 | (S)-1 |
| | [100] | [10] | [5] | [3000] |
| Example 17 | (M)-1 | (P)-1 | (G)-3 | (S)-1 |
| | [100] | [10] | [5] | [3000] |

TABLE 3

| | Component | Component | Component | Component |
|---|---|---|---|---|
| | (M) | (P) | (E) | (S) |
| Comparative | (M)-1 | — | — | (S)-1 |
| Example 1 | [100] | | | [3000] |
| Comparative | (M)-2 | — | — | (S)-1 |
| Example 2 | [100] | | | [3000] |
| Comparative | (M)-3 | — | — | (S)-1 |
| Example 3 | [100] | | | [3000] |
| Comparative | (M)-4 | — | — | (S)-2 |
| Example 4 | [100] | | | [3000] |
| Comparative | (M)-5 | — | — | (S)-3 |
| Example 5 | [100] | | | [3000] |
| Comparative | (M)-6 | — | — | (S)-3 |
| Example 6 | [100] | | | [3000] |

In Tables 2 and 3, each abbreviation has the following meaning. The numerical values in the brackets are blending amounts (parts by mass).

(M)-1 to (M)-6: each of the above metal compounds (M-1) to (M-6).

(P)-1 to (P)-10: the polymers each represented by Chemical Formulae (P-1) to (P-10). Each polymer was obtained by radical polymerization of a monomer that induce a constitutional unit that constitutes each polymer, using a predetermined molar ratio. The weight average molecular weight (Mw) determined by GPC measurement in terms of polystyrene equivalent value, the polydispersity (Mw/Mn), and the copolymer composition ratio (the proportion of each constitutional unit in the structural formula (molar ratio)) determined by ¹³C-NMR) were each as follows.

(P)-1: Mw=9,800, Mw/Mn=1.68, 1/m=60/40.

(P)-2: Mw=12,000, Mw/Mn=1.56, 1/m=70/30.

(P)-3: Mw=13,000, Mw/Mn=1.69, 1/m=80/20.

(P)-4: Mw=11,000, Mw/Mn=1.54, 1/m=80/20.

(P)-5: Mw=8,600, Mw/Mn=1.62, 1/m=60/40.

(P)-6: Mw=10,000, Mw/Mn=1.75, 1/m=60/40.

(P)-7: Mw=13,000, Mw/Mn=1.58, 1/m=60/40.

(P)-8: Mw=9,700, Mw/Mn=1.60.

(P)-9: Mw=2,000, Mw/Mn=1.70.

(P)-10: Mw=19,000, Mw/Mn=1.50.

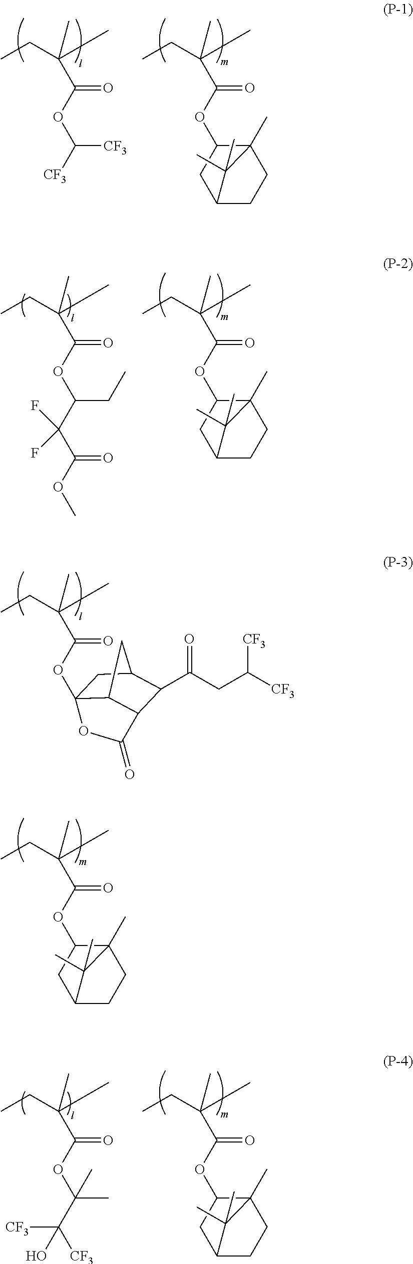

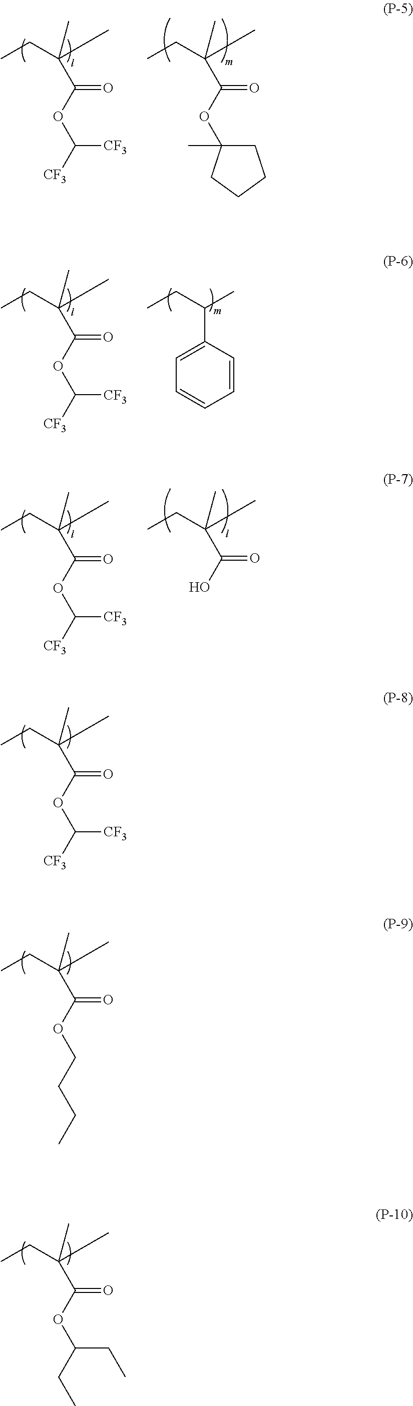

(G)-1 to (G)-3: compounds each represented by Chemical Formulae (G-1) to (G-3).

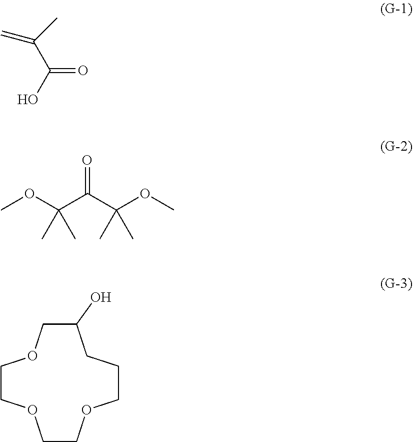

(S)-1: propylene glycol monomethyl ether acetate.

(S)-2: propylene glycol monomethyl ether.

(S)-3: 4-methyl-2-pentanol.

<Content of Metal Atom>

For the resist composition of each Example, the content of the metal atom with respect to the total mass of the resist composition was calculated. The results are shown in Tables 4 to 5 as “Metal atom content”.

<Formation of Resist Pattern>

The resist composition of each Example was applied onto an 8-inch silicon substrate which had been subjected to a hexamethyldisilazane (HMDS) treatment using a spinner, the coated wafer was subjected to a post-apply baking (PAB) treatment on a hot plate at a temperature of 80° C. for 60 seconds so that the coated wafer was dried to form a resist film having a film thickness of 40 nm.

Next, drawing (exposure) was carried out on the resist film by using an electron beam lithography apparatus JEOL-JBX-9300FS (manufactured by JEOL Ltd.), with the target size being set to a 1:1 line and space pattern (hereinafter, referred to as an “LS pattern”) of a line width of 50 nm, at an acceleration voltage of 100 kV. Next, solvent developing was carried out with butyl acetate at 23° C. for 30 seconds, and shake-off drying was carried out. As a result of the above, a 1:1 LS pattern having a line width of 50 nm was formed.

[Evaluation of LS Pattern Shape]

The shape of the LS pattern formed in <Formation of resist pattern> described above was observed by a length measuring scanning electron microscope (SEM, acceleration voltage: 300 V, product name: SU-8000, manufactured by Hitachi High-Tech Corporation), and the evaluation was carried out according to the following evaluation criteria. The results are shown in Tables 4 and 5 as “Pattern shape”.

Evaluation Criteria

A: The cross-sectional shape of the pattern is rectangular and has high verticality.

B: The cross-sectional shape of the pattern is a T-top shape.

[Evaluation of Linewise Roughness (LWR) Change]

3σ of the LS pattern formed in <Formation of resist pattern> described above, which is a scale indicating LWR, was determined. This was denoted by “LWR (nm)”.

“3σ” indicates a triple value (unit: nm) of the standard deviation (σ) determined from measurement results obtained by measuring 400 line positions in the longitudinal direction of the line with a scanning electron microscope (acceleration voltage: 800V, product name: S-9380, manufactured by Hitachi High-Tech Corporation)

The smaller the value of 3σ is, the smaller the roughness in the line side wall is, which means an LS pattern having a more uniform width was obtained.

The LWR change rate (%) was calculated by the following expression, where the LWR immediately after the formation of the resist film was denoted by L0 and the LWR 24 hours after the formation of the resist film was denoted by L1.

LWR change rate (%)=|L1-L0|×100/L0

It can be evaluated that the smaller the LWR change rate is, the more the chronological change of the resist film is suppressed. For this reason, the LWR change rate was evaluated based on the following evaluation criteria as an index of LWR change suppressibility. The results are shown in Tables 4 to 5 as “LWR change rate”.

Evaluation Criteria

A: LWR change rate is less than 10%.

B: LWR change rate is 10% or more and less than 20%.

C: LWR change rate is 20% or more.

D: It is resolved.

[Evaluation of Change of Optimum Exposure Amount (Eop)]

According to <Resist pattern formation> described above, an exposure amount with which an LS pattern having a target size (line width: 50 nm) is formed was determined as the optimum exposure amount Eop (μC/cm²).

The Eop change rate (%) was calculated by the following expression, where the Eop immediately after the formation of the resist film was denoted by D0 and the Eop 24 hours after the formation of the resist film was denoted by D1.

Eop change rate (%)=|D1−D0|×100/D0

It can be evaluated that the smaller the Eop change rate is, the more the chronological change of the resist film is suppressed. For this reason, the Eop change rate was evaluated based on the following evaluation criteria as an index of Eop sensitivity change suppressibility. The results are shown in Tables 4 to 5 as “Eop change rate”.

Evaluation Criteria

A: Eop change rate is less than 10%.

B: Eop change rate is 10% or more and less than 20%.

C: Eop change rate is 20% or more.

D: It is resolved.

[Evaluation of Etching Resistance]

The resist composition of each Example was applied onto an 8-inch silicon substrate which had been subjected to a hexamethyldisilazane (HMDS) treatment using a spinner, the coated wafer was subjected to a post-apply baking (PAB) treatment on a hot plate at a temperature of 80° C. for 60 seconds so that the coated wafer was dried to form a resist film having a film thickness of 400 nm.

This resist film was dry-etched (02 plasma etching) with plasma obtained from oxygen gas under the following conditions.

<O2 Plasma Etching Conditions>

Equipment: high vacuum RIE equipment (manufactured by Tokyo Ohka Kogyo Co., Ltd.; product name “TCA-2400”).

Gas: a mixed gas of 60% by volume of oxygen gas and 40% by volume of nitrogen gas.

Gas flow rate: 30 sccm (here, “sccm” indicates the measured value at 1 atm (atmospheric pressure: 1,013 hPa) and 23° C.).

Temperature in chamber: 60° C.

Pressure in chamber: 300 mmTorr.

Output power (RF) applied for plasma generation: 200 W.

Treatment time: 30 seconds.

The etching rate (the thickness of the etched film per unit time) was determined from the difference in the film thickness of the resist film before and after etching. Using this etching rate as an index, the etching resistance was evaluated based on the following evaluation criteria. The results are shown in Tables 4 to 5 as “Etching resistance”.

Evaluation Criteria

A: Etching rate is less than 5 mm Esec.

B: Etching rate is 5 nm/sec or more and 10 nm/sec or less.

C: Etching rate is 10 nm/sec or more.

TABLE 4

| | Content of metal | | | | |
|---|---|---|---|---|---|
| | atom | | | | Etching |
| | (% by mass) | Pattern shape | Eop change rate | LWR change rate | resistance |
| Example 1 | 1.0% | A | A | A | A |
| Example 2 | 1.0% | A | A | C | A |
| Example 3 | 1.0% | A | C | C | A |
| Example 4 | 1.0% | A | B | C | A |
| Example 5 | 1.2% | A | A | A | A |
| Example 6 | 1.6% | A | A | A | A |
| Example 7 | 0.7% | A | C | B | B |
| Example 8 | 1.9% | A | B | B | A |
| Example 9 | 1.0% | A | A | B | A |
| Example 10 | 1.0% | A | B | B | A |
| Example 11 | 1.0% | A | B | C | A |
| Example 12 | 1.0% | A | B | A | A |
| Example 13 | 1.0% | A | C | C | A |
| Example 14 | 1.0% | A | B | C | A |
| Example 15 | 1.0% | A | A | A | A |
| Example 16 | 1.0% | A | A | A | A |
| Example 17 | 1.0% | A | A | A | A |

TABLE 5

| | Content of metal | | | | |
|---|---|---|---|---|---|
| | atom | | | | Etching |
| | (% by mass) | Pattern shape | Eop change rate | LWR change rate | resistance |
| Comparative | 1.0% | B | D | D | A |
| Example 1 | | | | | |
| Comparative | 1.2% | B | D | D | A |
| Example 2 | | | | | |
| Comparative | 1.7% | B | D | D | A |
| Example 3 | | | | | |
| Comparative | 0.7% | B | D | D | B |
| Example 4 | | | | | |
| Comparative | 1.9% | B | D | D | A |
| Example 5 | | | | | |
| Comparative | 0.1% | B | A | A | C |
| Example 6 | | | | | |

From the results shown in Tables 4 to 5, it has been confirmed that using the resist compositions of Examples, it is possible to form a resist pattern excellent in all of the pattern shape, the Eop change rate, and the LWR change rate as compared with resist compositions of Comparative Examples. In addition, it has been confirmed that the resist compositions of Examples have good etching resistance.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

What is claimed is:

1. A resist composition comprising:
a metal compound, and
a polymer that segregates on a surface of a resist film in a case where the resist film is formed using the resist composition,
wherein a structure of the metal compound is changed upon exposure, and the metal compound exhibits changed solubility in a developing solution,
the metal compound contains a metal ion of a metal atom of Group 3 to Group 16 in the long periodic table or a metal oxide of the metal atom, and a bonder that is bonded to the metal ion or the metal oxide,
a content of the metal atom contained in the metal ion or the metal oxide is in a range of 0.2% to 3% by mass with respect to a total mass of the resist composition, and
the polymer has at least one constitutional unit selected from the group consisting of a constitutional unit (a01) derived from a compound represented by General Formula (a01-1) and a constitutional unit (a02) represented by General Formula (a02-1), 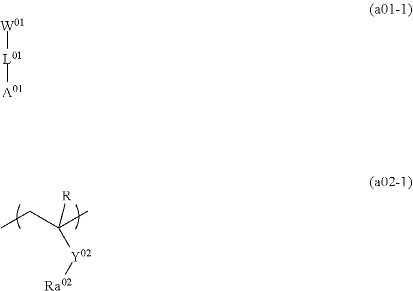
wherein, in General Formula (a01-1), W⁰¹ represents a polymerizable group-containing group; L⁰¹ represents a single bond or a divalent linking group; and A⁰¹ represents a hydrocarbon group which may have a substituent, provided that at least one of W⁰¹, L⁰¹, and A⁰¹ contains at least one fluorine atom, and
in General Formula (a02-1), R represents a hydrogen atom, an alkyl group having 1 to 5 carbon atoms, a halogenated alkyl group having 1 to 5 carbon atoms except for a fluorinated alkyl group, or a halogen atom except for a fluorine atom; Y⁰² represents a single bond or a divalent linking group; and Ra⁰² represents a hydrocarbon group except for a group containing an acid dissociable group.

2. The resist composition according to claim 1, wherein the polymer has the constitutional unit (a01).

3. The resist composition according to claim 2, wherein the polymer further has a constitutional unit other than the constitutional unit (a01).

4. The resist composition according to claim 1, wherein a content of the polymer is in a range of 0.1 to 50 parts by mass with respect to 100 parts by mass of the metal compound.

5. A method of forming a resist pattern, comprising:
forming a resist film on a support using the resist composition according to claim 1;
exposing the resist film; and
developing the exposed resist film to form a resist pattern.
